(19) United States
(12) Patent Application Publication
(10) Pub. No.: US 2014/0346456 A1
(43) Pub. Date: Nov. 27, 2014

(54) ORGANIC LIGHT-EMITTING DEVICE

(71) Applicants: Gyeongsang National University Industry-Academic Cooperation Foundation, Jinju (KR); SAMSUNG DISPLAY CO., LTD., Yongin-City (KR)

(72) Inventors: Se-Hun Kim, Yongin-City (KR); Hwan-Hee Cho, Yongin-City (KR); Mi-Kyung Kim, Yongin-City (KR); Chang-Woong Chu, Yongin-City (KR); Yun-Hi Kim, Jinju (KR)

(73) Assignees: Gyeongsang National University Industry-Academic Cooperation Foundation, Jinju (KR); SAMSUNG DISPLAY CO., LTD., Yongin-City (KR)

(21) Appl. No.: 14/045,789

(22) Filed: Oct. 3, 2013

(30) Foreign Application Priority Data
May 23, 2013 (KR) 10-2013-0058541

(51) Int. Cl. H01L 51/00

(52) U.S. Cl. CPC H01L 51/0094; H01L 51/0061; H01L 51/0055; H01L 51/0058
USPC 257/40

(57) ABSTRACT

An organic light-emitting diode includes a substrate, a first electrode, a second electrode facing the first electrode, and an emission layer between the first electrode and the second electrode. The emission layer includes an anthracene-based compound represented by Formula 1, and an amine-based compound represented by Formula 20:

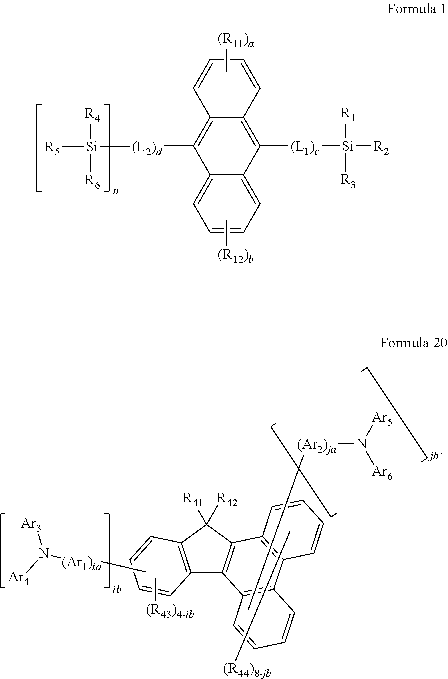

### CROSS-REFERENCE TO RELATED PATENT APPLICATION

This application claims priority to and the benefit of Korean Patent Application No. 10-2013-0058541, filed on May 23, 2013 in the Korean Intellectual Property Office, the entire content of which is incorporated herein by reference.

### BACKGROUND

1. Technical Field

Embodiments of the present invention relate to an organic light-emitting diode.

2. Description of the Related Art

Organic light-emitting diodes (OLEDs) are self-emitting diodes having advantages such as wide viewing angles, good contrast, quick response speeds, high brightness, and good driving voltage characteristics. Also, OLEDs can provide multicolored images.

A typical OLED structure includes a substrate, and an anode, a hole transport layer (HTL), an emission layer (EML), an electron transport layer (ETL), and a cathode sequentially stacked on the substrate. The HTL, the EML, and the ETL are organic thin films formed of organic compounds.

An operating principle of an OLED having the above-described structure is as follows. When a voltage is applied between the anode and the cathode, holes injected from the anode move to the EML via the HTL, and electrons injected from the cathode move to the EML via the ETL. The holes and electrons recombine in the EML to generate excitons. When the excitons drop from an excited state to a ground state, light is emitted.

### SUMMARY

Embodiments of the present invention are directed to organic light-emitting diodes (OLEDs) with high efficiency and improved lifetime.

According to an aspect of the present invention, an organic light-emitting diode includes: a substrate; a first electrode; a second electrode facing the first electrode; and an emission layer between the first electrode and the second electrode and including an anthracene-based compound represented by Formula 1 (below) and an amine-based compound represented by Formula 20 (below).

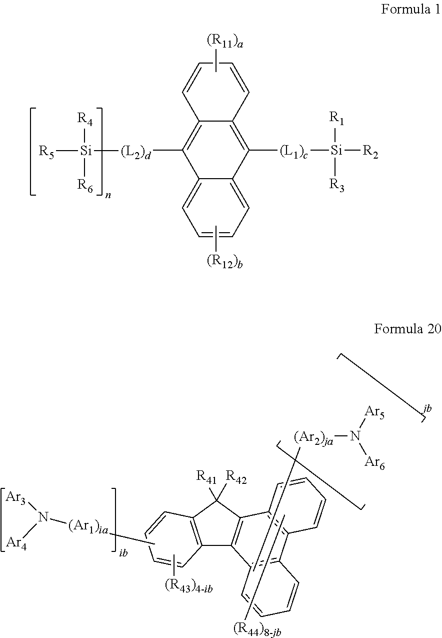

In Formulae 1 and 20, n is 0 or 1.

Also, R₁ to R₆ may each independently be a substituted or unsubstituted C₁-C₆₀ alkyl group, a 3- to 10-membered substituted or unsubstituted non-condensed ring group, or a substituted or unsubstituted condensed ring group in which at least two rings are fused to each other. If n is 0, at least one of R₁ to R₃ is a substituted or unsubstituted condensed ring group in which at least two rings are fused to each other. If n is 1, at least one of R₁ to R₆ is a substituted or unsubstituted condensed ring group in which at least two rings are fused to each other.

Additionally, L₁, L₂, A₁, and A₂ may each independently be a substituted or unsubstituted C₃-C₁₀ cycloalkylene group, a substituted or unsubstituted C₃-C₁₀ cycloalkenylene group, a substituted or unsubstituted C₃-C₁₀ heterocycloalkylene group, a substituted or unsubstituted C₃-C₁₀ heterocycloalkenylene group, a substituted or unsubstituted C₆-C₆₀ arylene group, or a substituted or unsubstituted C₂-C₆₀ heteroarylene group.

Also, c and d may each independently be an integer of 1 to 3.

R₁₁, R₁₂, R₄₃, and R₄₄ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, —N(Q₁)(Q₂), or —Si(Q₃)(Q₄)(Q₅). Q₁ to Q₅ may each independently be a hydrogen atom, a C₁-C₁₀ alkyl group, a C₆-C₂₀ aryl group, or a C₂-C₂₀ heteroaryl group.

Additionally, a and b may each independently be an integer of 1 to 4.

R₄₁ and R₄₂ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, or a substituted or unsubstituted C₂-C₆₀ heteroaryl group.

Also, ia and ja may each independently be an integer of 0 to 3, and ib and jb may each independently be an integer of 0 to 3, where ib+jb≧1.

Ar₃ to Ar₆ may each independently be a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, or a substituted or unsubstituted C₂-C₆₀ heteroaryl group.

### BRIEF DESCRIPTION OF THE DRAWINGS

The above and other features and advantages of the present invention will become more apparent by reference to the following detailed description when considered in conjunction with the attached drawing, in which:

FIG. 1 is a schematic diagram of the structure of an organic light-emitting diode according to an embodiment of the present invention.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list.

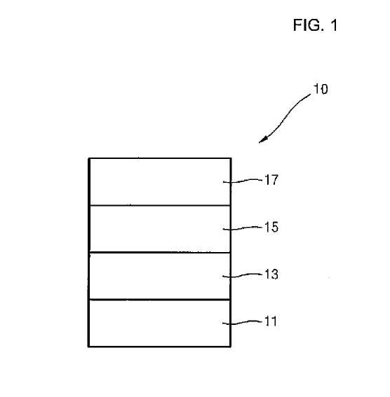

FIG. 1 is a schematic sectional view of an organic light-emitting diode 10 according to an embodiment of the present invention. Referring to FIG. 1, the organic light-emitting diode 10 according to an embodiment includes a substrate 11, a first electrode 13, an organic layer 15, and a second electrode 17. Hereinafter, a structure of an organic light-emitting diode according to an embodiment of the present invention and a method of manufacturing the same will be described with reference to FIG. 1.

The substrate 11 may be any substrate conventionally used in organic light-emitting diodes. In some embodiments, the substrate 11 may be a glass substrate or a transparent plastic substrate with mechanical strength, thermal stability, transparency, surface smoothness, ease of handling, and water resistance.

The first electrode 13 may be formed by depositing or sputtering a first electrode-forming material on the substrate 11. When the first electrode 13 is an anode, a material having a high work function may be used as the first electrode-forming material to facilitate hole injection. The first electrode 13 may be a reflective electrode or a transmissive electrode. Nonlimiting examples of suitable first electrode-forming materials include transparent and conductive materials, such as ITO, IZO, SnO₂, and ZnO. The first electrode 13 may be formed as a reflective electrode using magnesium (Mg), aluminum (Al), aluminum-lithium (Al—Li), calcium (Ca), magnesium-indium (Mg—In), magnesium-silver (Mg—Ag), or the like.

The first electrode 13 may have a single-layer structure or a multi-layer structure including at least two layers. For example, the first electrode 13 may have a three-layered structure of ITO/Ag/ITO, but it is not limited thereto.

The organic layer 15 may be disposed on the first electrode 13. The organic layer 15 may include a plurality of layers between the first electrode 13 and the second electrode 17 of the organic light-emitting diode 10. The organic layer 15 may include an emission layer (EML), and may include at least one of a hole injection layer (HIL), a hole transport layer (HTL), a functional layer having both hole injection and hole transport capabilities, a buffer layer, an electron blocking layer, a hole blocking layer, an electron transport layer (ETL), an electron injection layer (EIL), and/or a functional layer having both electron injection and electron transport capabilities.

In some embodiments, the organic layer 15 may include an HIL, an HTL, a buffer layer, an EML, an ETL, and an EIL stacked in that order.

The HIL may be formed on the first electrode 13 by vacuum deposition, spin coating, casting, Langmuir-Blodgett (LB) deposition, or the like. When the HIL is formed by vacuum deposition, the vacuum deposition conditions may vary according to the compound that is used to form the HIL, and the desired structural and thermal properties of the HIL to be formed. For example, the vacuum deposition may be performed at a temperature of about 100° C. to about 500° C., a pressure of about 10⁻⁸ torr to about 10⁻³ torr, and a deposition rate of about 0.01 to about 100 Å/sec. However, the deposition conditions are not limited thereto.

When the HIL is formed by spin coating, the coating conditions may vary according to the compound that is used to form the HIL, and the desired structural and thermal properties of the HIL to be formed. For example, the coating rate may be about 2000 rpm to about 5000 rpm, and the temperature at which heat treatment is performed to remove solvent after coating may be about 80° C. to about 200° C. However, the coating conditions are not limited thereto.

The HIL may be formed of any material that is commonly used to form an HIL. Nonlimiting examples of the material that can be used to form the HIL include N,N′-diphenyl-N,N′-bis-[4-(phenyl-m-tolyl-amino)-phenyl]-biphenyl-4,4′-diamine (DNTPD), a phthalocyanine compound, such as copper phthalocyanine, 4,4′,4″-tris(3-methylphenylphenylamino)triphenylamine (m-MTDATA), N,N′-di(1-naphthyl)-N,N′-diphenylbenzidine (NPB), TDATA, 2-TNATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), and polyaniline)/poly(4-styrenesulfonate (PANI/PSS).

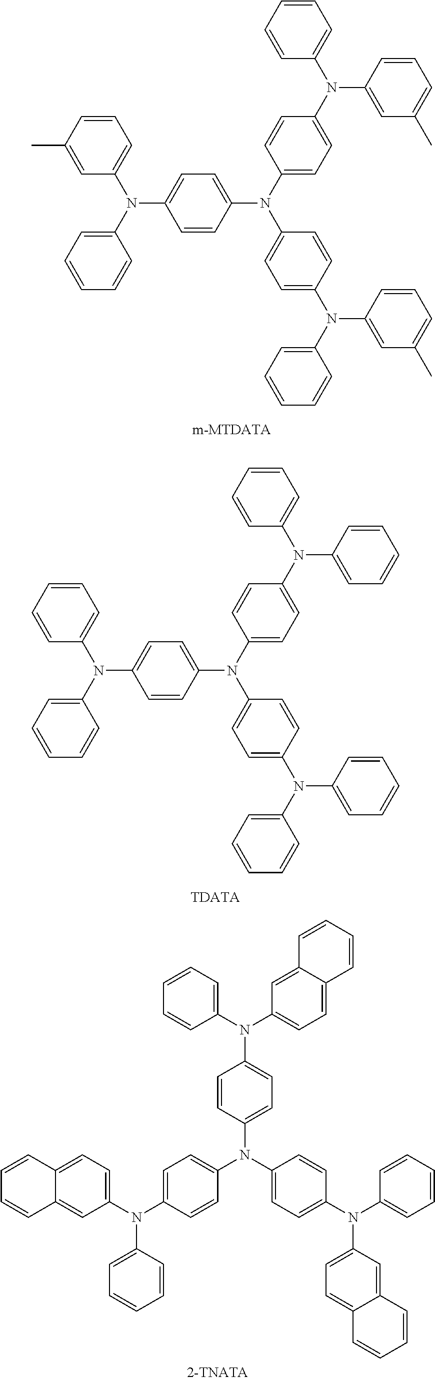

The thickness of the HIL may be about 100 Å to about 10000 Å, and in some embodiments, may be about 100 Å to about 1000 Å. When the thickness of the HIL is within these ranges, the HIL may have good hole injecting ability without a substantial increase in driving voltage.

Then, an HTL may be formed on the HIL by vacuum deposition, spin coating, casting, Langmuir-Blodgett (LB) deposition, or the like. When the HTL is formed using vacuum deposition or spin coating, the conditions for deposition or coating may be similar to those for the formation of the HIL, though the conditions for the deposition or coating may vary according to the material that is used to form the HTL.

Nonlimiting examples of suitable HTL forming materials include carbazole derivatives, such as N-phenylcarbazole or polyvinylcarbazole, N,N′-bis(3-methylphenyl)-N,N′-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine) (NPB).

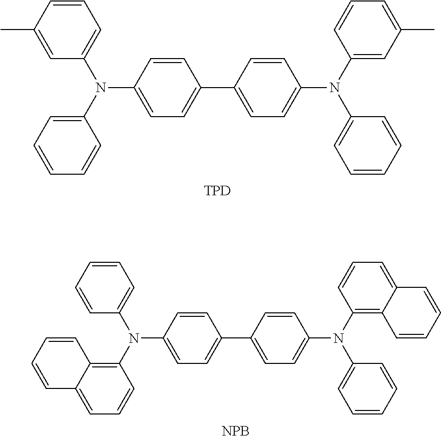

The thickness of the HTL may be about 50 Å to about 2000 Å, and in some embodiments, may be about 100 Å to about 1500 Å. When the thickness of the HTL is within these ranges, the HTL may have good hole transporting ability without a substantial increase in driving voltage.

The functional layer (hereinafter, referred to as “H-functional layer”) having both hole injection and hole transport capabilities may be used instead of the HIL and HTL, and may contain at least one hole injection layer material and at least one hole transport layer material. The thickness of the H-functional layer may be about 100 Å to about 10,000 Å, and in some embodiments, may be about 100 Å to about 1,000 Å. When the thickness of the H-functional layer is within these ranges, the H-functional layer may have good hole injection and transport capabilities without a substantial increase in driving voltage.

In some embodiments, at least one of the HIL, HTL, and H-functional layer may include at least one of a compound of Formula 300 below and a compound of Formula 301 below.

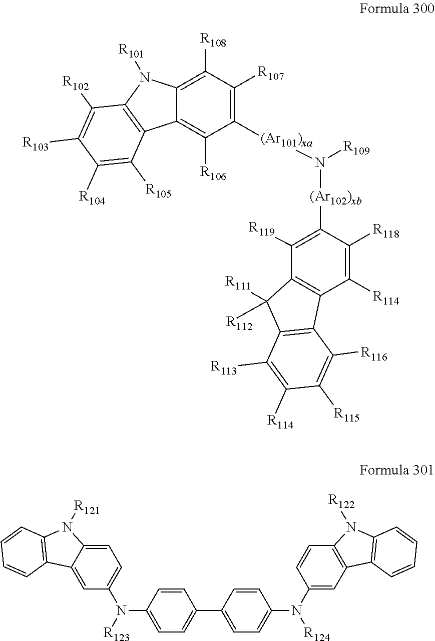

In Formula 300 (above), Ar₁₀₁ and Ar₁₀₂ may each independently be a substituted or unsubstituted C₆-C₆₀ arylene group.

In some embodiments, Ar₁₀₁ and Ar₁₀₂ may each independently be:

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylenylene group, a chrysenylene group, a naphthacenylene group, a picenylene group, a perylenylene group, or a pentacenylene group; or

a phenylene group, a pentalenylene group, an indenylene group, a naphthylene group, an azulenylene group, a heptalenylene group, acenaphthylene group, a fluorenylene group, a phenalenylene group, a phenanthrenylene group, an anthracenylene group, a fluoranthenylene group, a triphenylenylene group, a pyrenylenylene group, a chrysenylene group, a naphthacenylene group, a picenylene group, a perylenylene group, or a pentacenylene group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, or a C₂-C₆₀ heteroaryl group. However, Ar₁₀₁ and Ar₁₀₂ are not limited thereto.

In Formula 300, xa and xb may each independently be an integer of 0 to 5, for example, 0, 1, or 2. For example, xa may be 1, and xb may be 0, but they are not limited thereto.

In Formulae 300 and 301, R₁₀₁ to R₁₀₈, R₁₁₁ to R₁₁₉, and R₁₂₁ to R₁₂₄ may each independently be:

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₆-C⁶⁰ aryl group, a substituted or unsubstituted C₆-C₆₀ aryloxy group, or a substituted or unsubstituted C₆-C₆₀ arylthio group.

In some embodiments, R₁₀₁ to R₁₀₈, R₁₁₁ to R₁₁₉, and R₁₂₁ to R₁₂₄ may each independently be:

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group (e.g., a methyl group, an ethyl group, a propyl group, a butyl group, a pentyl group, a hexyl group, etc.), or a C₁-C₁₀ alkoxy group (e.g., a methoxy group, an ethoxy group, a propoxy group, a butoxy group, a pentoxy group, etc.); or

a C₁-C₁₀ alkyl group or a C₁-C₁₀ alkoxy group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof; or

a phenyl group, a naphthyl group, an anthracenyl group, a fluorenyl group, or a pyrenyl group; or

a phenyl group, a naphthyl group, an anthracenyl group, a fluorenyl group, or a pyrenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, or a C₁-C₁₀ alkoxy group. However, R₁₀₁ to R₁₀₈, R₁₁₁ to R₁₁₉, and R₁₂₁ to R₁₂₄ are not limited thereto.

In Formula 300, R₁₀₉ may be:

a phenyl group, a naphthyl group, an anthracenyl group, a biphenyl group, or a pyridyl group; or

a phenyl group, a naphthyl group, an anthracenyl group, a biphenyl group, or a pyridyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, or a C₁-C₂₀ alkoxy group.

In an embodiment, the compound of Formula 300 may be a compound represented by Formula 300 Å below, but is not limited thereto.

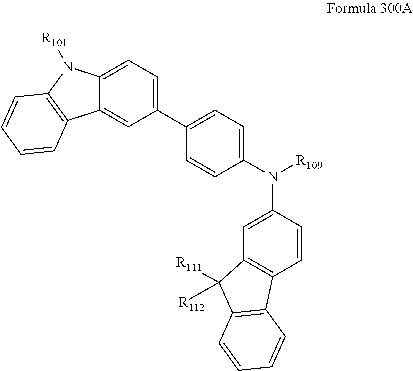

In Formula 300 Å, R₁₀₁, R₁₁₁, R₁₁₂ and R₁₀₉ are as defined above.

In some non-limiting embodiments, at least one of the HIL, HTL, and H-functional layer may include at least one of the compounds represented by Formulae 301 to 320 below, but the HIL, HTL, and H-functional layer are not limited thereto.

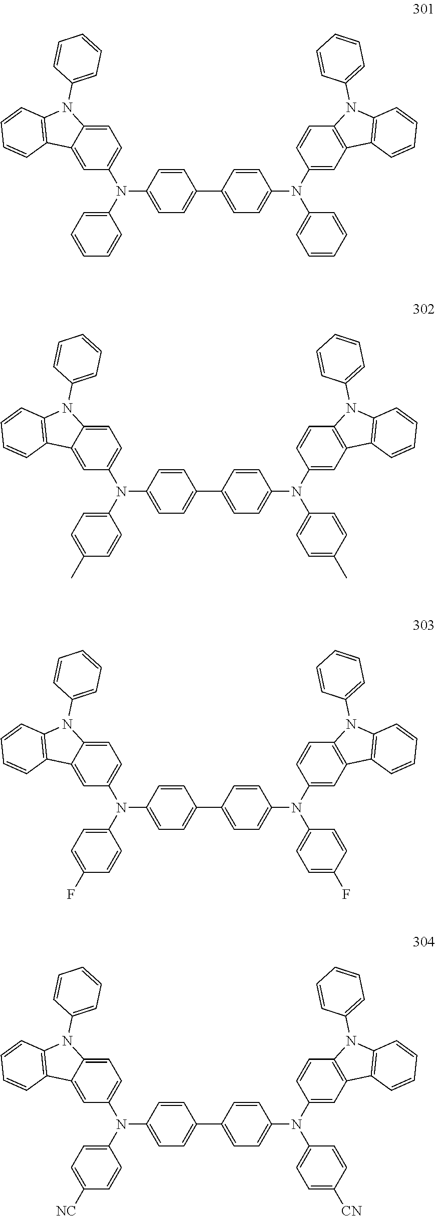 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

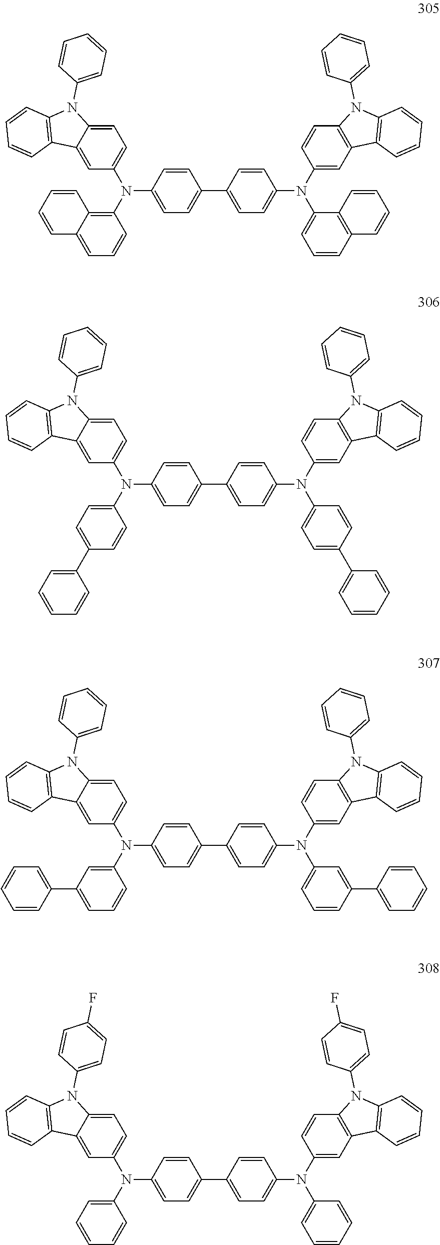 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

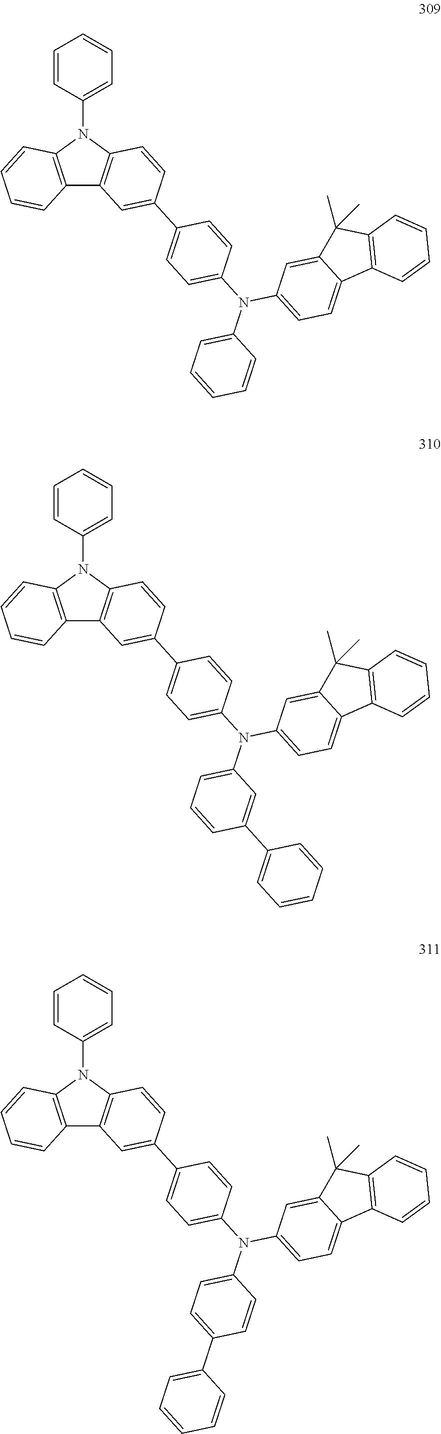 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

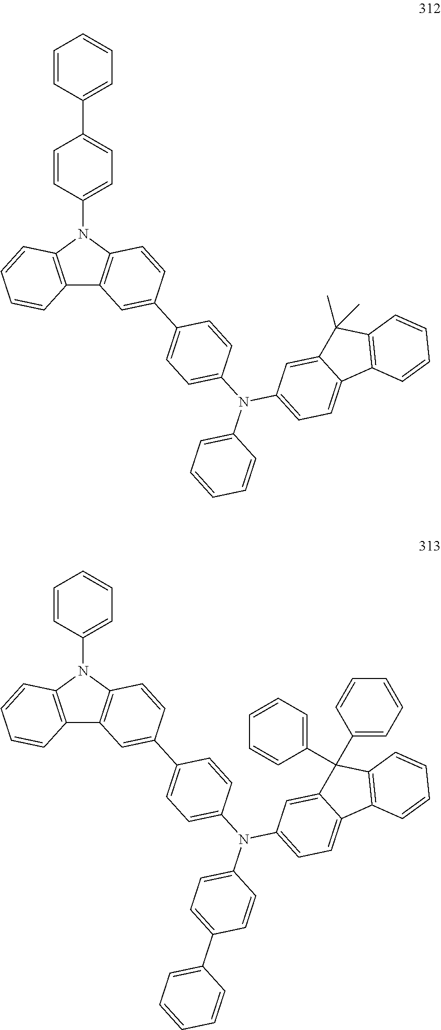 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

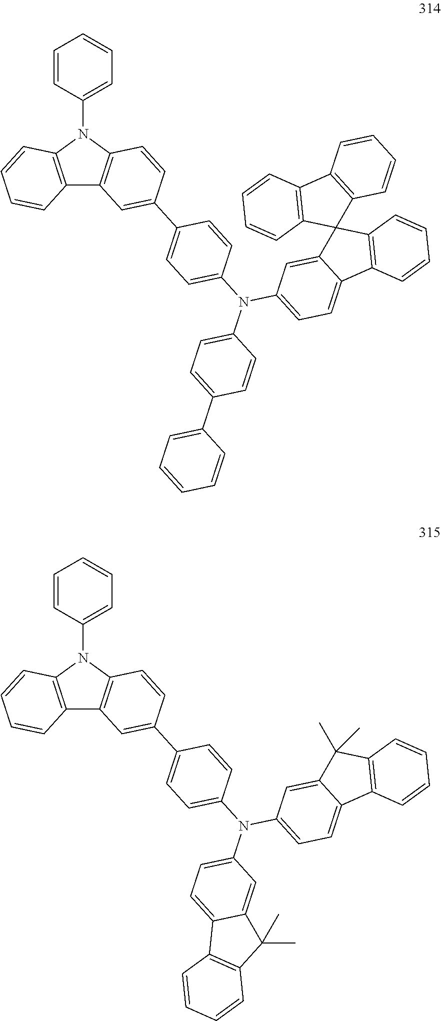 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

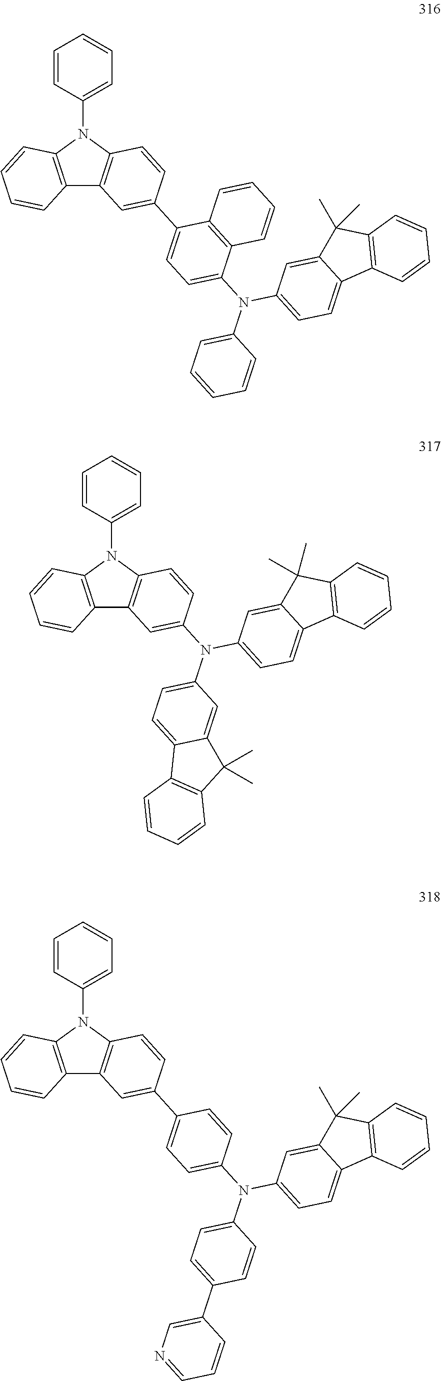 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

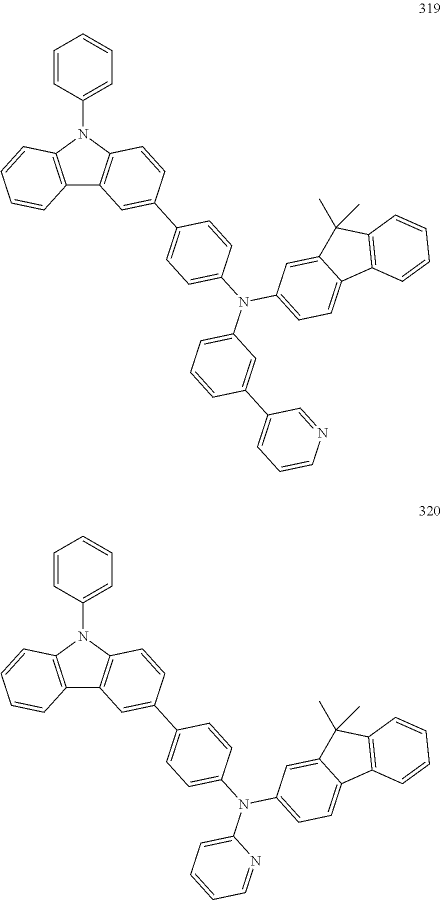 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

In addition to the hole injecting material, hole transport material, and/or material having both hole injection and hole transport capabilities, at least one of the HIL, HTL, and H-functional layer may further include a charge-generating material for improved layer conductivity. The charge-generating material may be, for example, a p-dopant. Nonlimiting examples of the p-dopant include quinone derivatives, metal oxides, and cyano group-containing compounds. Specific nonlimiting examples of the p-dopant include quinone derivatives, such as tetracyanoquinonedimethane (TCNQ), 2,3,5,6-tetrafluoro-tetracyano-1,4-benzoquinonedimethane (F4-TCNQ), and the like; metal oxides, such as tungsten oxide, molybdenum oxide, and the like; and cyano-containing compounds, such as Compound 200 below.

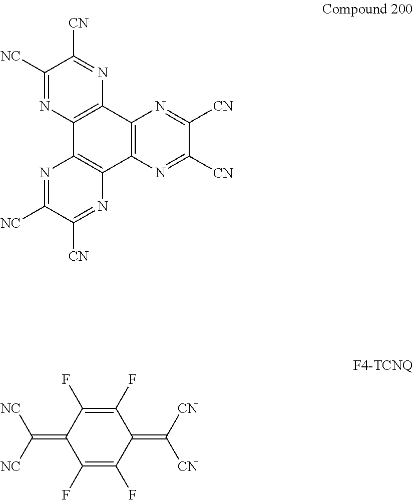 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When the hole injection layer, hole transport layer, or H-functional layer further includes a charge-generating material, the charge-generating material may be homogeneously dispersed or inhomogeneously distributed in the layer.

A buffer layer may be disposed between the EML and at least one of the HIL, HTL, and H-functional layer. The buffer layer may compensate for an optical resonance distance of light according to a wavelength of the light emitted from the EML, and thus may increase efficiency. The buffer layer may include any hole injecting material or hole transporting material. In some embodiments, the buffer layer may include the same material as one of the materials included in the HIL, HTL, and/or H-functional layer underneath the buffer layer.

Then, an EML may be formed on the HTL, H-functional layer, or buffer layer by vacuum deposition, spin coating, casting, LB deposition, or the like. When the EML is formed by vacuum deposition or spin coating, the deposition or coating conditions may be similar to those for the formation of the HIL, though the conditions for deposition or coating may vary according to the material that is used to form the EML.

The EML may include an anthracene-based compound represented by Formula 1 and an amine-based compound represented by Formula 20 below.

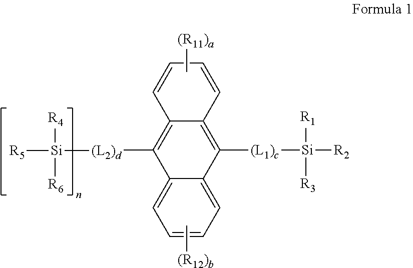

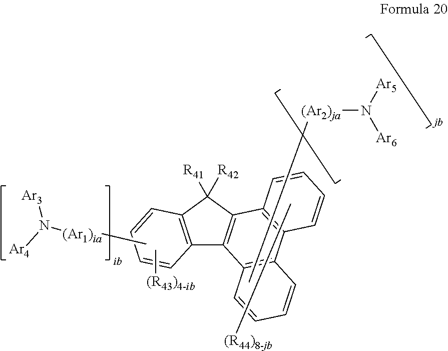

The anthracene-based compound may serve as a host, and the amine-based compound may serve as a dopant. For example, the amine-based compound may serve as a blue fluorescent dopant that emits blue light by a fluorescent emission mechanism. A weight ratio of the anthracene-based compound to the amine-based compound in the EML may be about 99.9:0.01 to about 80:20.

In Formula 1, n may be 0 or 1. If n is 0, the compound of Formula 1 does not include the —Si(R₄)(R₅)(R₆) substituent.

In Formula 1, R₁ to R₆ may each independently be a substituted or unsubstituted C₁-C₆₀ alkyl group, a 3- to 10-membered substituted or unsubstituted non-condensed ring group, or a substituted or unsubstituted condensed ring group in which at least two rings are fused to each other. If n is 0, at least one of R₁ to R₃ is a substituted or unsubstituted condensed ring group in which at least two rings are fused to each other. If n is 1, at least one of R₁ to R₆ is a substituted or unsubstituted condensed ring group in which at least two rings are fused to each other.

As used herein, the phrase “the 3- to 10-membered substituted or unsubstituted non-condensed ring group” refers to a 3- to 10-membered cyclic group with one ring that does not form a condensed ring. Ring atoms of “the 3- to 10-membered substituted or unsubstituted non-condensed ring group” may be selected from C, N, O, P, S, and Si. This will be further understood by reference to Formulae 2A to 2T, described below.

As used herein, the phrase “substituted or unsubstituted condensed ring group in which at least two rings are fused to each other” refers to a group with at least two rings that are fused to each other. The “substituted or unsubstituted condensed ring group in which at least two rings are fused to each other” may be an aromatic or non-aromatic group, and may include 3 to 60 ring atoms. The ring atoms may be selected from C, N, O, P, S, and Si. The “substituted or unsubstituted condensed ring group in which at least two rings are fused to each other” will be further understood by reference to, for example, Formulae 3A to 3R and Formulae 4A to 4J, described below.

In some embodiments, in Formula 1, R₁ to R₆ may each independently be:

a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group; or

a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q₁₁ₐ)(Q₁₂ₐ) (where Q₁₁ₐ and Q₁₂ₐ are each independently a hydrogen atom, a C₁-C₁₀ alkyl group, a C₆-C₂₀ aryl group, or a C₂-C₂₀ heteroaryl group).

In Formula 1, if n is 0, at least one of R₁ to R₃, or, if n is 1, at least one of R₁ to R₆, may each independently be:

a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group; or

a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q₁₁ₐ)(Q₁₂ₐ) (where Q₁₁ₐ and Q₁₂ₐ are each independently a hydrogen atom, a C₁-C₁₀ alkyl group, a C₆-C₂₀ aryl group, or a C₂-C₂₀ heteroaryl group).

In some embodiments, in Formula 1, R₁ to R₆ may each independently be:

a methyl group, an ethyl group, a n-propyl group, an i-propyl group, an n-butyl group, an i-butyl group, a t-butyl group, a pentyl group, a hexyl group, a heptyl group, an octyl group, a nonyl group, or a decyl group; or

a methyl group, an ethyl group, a n-propyl group, an i-propyl group, a n-butyl group, an i-butyl group, a t-butyl group, a pentyl group, a hexyl group, a heptyl group, an octyl group, a nonyl group, or a decyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q₁₁ₐ)(Q₁₂ₐ) (where Q₁₁ₐ and Q₁₂ₐ are each independently a hydrogen atom, a C₁-C₁₀ alkyl group, a C₆-C₂₀ aryl group, or a C₂-C₂₀ heteroaryl group); or

a group represented by one of Formulae 2A to 2T below; or

a group represented by one of Formulae 3A to 3R below,

In Formula 1, if n is 0, at least one of R₁ to R₃, or, if n is 1, at least one of R₁ to R₆ may each independently be a group represented by one of Formulae 3A to 3R below.

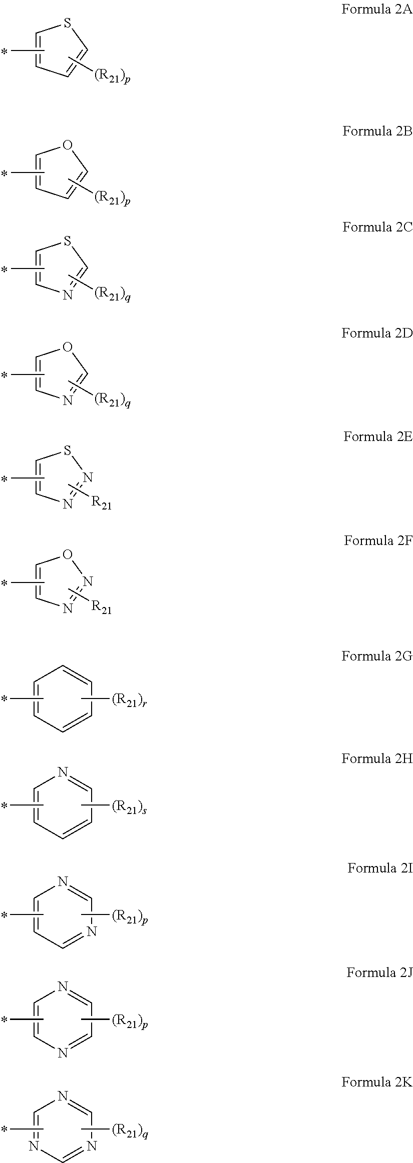

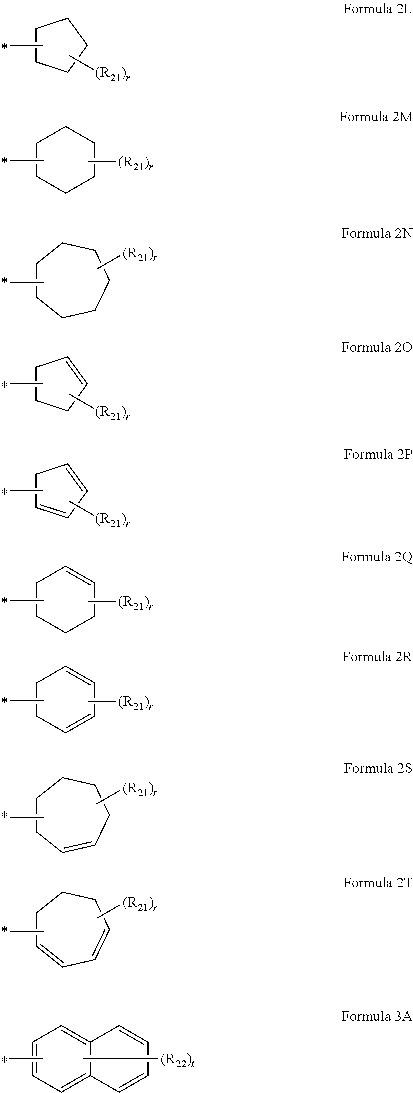

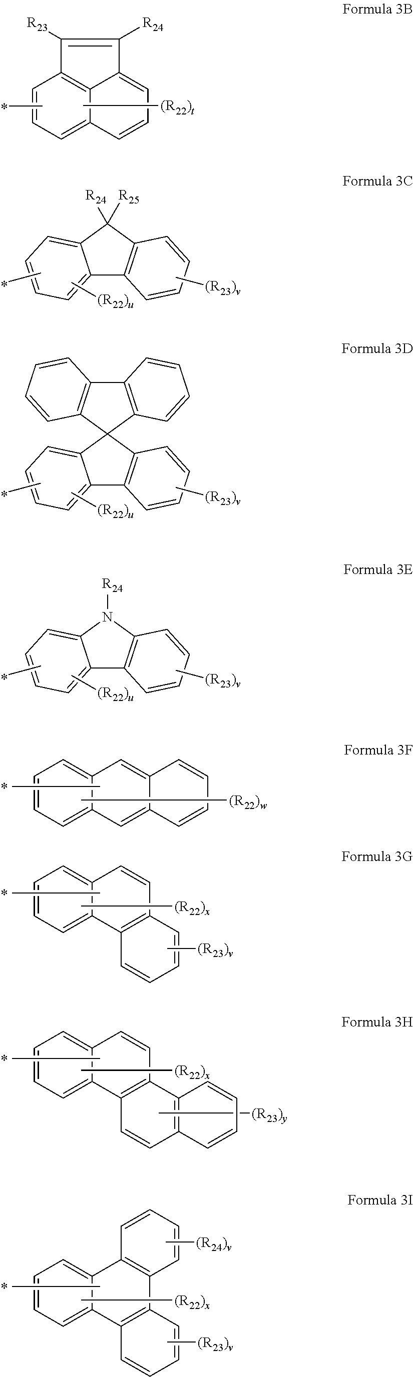

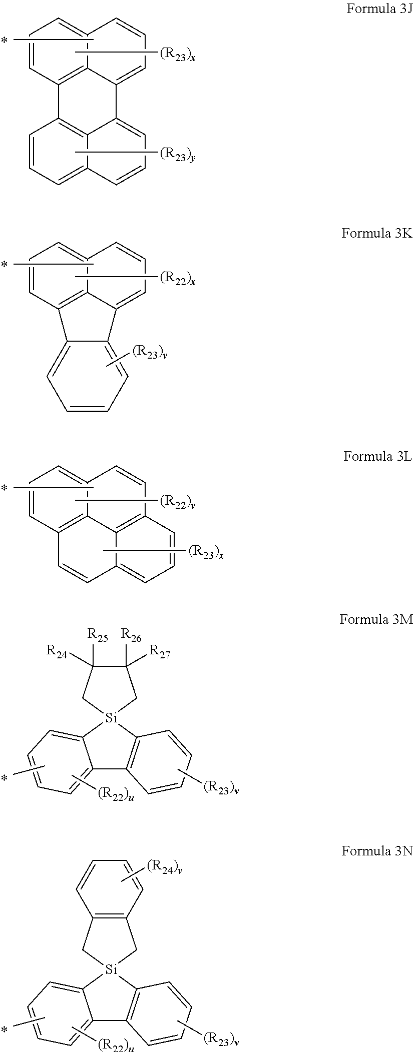

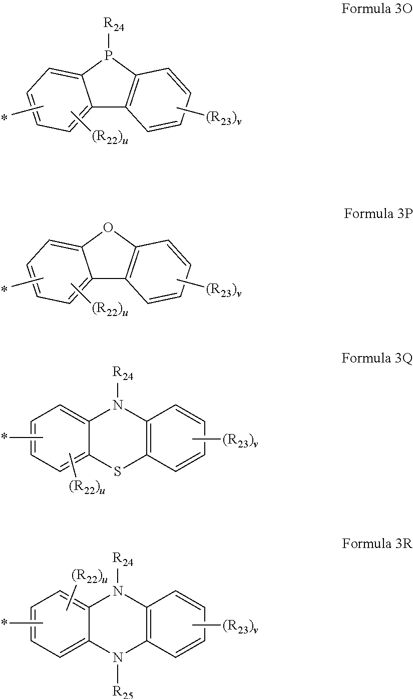

In Formulae 2A to 2T and Formulae 3A to 3R, R₂₁ to R₂₇ may each independently be:

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q₁₁ₐ)(Q₁₂ₐ) (where Q₁₁ₐ and Q₁₂ₐ are each independently a hydrogen atom, a C₁-C₁₀ alkyl group, a C₆-C₂₀ aryl group, or a C₂-C₂₀ heteroaryl group).

Also, p and u may each independently be an integer of 1 to 3; q may be 1 or 2; r and x may each independently be an integer of 1 to 5; s and v may each independently be an integer of 1 to 4; t may be an integer of 1 to 7; w may be an integer of 1 to 9; and y may be an integer of 1 to 6.

In some embodiments, in Formulae 2A to 2T and Formulae 3A to 3R, R₂₁ to R₂₇ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a dimethyl-fluorenyl group, a phenyl-carbazolyl group, a pyrenyl group, a chrysenyl group, a benzothiazolyl group, a benzooxazolyl group, a phenyl-benzoimidazolyl group, or —N(Q₁₁ₐ)(Q₁₂ₐ) (where Q₁₁ₐ and Q₁₂ₐ are each independently a hydrogen atom, a C₁-C₁₀ alkyl group, a phenyl group, a naphthyl group, or an anthracenyl group). However, but R₂₁ to R₂₇ are not limited thereto.

In some other embodiments, in Formula 1, R₁ to R₆ may each independently be:

a methyl group, an ethyl group, a n-propyl group, an i-propyl group, an n-butyl group, an i-butyl group, a t-butyl group, a pentyl group, a hexyl group, a heptyl group, an octyl group, a nonyl group, or a decyl group; or

a methyl group, an ethyl group, an n-propyl group, an i-propyl group, an n-butyl group, an i-butyl group, a t-butyl group, a pentyl group, a hexyl group, a heptyl group, an octyl group, a nonyl group, or a decyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a phenyl group, a naphthyl group, or an anthracenyl group; or

a group represented by Formula 2G below; or

a group represented by Formulae 4A to 4J below.

In Formula 1, if n is 0, at least one of R₁ to R₃, or, if n is 1, at least one of R₁ to R₆, may each independently be a group represented by one of Formulae 4A to 4J below.

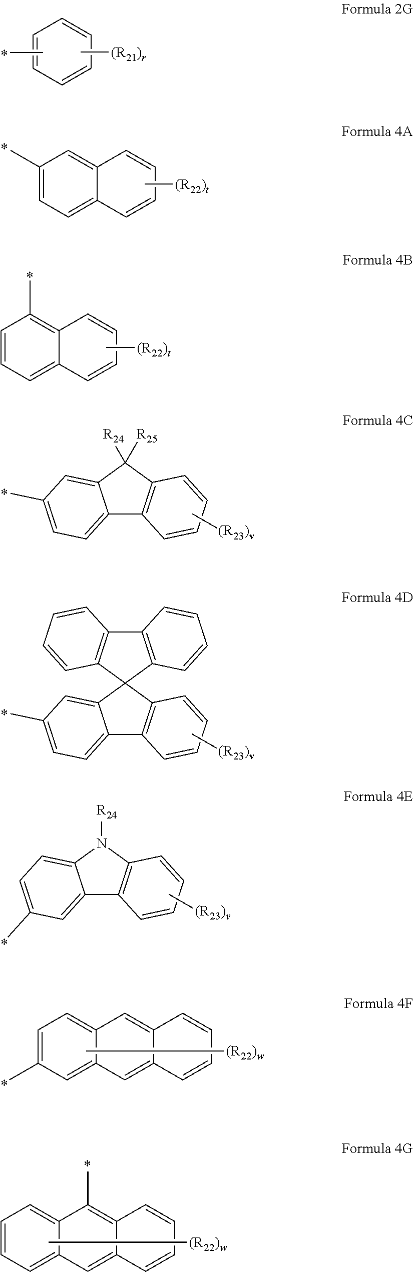

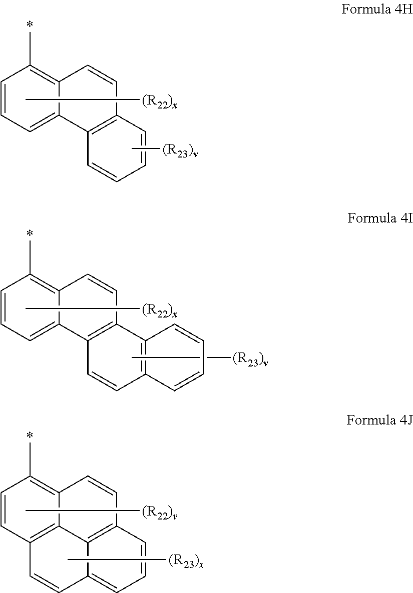

In Formula 2G and Formulae 4A to 4J, R₂₁ to R₂₅ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a dimethyl-fluorenyl group, a phenyl-carbazolyl group, a pyrenyl group, a chrysenyl group, a benzothiazolyl group, a benzooxazolyl group, a phenyl-benzoimidazolyl group, or —N(Q₁₁ₐ)(Q₁₂ₐ) (where Q₁₁ₐ and Q₁₂ₐ are each independently, a hydrogen atom, a C₁-C₁₀ alkyl group, a phenyl group, a naphthyl group, or an anthracenyl group).

Also, r and x may each independently be an integer of 1 to 5; v may be an integer from 1 to 4; t may be an integer of 1 to 7; w may be an integer from 1 to 9; and y may be an integer of 1 to 6.

In Formulae 1 and 20, L₁, L₂, Ar₁, and Ar₂ may each independently be a substituted or unsubstituted C₃-C₁₀ cycloalkylene group, a substituted or unsubstituted C₃-C₁₀ cycloalkenylene group, a substituted or unsubstituted C₃-C₁₀ heterocycloalkylene group, a substituted or unsubstituted C₃-C₁₀ heterocycloalkenylene group, a substituted or unsubstituted C₆-C₆₀ arylene group, or a substituted or unsubstituted C₂-C₆₀ heteroarylene group.

For example, in Formulae 1 and 20, L₁, L₂, Ar₁, and Ar₂ may each independently be:

a cyclopropylene group, a cyclobutylene group, a cyclopentylene group, a cyclohexylene group, a cycloheptylene group, a cyclooctylene group, a cyclopentenylene group, a cyclopentadienylene group, a cyclohexenylene group, a cyclohexadienylene group, a cycloheptadienylene group, a thiophenylene group, a furanylene group, a pyrrolylene group, an imidazolylene group, a pyrazolylene group, an isothiazolylene group, an isoxazolylene group, a thiazolylene group, an oxazolylene group, an oxadiazolylene group, a thiadiazolylene group, a triazolylene group, a phenylene group, a pyridinylene group, a pyrazinylene group, a pyrimidinylene group, a pyridazinylene group, a triazinylene group, a pentalenylene group, an indenylene group, a naphthylene group, an azulenylene group, a heptalenylene group, a biphenylenylene group, an indacenylene group, an acenaphthalenylene group, a fluorenylene group, a spiro-fluorenylene group, a carbazolylene group, an anthracenylene group, a phenalenylene group, a phenanthrenylene group, a perylenylene group, a fluoranthenylene group, a naphthacenylene group, a picenylene group, a pentaphenylene group, a hexacenylene group, a dibenzofuranylene group, a phenothiazinylene group, a phenoxazinylene group, a dihydrophenazinylene group, a phenoxathiinylene group, or a phenanthridinylene group; or

a cyclopropylene group, a cyclobutylene group, a cyclopentylene group, a cyclohexylene group, a cycloheptylene group, a cyclooctylene group, a cyclopentenylene group, a cyclopentadienylene group, a cyclohexenylene group, a cyclohexadienylene group, a cycloheptadienylene group, a thiophenylene group, a furanylene group, a pyrrolylene group, an imidazolylene group, a pyrazolylene group, an isothiazolylene group, an isoxazolylene group, a thiazolylene group, an oxazolylene group, an oxadiazolylene group, a thiadiazolylene group, a triazolylene group, a phenylene group, a pyridinylene group, a pyrazinylene group, a pyrimidinylene group, a pyridazinylene group, a triazinylene group, a pentalenylene group, an indenylene group, a naphthylene group, an azulenylene group, a heptalenylene group, a biphenylenylene group, an indacenylene group, an acenaphthalenylene group, a fluorenylene group, a spiro-fluorenylene group, a carbazolylene group, an anthracenylene group, a phenalenylene group, a phenanthrenylene group, a perylenylene group, a fluoranthenylene group, a naphthacenylene group, a picenylene group, a pentaphenylene group, a hexacenylene group, a dibenzofuranylene group, a phenothiazinylene group, a phenoxazinylene group, a dihydrophenazinylene group, a phenoxathiinylene group, or a phenanthridinylene group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q_{11b})(Q_{12b}) (where Q_{11b} and Q_{12b} are each independently a hydrogen atom, a C₁-C₁₀ alkyl group, a C₆-C₂₀ aryl group, or a C₂-C₂₀ heteroaryl group).

In some embodiments, in Formulae 1 and 20, L₁, L₂, Ar₁, and Ar₂ may each independently be a group represented by one of Formulae 5A to 5J below.

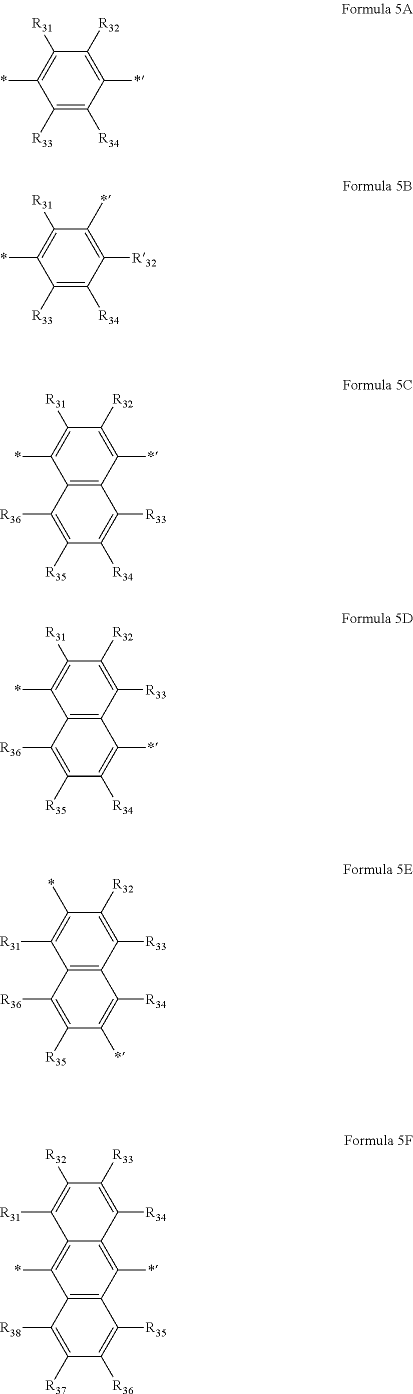

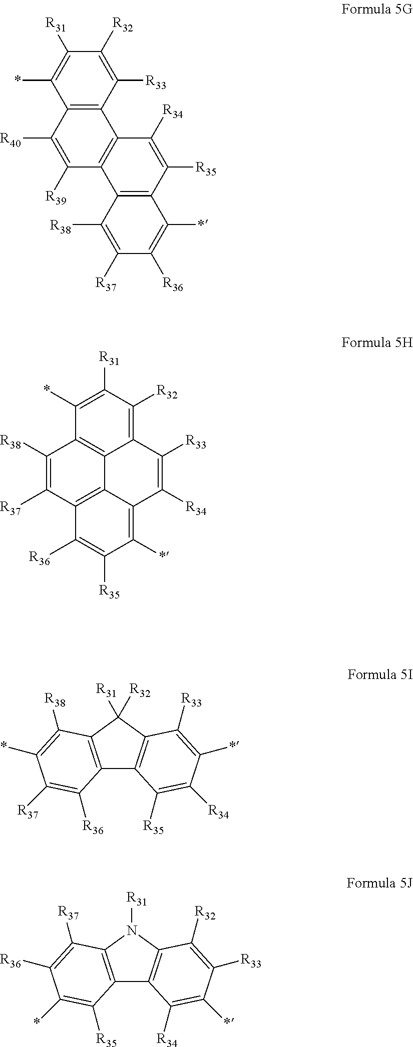

In Formulae 5A to 5J, R₃₁ to R₄₀ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or a —N(Q_{11b})(Q_{12b}) (where Q_{11b} and Q_{12b} are each independently a hydrogen atom, a C₁-C₁₀ alkyl group, a C₆-C₂₀ aryl group, or a C₂-C₂₀ heteroaryl group).

Also, * indicates a binding site with the anthracene core in Formula 1.

For example, in Formulae 5A to 5J, R₃₁ to R₄₀ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a dimethyl-fluorenyl group, a phenyl-carbazolyl group, a pyrenyl group, a chrysenyl group, a benzothiazolyl group, a benzooxazolyl group, or a phenyl-benzoimidazolyl group.

In Formula 1, c indicates the number of L is, and may be an integer of 1 to 3. If c is 2 or greater, the at least two L₁s may be the same or different. In Formula 1, d indicates the number of L₂s, and may be an integer of 1 to 3. If d is 2 or greater, the at least two L₂s may be the same or different. In Formula 1, c and d may be 1.

In Formulae 1 and 20, R₁₁, R₁₂, R₄₃, and R₄₄ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, —N(Q₁)(Q₂), or —Si(Q₃)(Q₄(Q₅) (where Q₁ to Q₅ are each independently a hydrogen atom, a C₁-C₁₀ alkyl group, a C₆-C₂₀ aryl group, or a C₂-C₂₀ heteroaryl group).

In some embodiments, in Formulae 1 and 20, R₁₁, R₁₂, R₄₃, and R₄₄ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, or an anthracenyl group.

In some other embodiments, in Formulae 1 and 20, R₁₁, R₁₂, R₄₃, and R₄₄ may each be a hydrogen atom.

In Formula 1, n may be 1; R₁, R₃, R₄, and R₆ may each independently be a substituted or unsubstituted C₁-C₆₀ alkyl group; and R₂ and R₅ may each independently be a 3- to 10-membered substituted or unsubstituted non-condensed ring group or a substituted or unsubstituted condensed ring group in which at least two rings are fused to each other; and at least one of R₃ and R₅ may be a substituted or unsubstituted condensed ring group in which at least two rings are fused to each other.

Alternatively, in Formula 1, n may be 0; R₁ and R₃ may each independently be a substituted or unsubstituted C₁-C₆₀ alkyl group; and R₂ may be a substituted or unsubstituted condensed ring group in which at least two rings are fused to each other.

In some embodiments, the anthracene-based compound of Formula 1 may be one of Compounds 1 to 24 below, but the anthracene-based compound of Formula 1 is not limited thereto.

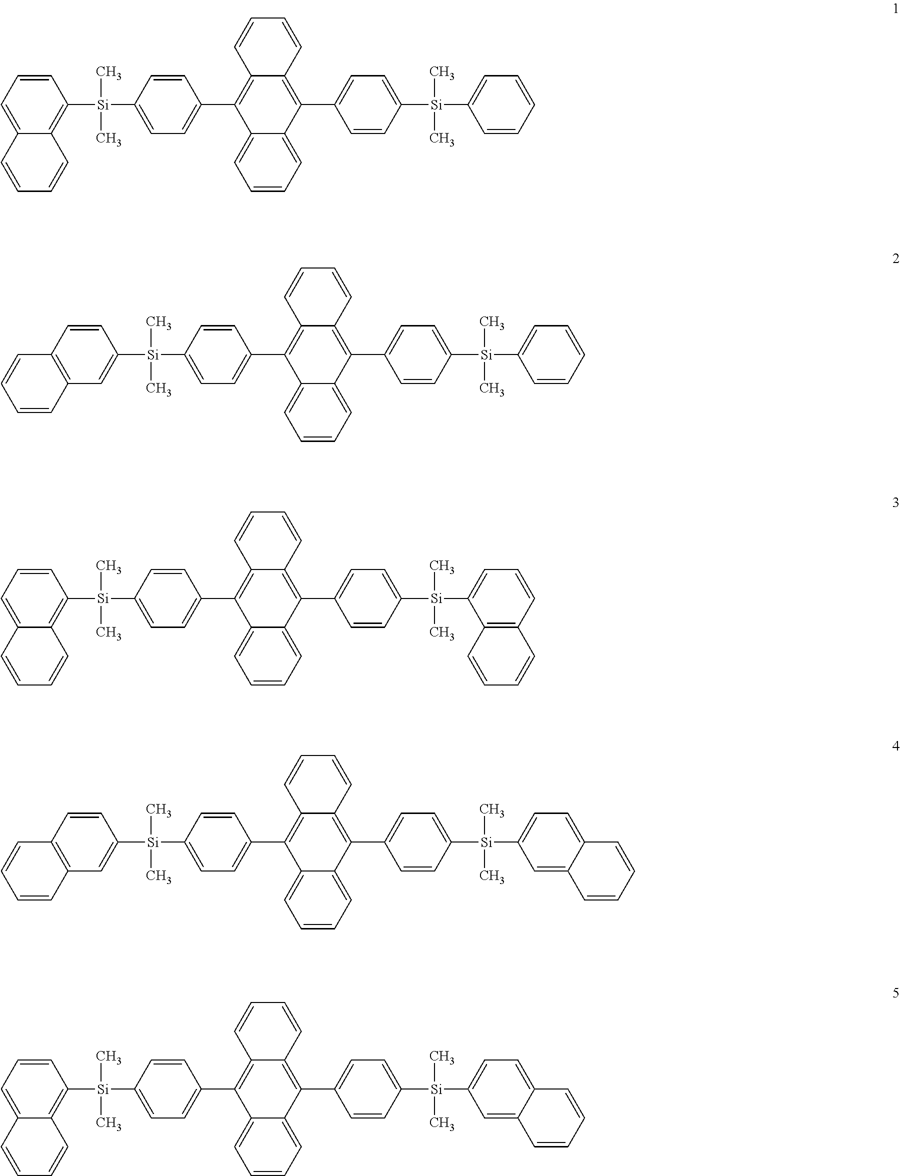 [SMILES: C[Si](C)(c1ccccc1)c1ccc(-c2c3ccccc3c(-c3ccc([Si](C)(C)c4cccc5ccccc45)cc3)c3ccccc23)cc1 ; C[Si](C)(c1ccccc1)c1ccc(-c2c3ccccc3c(-c3ccc([Si](C)(C)c4ccc5ccccc5c4)cc3)c3ccccc23)cc1 ; C[Si](C)(c1ccc(-c2c3ccccc3c(-c3ccc([Si](C)(C)c4cccc5ccccc45)cc3)c3ccccc23)cc1)c1cccc2ccccc12 ; C[Si](C)(c1ccc(-c2c3ccccc3c(-c3ccc([Si](C)(C)c4ccc5ccccc5c4)cc3)c3ccccc23)cc1)c1ccc2ccccc2c1 ; C[Si](C)(c1ccc(-c2c3ccccc3c(-c3ccc([Si](C)(C)c4cccc5ccccc45)cc3)c3ccccc23)cc1)c1ccc2ccccc2c1]

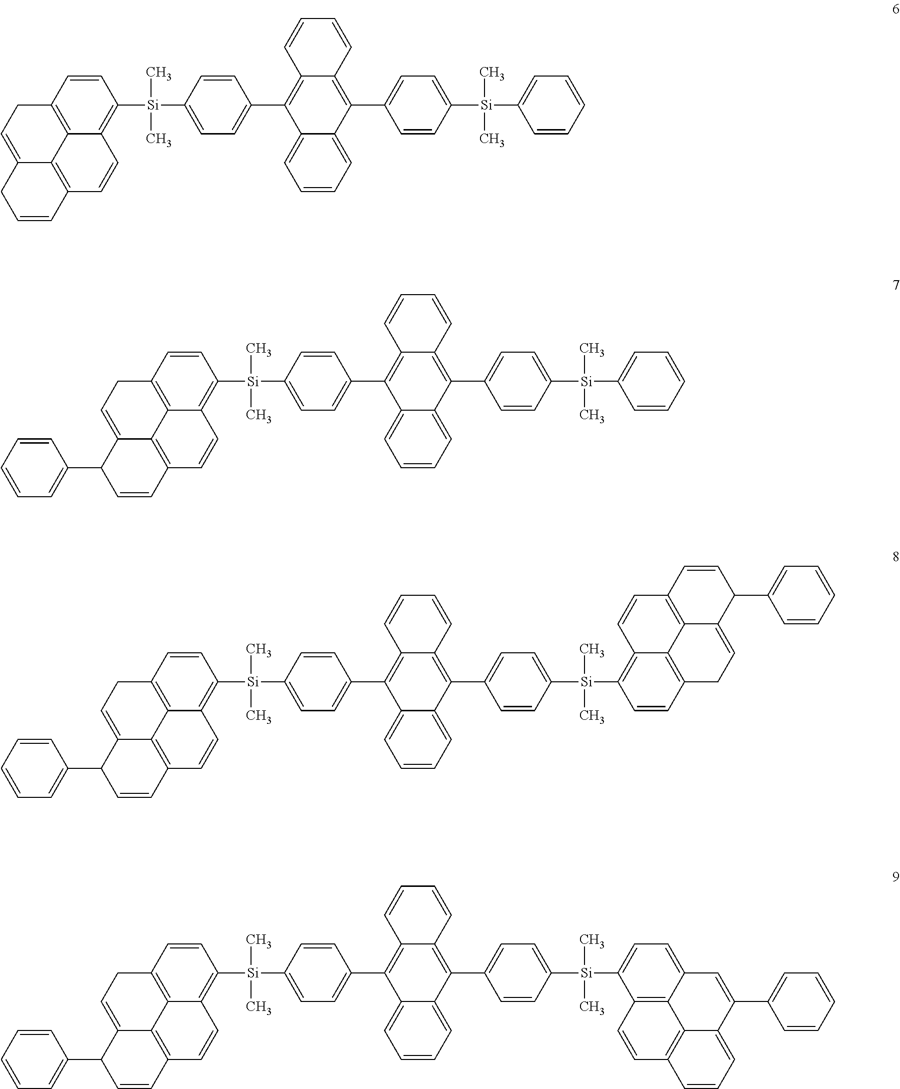 [SMILES: C[Si](C)(c1ccccc1)c1ccc(-c2c3ccccc3c(-c3ccc([Si](C)(C)c4ccc5c6c7c(ccc46)C=CCC7=CC5)cc3)c3ccccc23)cc1 ; C[Si](C)(c1ccccc1)c1ccc(-c2c3ccccc3c(-c3ccc([Si](C)(C)c4ccc5c6c7c(ccc46)C=CC(c4ccccc4)C7=CC5)cc3)c3ccccc23)cc1 ; C[Si](C)(c1ccc(-c2c3ccccc3c(-c3ccc([Si](C)(C)c4ccc5c6c7c(ccc46)C=CC(c4ccccc4)C7=CC5)cc3)c3ccccc23)cc1)c1ccc2c3c4c(ccc13)C=CC(c1ccccc1)C4=CC2 ; C[Si](C)(c1ccc(-c2c3ccccc3c(-c3ccc([Si](C)(C)c4ccc5cc(-c6ccccc6)c6cccc7ccc4c5c76)cc3)c3ccccc23)cc1)c1ccc2c3c4c(ccc13)C=CC(c1ccccc1)C4=CC2]

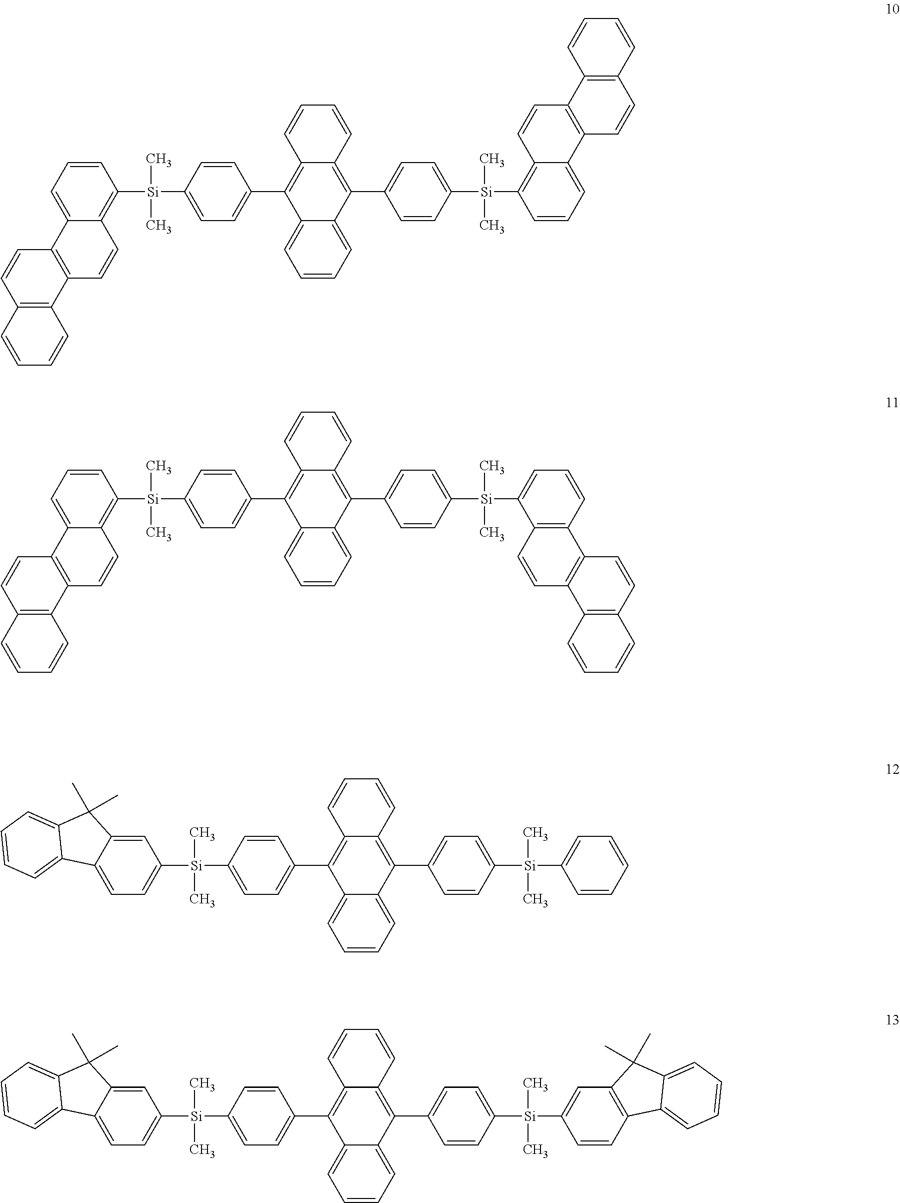 [SMILES: C[Si](C)(c1ccc(-c2c3ccccc3c(-c3ccc([Si](C)(C)c4cccc5c4ccc4c6ccccc6ccc54)cc3)c3ccccc23)cc1)c1cccc2c1ccc1c3ccccc3ccc21 ; C[Si](C)(c1ccc(-c2c3ccccc3c(-c3ccc([Si](C)(C)c4cccc5c4ccc4c6ccccc6ccc54)cc3)c3ccccc23)cc1)c1cccc2c1ccc1c3ccccc3ccc21 ; CC1(C)c2ccccc2-c2ccc([Si](C)(C)c3ccc(-c4c5ccccc5c(-c5ccc([Si](C)(C)c6ccccc6)cc5)c5ccccc45)cc3)cc21 ; CC1(C)c2ccccc2-c2ccc([Si](C)(C)c3ccc(-c4c5ccccc5c(-c5ccc([Si](C)(C)c6ccc7c(c6)C(C)(C)c6ccccc6-7)cc5)c5ccccc45)cc3)cc21]

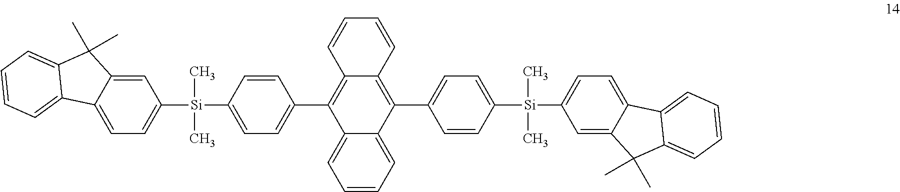 [SMILES: CC1(C)c2ccccc2-c2ccc([Si](C)(C)c3ccc(-c4c5ccccc5c(-c5ccc([Si](C)(C)c6ccc7c(c6)C(C)(C)c6ccccc6-7)cc5)c5ccccc45)cc3)cc21]

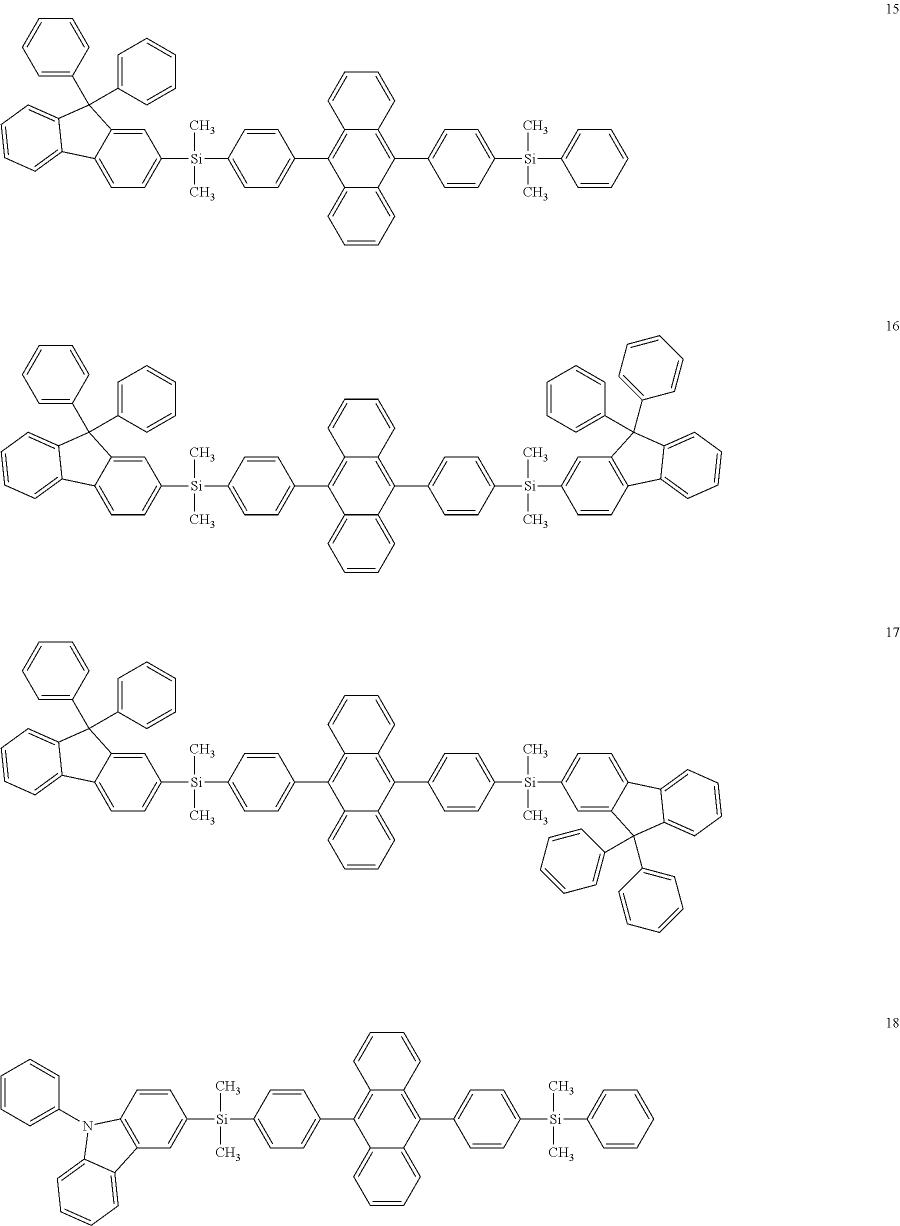

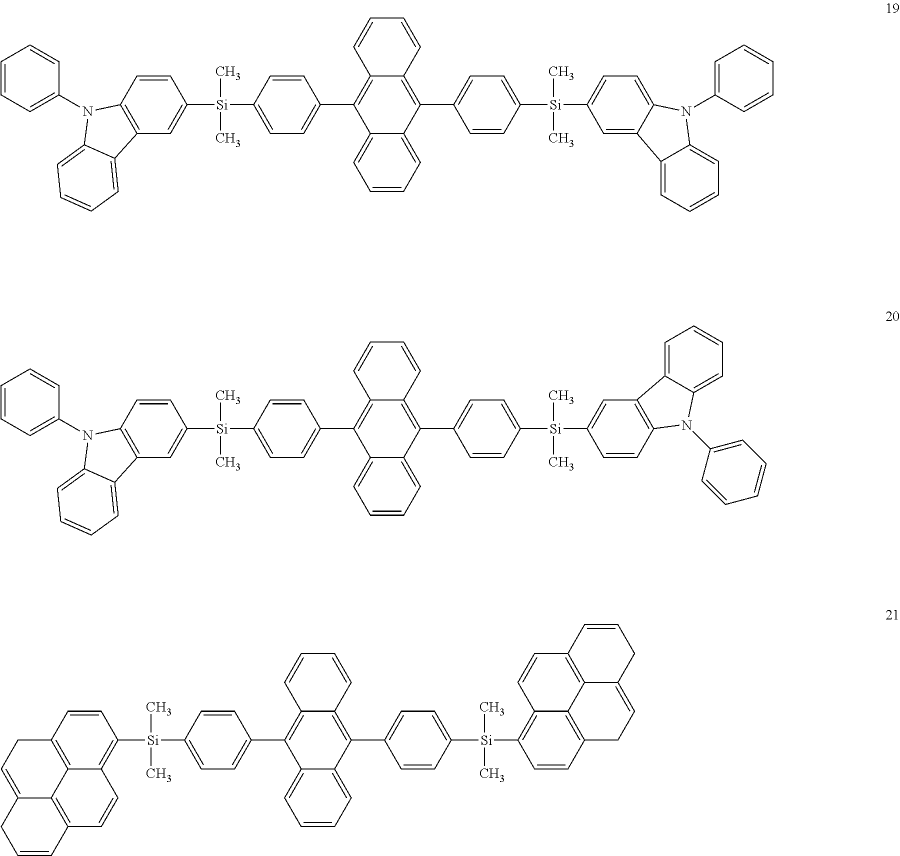 [SMILES: C[Si](C)(c1ccc(-c2c3ccccc3c(-c3ccc([Si](C)(C)c4ccc5c(c4)c4ccccc4n5-c4ccccc4)cc3)c3ccccc23)cc1)c1ccc2c(c1)c1ccccc1n2-c1ccccc1 ; C[Si](C)(c1ccc(-c2c3ccccc3c(-c3ccc([Si](C)(C)c4ccc5c(c4)c4ccccc4n5-c4ccccc4)cc3)c3ccccc23)cc1)c1ccc2c(c1)c1ccccc1n2-c1ccccc1 ; C[Si](C)(c1ccc(-c2c3ccccc3c(-c3ccc([Si](C)(C)c4ccc5c6c7c(ccc46)C=CCC7=CC5)cc3)c3ccccc23)cc1)c1ccc2c3c4c(ccc13)C=CCC4=CC2]

In Formula 20, R₄₁ and R₄₂ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, or a substituted or unsubstituted C₂-C₆₀ heteroaryl group.

For example, in Formula 20, R₄₁ and R₄₂ may each independently be:

a C₁-C₂₀ alkyl group, a C₁-C₂₀ alkoxy group, a phenyl group, a naphthyl group, an anthracenyl group, a pyrenyl group, or a chrysenyl group; or

a C₁-C₂₀ alkyl group, a C₁-C₂₀ alkoxy group, a phenyl group, a naphthyl group, an anthracenyl group, a pyrenyl group, or a chrysenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyrenyl group, or a chrysenyl group.

For example, in Formula 20, R₄₁ and R₄₂ may each independently be a methyl group, an ethyl group, a propyl group, a butyl group, a pentyl group, a phenyl group, a naphthyl group, or an anthracenyl group.

In Formula 20, ia indicates the number of Ar₁s, and may be an integer of 0 to 3. If ia is 0, N of —N(Ar₃)(Ar₄) is directly bonded to the core of the compound represented by Formula 20. If ia is 2 or greater, the at least two Ar₁s may be the same or different. Also, ja indicates the number of Ar₂s, and may be an integer of 0 to 3. If ja is 0, N of —N(Ar₅)(Ar₆) is directly bonded to the core of the compound represented by Formula 20. If ja is 2 or greater, the at least two Ar₂s may be the same or different.

In Formula 20, ib and jb may each independently be an integer of 0 to 3, and ib+jb≧1. For example, in Formula 20, ib and jb may each independently be 0, 1, or 2, and ib+jb≧1. In some embodiments, in Formula 20, both ib and jb may be 1.

In some embodiments, in Formula 20, ia=0 & ja=0; or ia=1 & ja=0; or ia=0 & ja=1; or ia=1 & ja=1.

In Formula 20, Ar₃ to Ar₆ may each independently be a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, or a substituted or unsubstituted C₂-C₆₀ heteroaryl group.

For example, in Formula 20, Ar₃ to Ar₆ may each independently be:

a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group; or

a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₁-C₆₀ fluoroalkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C⁶⁰ aryloxy group, a C₆-C₆₀ arylthio group, a C₂-C₆₀ heteroaryl group, —N(Q_{11c})(Q_{12c}), or —Si(Q_{13c})(Q_{14c})(Q_{15c}) (where Q11c through Q15c are each independently a hydrogen atom, a C₁-C₁₀ alkyl group, a C₆-C₂₀ aryl group, or a C₂-C₂₀ heteroaryl group).

In particular, in Formula 20, Ar₃ to Ar₆ may each independently be a phenyl group, a naphthyl group, an azulenyl group, a heptalenyl group, a biphenylenyl group, an indacenyl group, an acenaphthalenyl group, a fluorenyl group, a spiro-fluorenyl group, an anthracenyl group, a phenalenyl group, a phenanthrenyl group, a perylenyl group, a fluoranthenyl group, a naphthacenyl group, a picenyl group, a pentaphenyl group, or a hexacenyl group; or

a phenyl group, a naphthyl group, an azulenyl group, a heptalenyl group, a biphenylenyl group, an indacenyl group, an acenaphthalenyl group, a fluorenyl group, a spiro-fluorenyl group, an anthracenyl group, a phenalenyl group, a phenanthrenyl group, a perylenyl group, a fluoranthenyl group, a naphthacenyl group, a picenyl group, a pentaphenyl group, or a hexacenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ fluoroalkyl group, a C₁-C₂₀ alkoxy group, a phenyl group, a naphthyl group, an anthracenyl group, or —Si(Q_{13c})(Q_{14c})(Q_{15c}) (where Q_{13c} to Q_{15c} are each independently a C₁-C₂₀ alkyl group, a phenyl group, a naphthyl group, or an anthracenyl group).

In some embodiments, the amine-based compound may be represented by Formula 20-1 below.

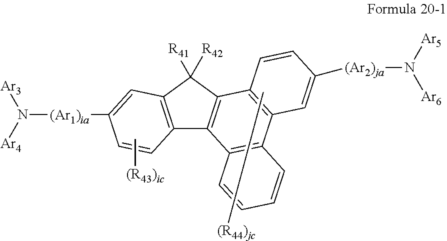

In Formula 20-1, R₄₁ to R₄₄, Ar₁ to Ar₆, ia, and ja are as defined above.

In Formula 20-1, ic is an integer of 0 to 3, and jc is an integer of 0 to 7. In some embodiments, in Formula 20-1, ic and jc may each independently be 0, 1, or 2. In some other embodiments, in Formula 20-1, ic and jc may each be 0.

For example, in Formula 20-1, R₄₁ and R₄₂ may each independently be:

a C₁-C₂₀ alkyl group, a C₁-C₂₀ alkoxy group, a phenyl group, a naphthyl group, an anthracenyl group, a pyrenyl group, or a chrysenyl group; or

a C₁-C₂₀ alkyl group, a C₁-C₂₀ alkoxy group, a phenyl group, a naphthyl group, an anthracenyl group, a pyrenyl group, or a chrysenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyrenyl group, or a chrysenyl group.

Also, R₄₃ and R₄₄ may each independently be:

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyrenyl group, or a chrysenyl group.

Ar₁ and Ar₂ may each independently be:

a cyclopropylene group, a cyclobutylene group, a cyclopentylene group, a cyclohexylene group, a cycloheptylene group, a cyclooctylene group, a cyclopentenylene group, a cyclopentadienylene group, a cyclohexenylene group, a cyclohexadienylene group, a cycloheptadienylene group, a thiophenylene group, a furanylene group, a pyrrolylene group, an imidazolylene group, a pyrazolylene group, an isothiazolylene group, an isoxazolylene group, a thiazolylene group, an oxazolylene group, an oxadiazolylene group, a thiadiazolylene group, a triazolylene group, a phenylene group, a pyridinylene group, a pyrazinylene group, a pyrimidinylene group, a pyridazinylene group, a triazinylene group, a pentalenylene group, an indenylene group, a naphthylene group, an azulenylene group, a heptalenylene group, a biphenylenylene group, an indacenylene group, an acenaphthalenylene group, a fluorenylene group, a spiro-fluorenylene group, a carbazolylene group, an anthracenylene group, a phenalenylene group, a phenanthrenylene group, a perylenylene group, a fluoranthenylene group, a naphthacenylene group, a picenylene group, a pentaphenylene group, a hexacenylene group, a dibenzofuranylene group, a phenothiazinylene group, a phenoxazinylene group, a dihydrophenazinylene group, a phenoxathiinylene group, or a phenanthridinylene group; or

a cyclopropylene group, a cyclobutylene group, a cyclopentylene group, a cyclohexylene group, a cycloheptylene group, a cyclooctylene group, a cyclopentenylene group, a cyclopentadienylene group, a cyclohexenylene group, a cyclohexadienylene group, a cycloheptadienylene group, a thiophenylene group, a furanylene group, a pyrrolylene group, an imidazolylene group, a pyrazolylene group, an isothiazolylene group, an isoxazolylene group, a thiazolylene group, an oxazolylene group, an oxadiazolylene group, a thiadiazolylene group, a triazolylene group, a phenylene group, a pyridinylene group, a pyrazinylene group, a pyrimidinylene group, a pyridazinylene group, a triazinylene group, a pentalenylene group, an indenylene group, a naphthylene group, an azulenylene group, a heptalenylene group, a biphenylenylene group, an indacenylene group, an acenaphthalenylene group, a fluorenylene group, a spiro-fluorenylene group, a carbazolylene group, an anthracenylene group, a phenalenylene group, a phenanthrenylene group, a perylenylene group, a fluoranthenylene group, a naphthacenylene group, a picenylene group, a pentaphenylene group, a hexacenylene group, a dibenzofuranylene group, a phenothiazinylene group, a phenoxazinylene group, a dihydrophenazinylene group, a phenoxathiinylene group, or a phenanthridinylene group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q_{11b})(Q_{12b}) (where Q_{11b} and Q_{12b} may each independently be a hydrogen atom, a C₁-C₁₀ alkyl group, a C₆-C₂₀ aryl group, or a C₂-C₂₀ heteroaryl group).

Ar₃ to Ar₆ may each independently be:

a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fiuorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group; or

a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₁-C₆₀ fluoroalkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, —N(Q_{11c})(Q_{12c}), or —Si(Q_{13c})(Q_{14c})(Q_{15c}) (where Q_{11c} through Q_{15c} are each independently a hydrogen atom, a C₁-C₁₀ alkyl group, a C₆-C₂₀ aryl group, or a C₂-C₂₀ heteroaryl group).

In some other embodiments, in Formula 20-1, R₄₁ and R₄₂ may each independently be a methyl group, an ethyl group, a propyl group, a butyl group, a pentyl group, a phenyl group, a naphthyl group, or an anthracenyl group.

R₄₃ and R₄₄ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyrenyl group, or a chrysenyl group.

Ar₁ and Ar₂ may each independently be a group represented by one of Formulae 5A to 5J.

Ar₃ to Ar₆ may each independently be:

a phenyl group, a naphthyl group, an azulenyl group, a heptalenyl group, a biphenylenyl group, an indacenyl group, an acenaphthalenyl group, a fluorenyl group, a spiro-fluorenyl group, an anthracenyl group, a phenalenyl group, a phenanthrenyl group, a perylenyl group, a fluoranthenyl group, a naphthacenyl group, a picenyl group, a pentaphenyl group, or a hexacenyl group; or

a phenyl group, a naphthyl group, an azulenyl group, a heptalenyl group, a biphenylenyl group, an indacenyl group, an acenaphthalenyl group, a fluorenyl group, a spiro-fluorenyl group, an anthracenyl group, a phenalenyl group, a phenanthrenyl group, a perylenyl group, a fluoranthenyl group, a naphthacenyl group, a picenyl group, a pentaphenyl group, or a hexacenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ fluoroalkyl group, a C₁-C₂₀ alkoxy group, a phenyl group, a naphthyl group, an anthracenyl group, or —Si(Q_{13c})(Q_{14c})(Q_{15c}) (where Q_{13c} to Q_{15c} are each independently a C₁-C₂₀ alkyl group, a phenyl group, a naphthyl group, or an anthracenyl group).

Also, ia=0 & ja=0; or ia=1 & ja=0; or ia=0 & ja=1; or ia=1 & ja=1.

In some embodiments, the amine-based compound may be one of Compounds 25 to 116 below, but the amine-based compound is not limited thereto.

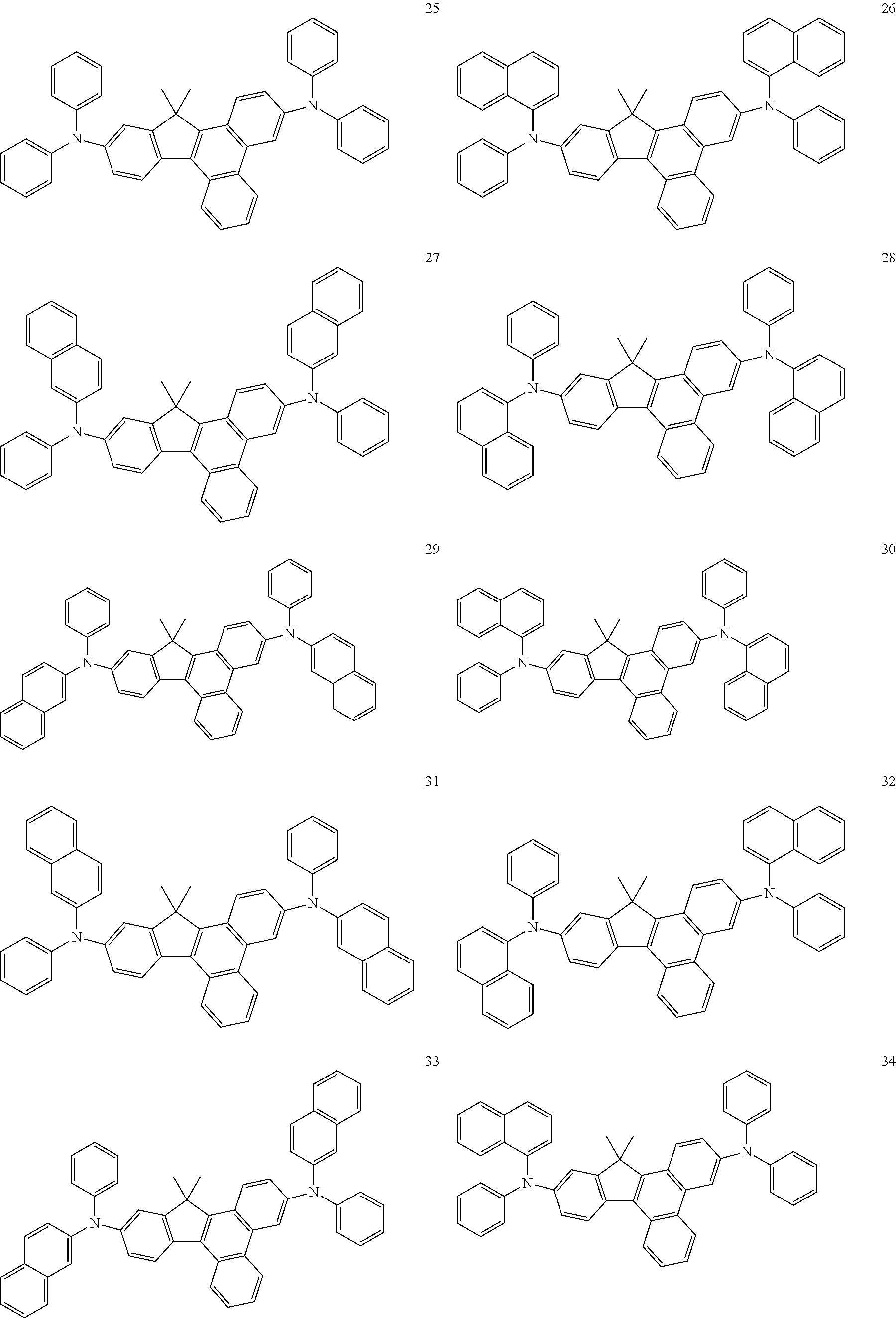

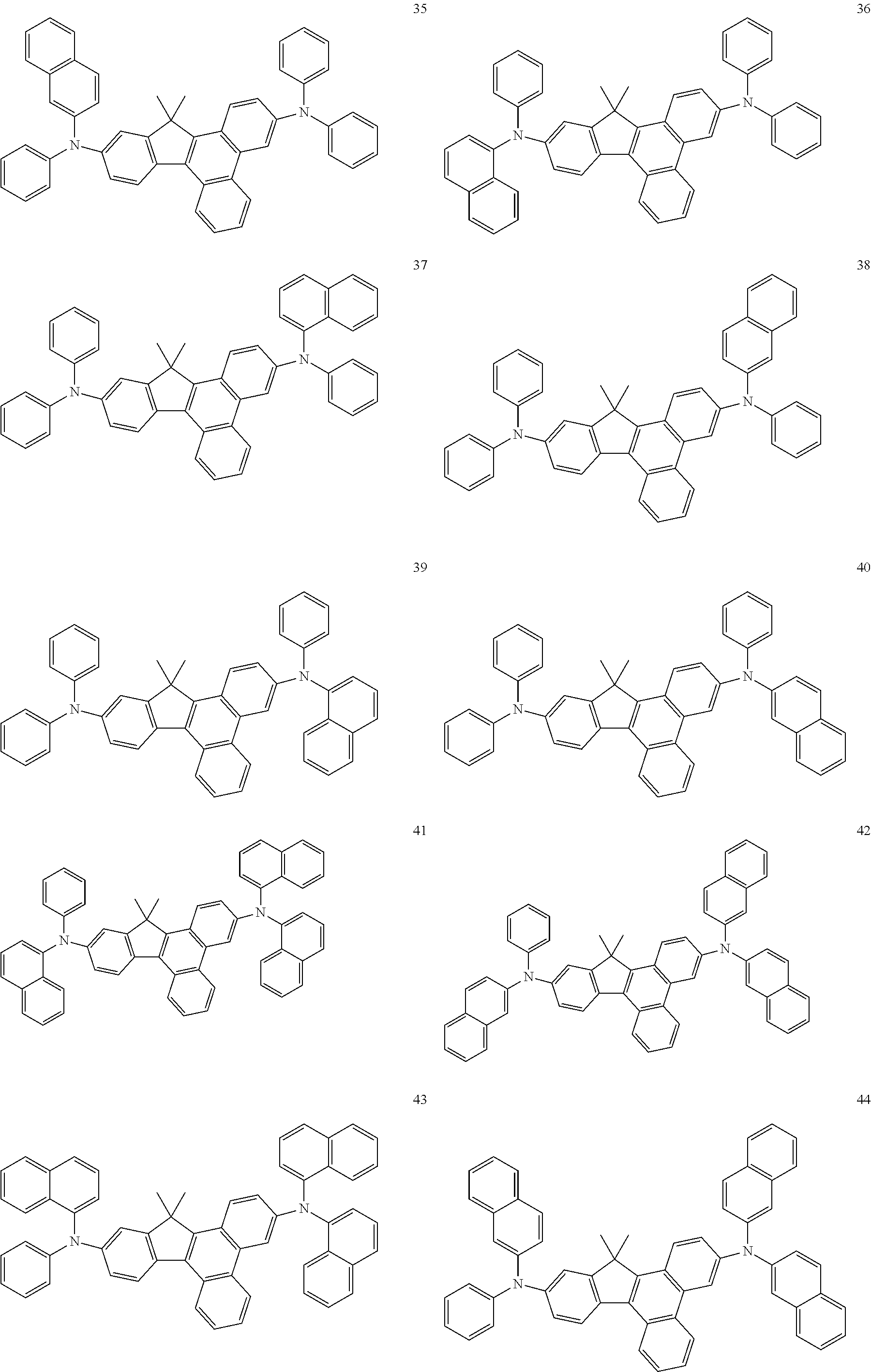

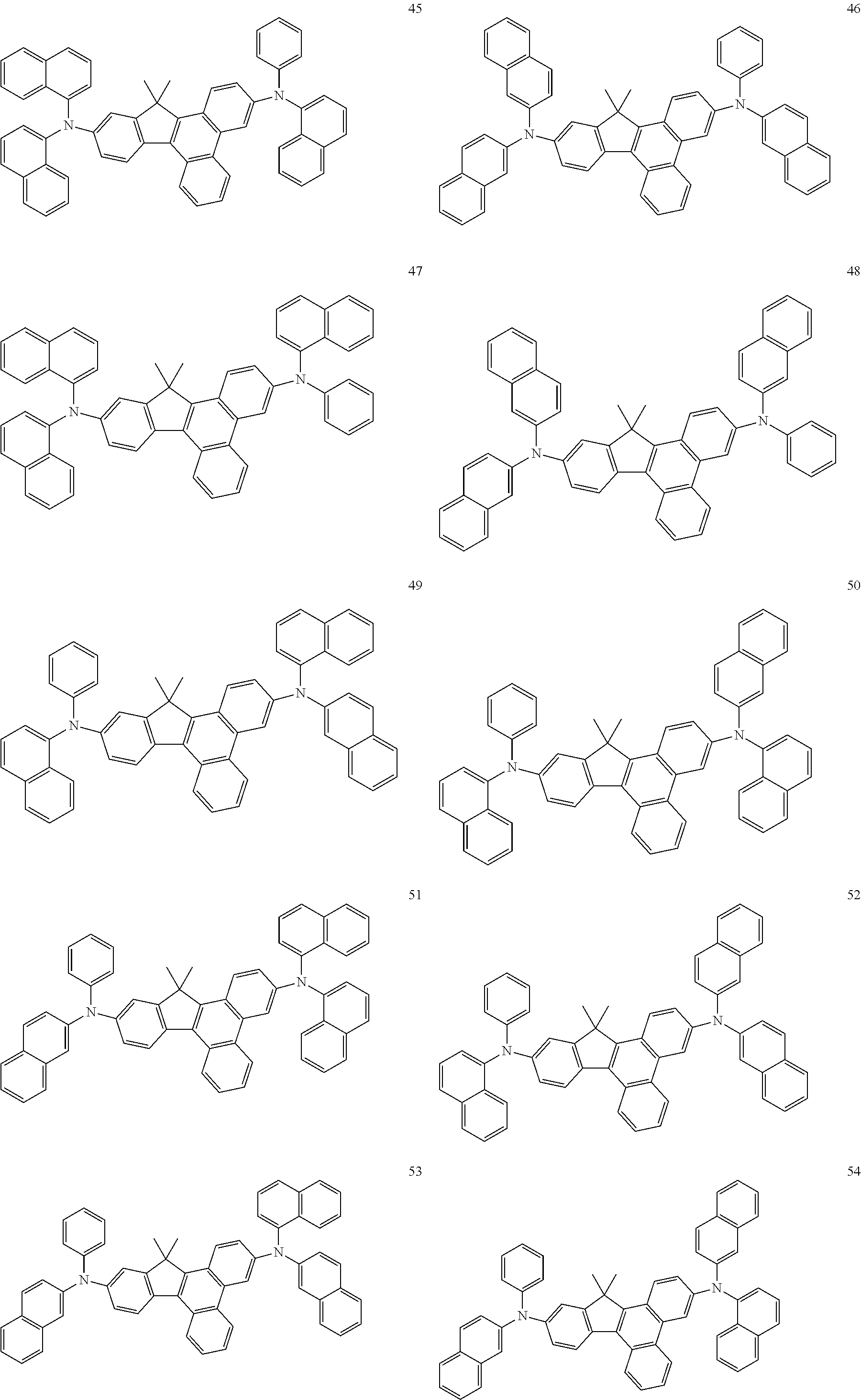

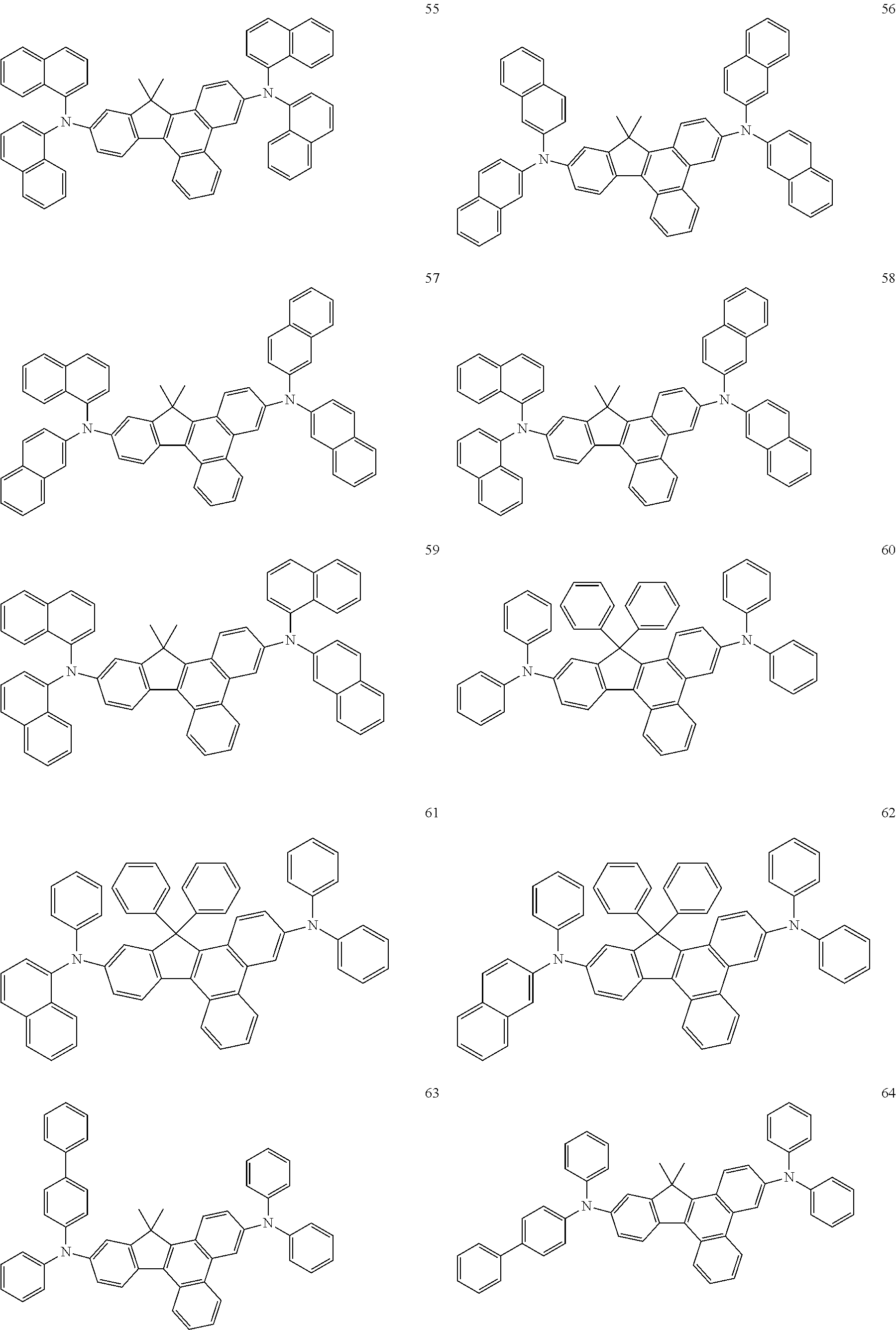

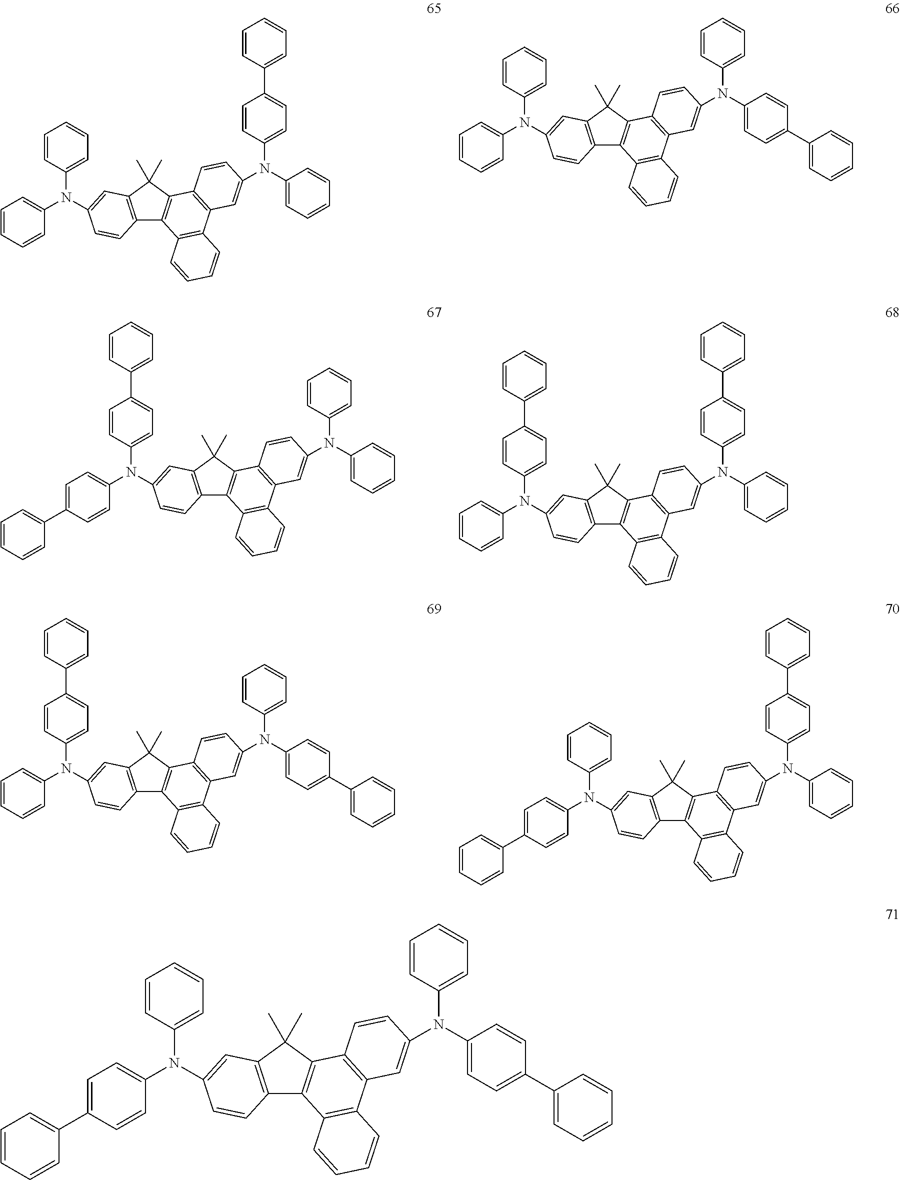

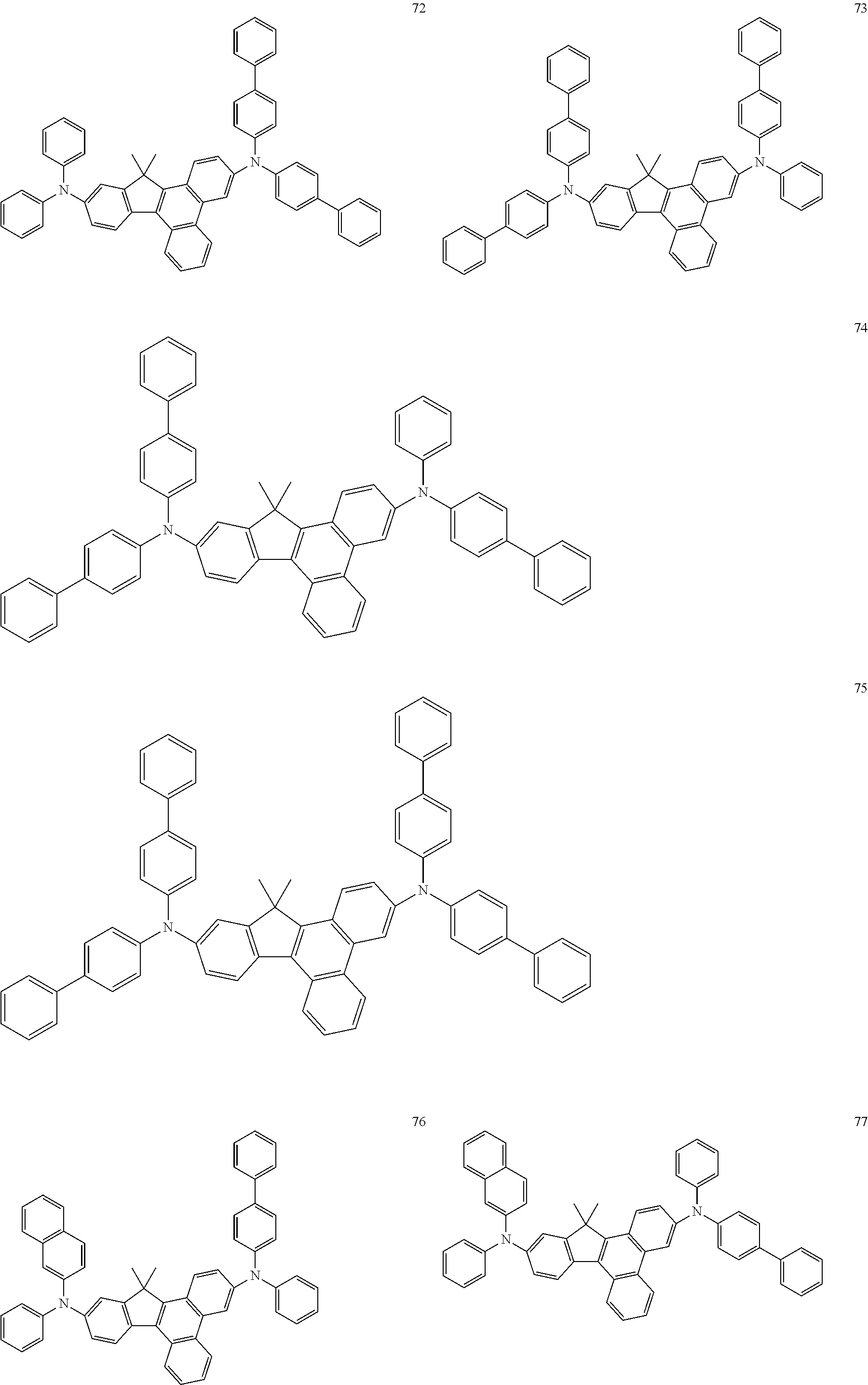

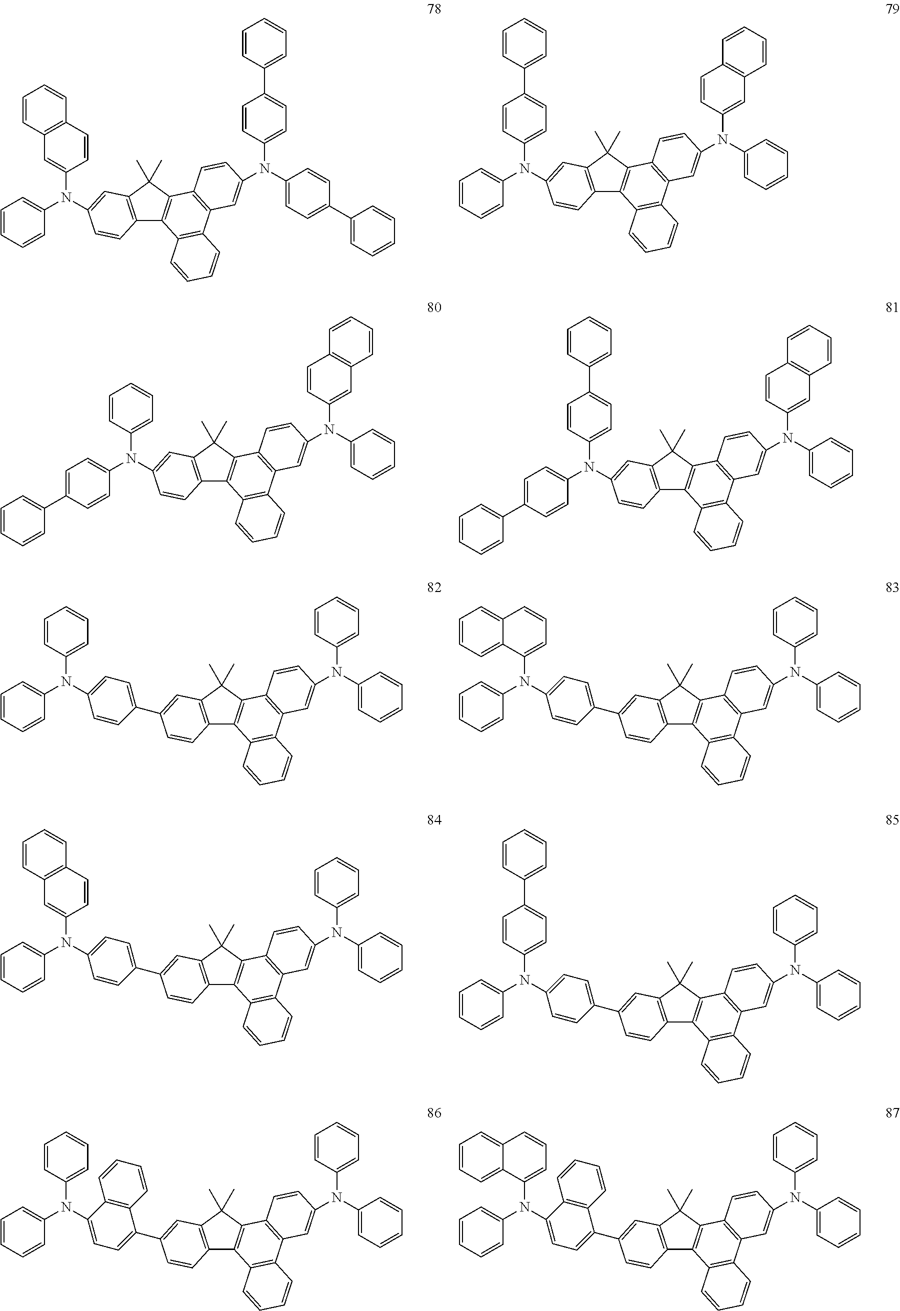

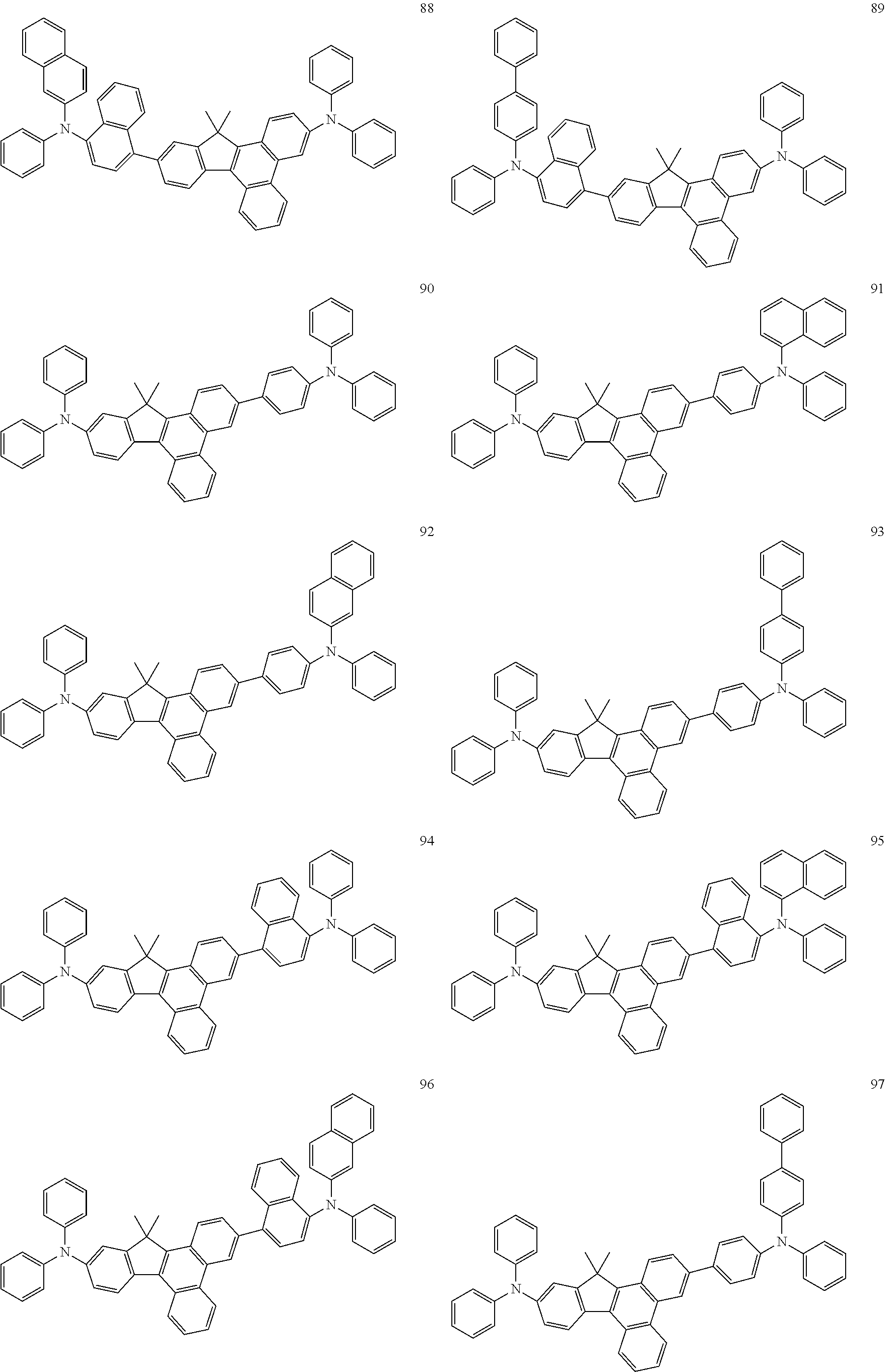

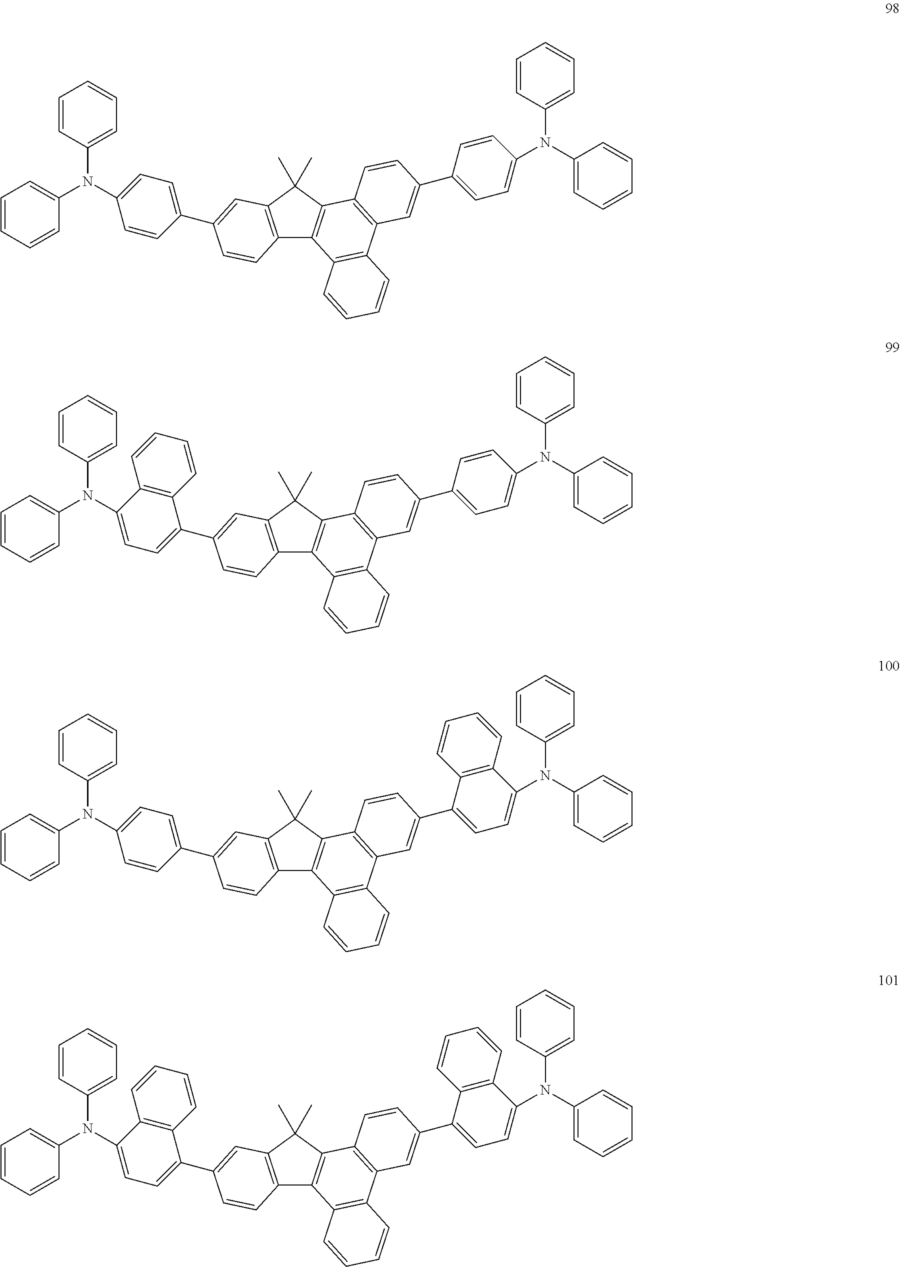 [SMILES: CC1(C)c2cc(-c3ccc(N(c4ccccc4)c4ccccc4)cc3)ccc2-c2c1c1ccc(-c3ccc(N(c4ccccc4)c4ccccc4)cc3)cc1c1ccccc21 ; CC1(C)c2cc(-c3ccc(N(c4ccccc4)c4ccccc4)c4ccccc34)ccc2-c2c1c1ccc(-c3ccc(N(c4ccccc4)c4ccccc4)cc3)cc1c1ccccc21 ; CC1(C)c2cc(-c3ccc(N(c4ccccc4)c4ccccc4)cc3)ccc2-c2c1c1ccc(-c3ccc(N(c4ccccc4)c4ccccc4)c4ccccc34)cc1c1ccccc21 ; CC1(C)c2cc(-c3ccc(N(c4ccccc4)c4ccccc4)c4ccccc34)ccc2-c2c1c1ccc(-c3ccc(N(c4ccccc4)c4ccccc4)c4ccccc34)cc1c1ccccc21]

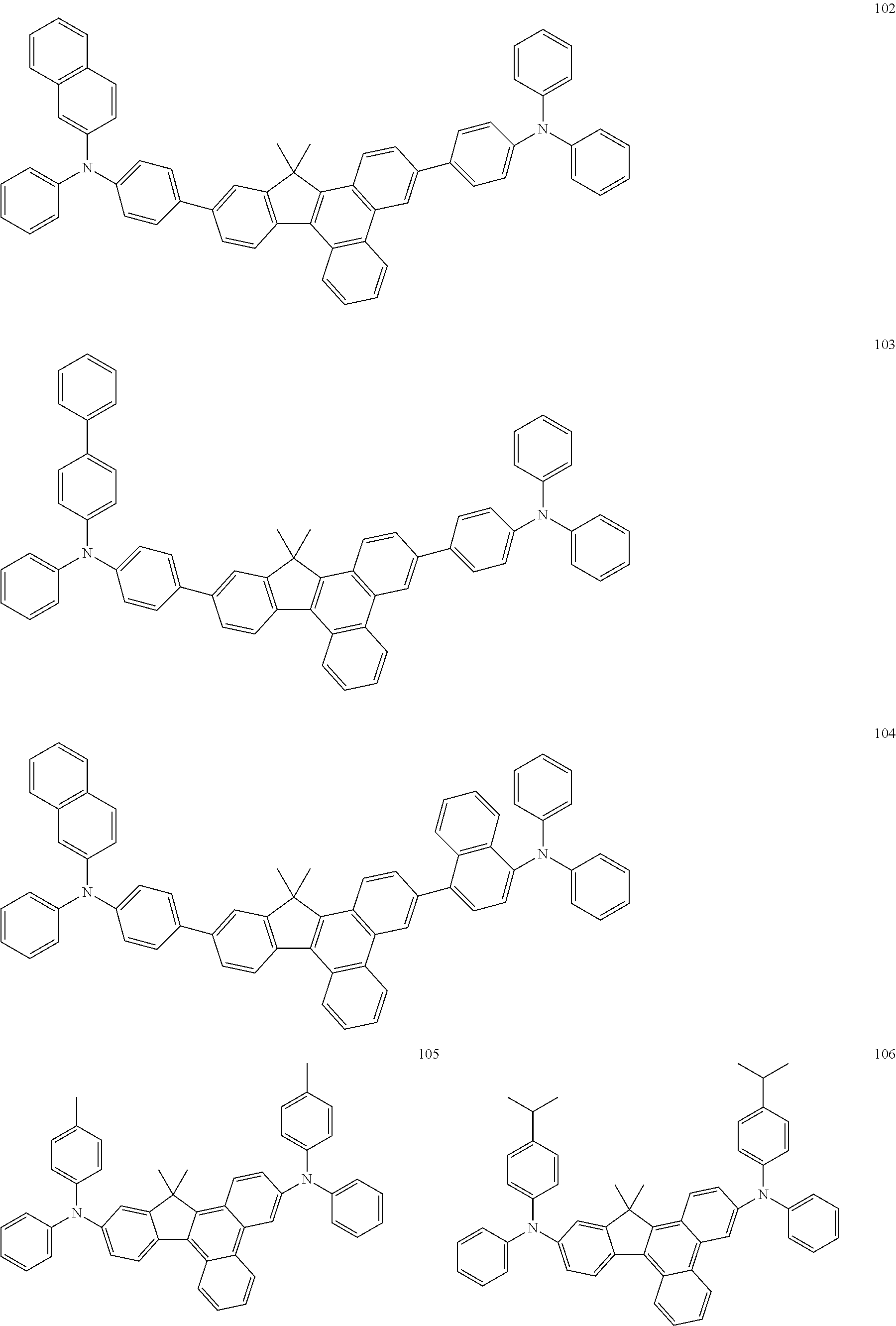

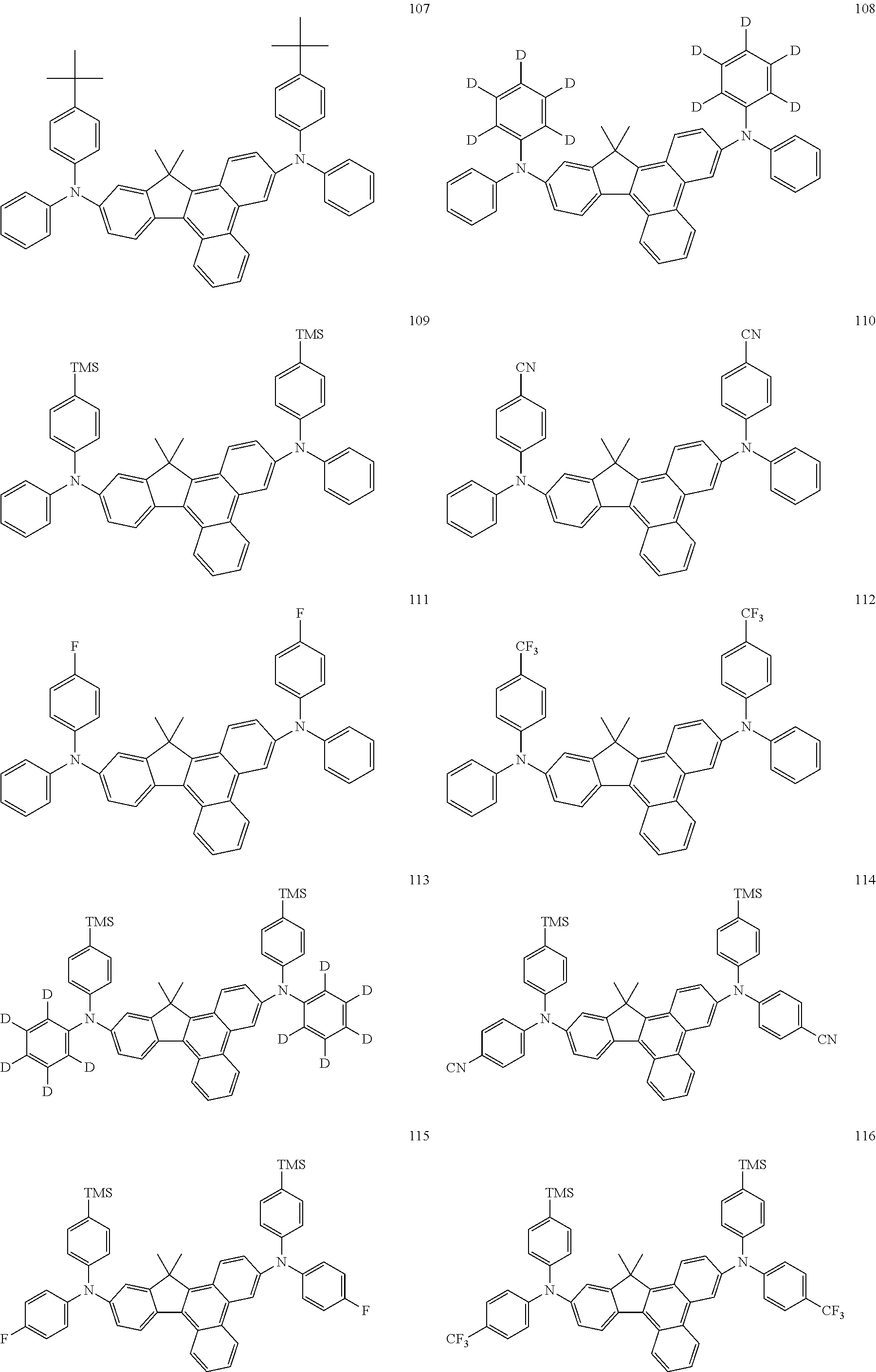

The EML may include one of Compounds 1 to 24 as the anthracene-based compound and one of Compounds 25 to 116 as the amine-based compound, but the EML is not limited thereto.

The anthracene-based compound represented by Formula 1 includes “a substituted or unsubstituted condensed ring group in which at least two rings are fused to each other” as a Si substituent, and thus may have a cascade structure with high light-emitting efficiency. Therefore, when the anthracene-based compound of Formula 1 is used as a host in an EML of an organic light-emitting diode, the organic light-emitting diode may have high efficiency and a long lifetime. When the anthracene-based compound of Formula 1 is used as a host, and the amine-based compound of Formula 20 is used as a dopant, these two compounds may have high energy transfer efficiency. Thus, an organic light-emitting diode including an EML including both the anthracene-based compound represented by Formula 1 and the amine-based compound represented by Formula 20 may have high light-emitting efficiency and improved lifetime characteristics.

When the organic light-emitting diode is a full color organic light-emitting diode, the EML may be patterned into a red EML, a green EML, and a blue EML. In some embodiments, the EML may include at least two of the red EML, the green EML and the blue EML stacked on one another, and thus may emit white light. The blue EML may include a host and a dopant, as described above.

At least one of the red EML and the green EML may include a dopant, nonlimiting examples of which are noted below (ppy=phenylpyridine).

Nonlimiting examples of the red dopant include compounds represented by the formulae below. In an embodiment, the red dopant may be DCM or DCJTB (represented below).

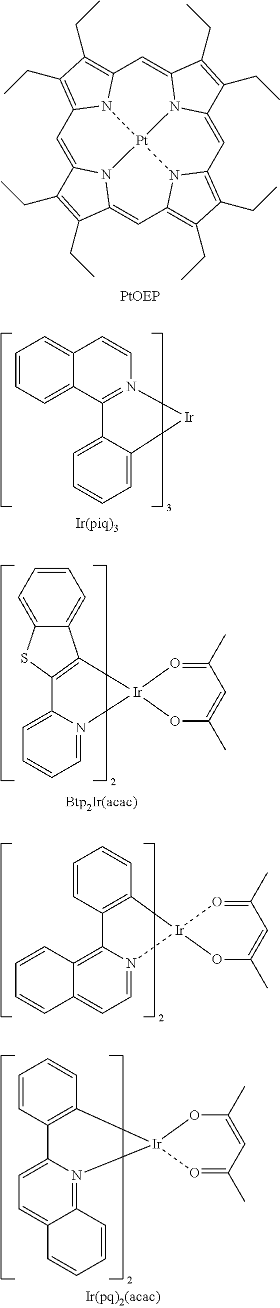

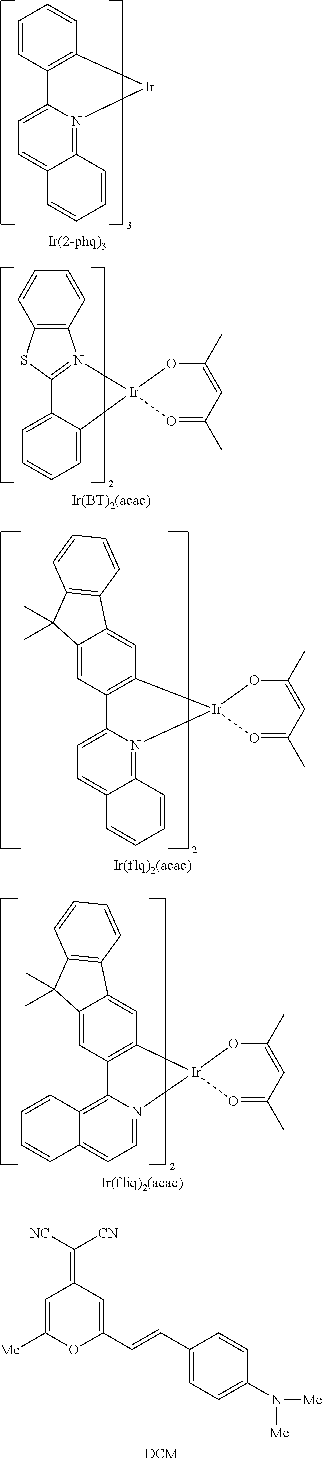

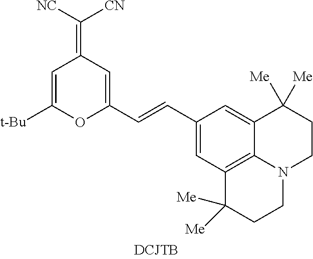 [SMILES: CC(C)(C)C1=CC(=C(C#N)C#N)C=C(/C=C/c2cc3c4c(c2)C(C)(C)CCN4CCC3(C)C)O1]

Nonlimiting examples of the green dopant include compounds represented by the formulae below. In an embodiment, the green dopant may be C545T (represented below).

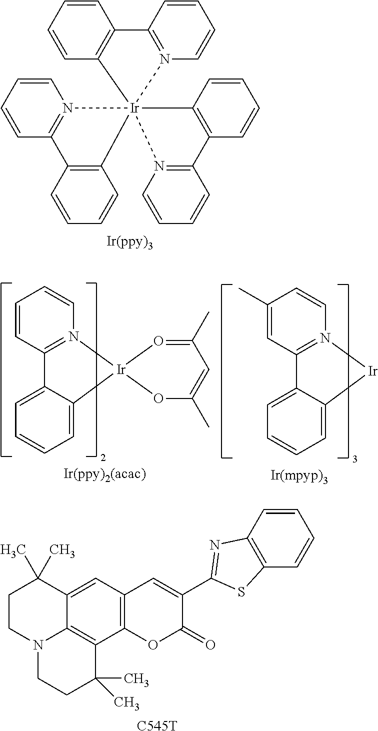

The thickness of the EML may be about 100 Å to about 1000 Å, and in some embodiments, may be about 200 Å to about 600 Å. When the thickness of the EML is within these ranges, the EML may have good light emitting ability without a substantial increase in driving voltage.

Then, an ETL may be formed on the EML by vacuum deposition, spin coating, casting, or the like. When the ETL is formed using vacuum deposition or spin coating, the deposition or coating conditions may be similar to those for the formation of the HIL, though the deposition or coating conditions may vary according to the compound that is used to form the ETL.

The material for forming the ETL may be any material that can stably transport electrons injected from an electron injecting electrode (cathode). Nonlimiting examples of materials for forming the ETL include quinoline derivatives, such as tris(8-quinolinorate)aluminum (Alq3), TAZ, BAlq, beryllium bis(benzoquinolin-10-olate) (Bebq₂), 9,10-di(naphthalene-2-yl)anthracene (ADN), Compound 201, and Compound 202.

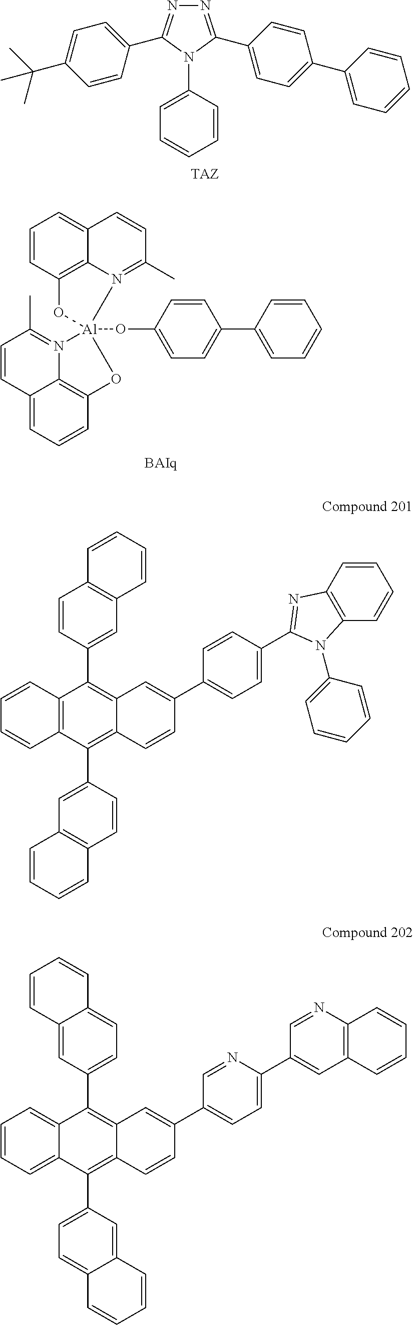

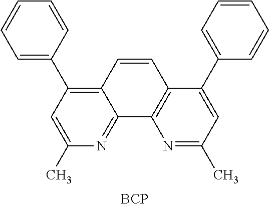

The thickness of the ETL may be about 100 Å to about 1,000 Å, and in some embodiments, may be about 150 Å to about 500 Å. When the thickness of the ETL is within these ranges, the ETL may have satisfactory electron transporting ability without a substantial increase in driving voltage.

In addition to the electron-transporting organic compound, in some embodiments, the ETL may further include a metal-containing material. The metal-containing material may include a lithium (Li) complex. Nonlimiting examples of the Li complex include lithium quinolate (LiQ) and Compound 203 below:

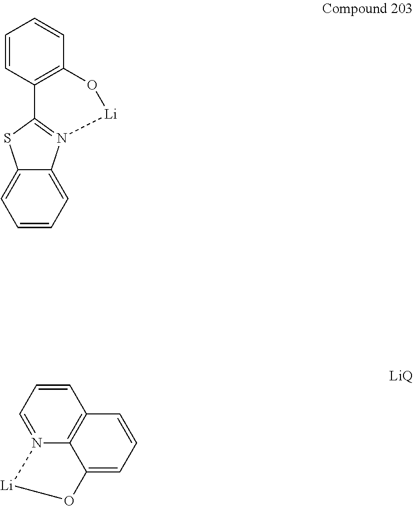

Then, an EIL, which facilitates injection of electrons from the cathode, may be formed on the ETL. Any suitable electron-injecting material may be used to form the EIL. Nonlimiting examples of materials for forming the EIL include LiF, NaCl, CsF, Li2O, and BaO.

The deposition or coating conditions for forming the EIL may be similar to those for the formation of the HIL, though the deposition or coating conditions may vary according to the material that is used to form the EIL.

The thickness of the EIL may be about 1 Å to about 100 Å, and in some embodiments, may be about 3 Å to about 90 Å. When the thickness of the EIL is within these ranges, the EIL may have satisfactory electron injection ability without a substantial increase in driving voltage.

The second electrode 17 is disposed on the organic layer 15. The second electrode 17 may be a cathode, i.e. an electron injection electrode. A material for forming the second electrode 17 may be a metal, an alloy, or an electro-conductive compound, all of which have low work functions, or a mixture thereof. For example, the second electrode 17 may be formed of lithium (Li), magnesium (Mg), aluminum (Al), aluminum (AI)-lithium (Li), calcium (Ca), magnesium (Mg)-indium (In), magnesium (Mg)-silver (Ag), or the like, and may be formed as a thin film type transmissive electrode. In some embodiments, to manufacture a top-emission light-emitting diode, the transmission electrode may be formed of indium tin oxide (ITO) or indium zinc oxide (IZO).

Although the organic light-emitting diode has been described with reference to FIG. 1, the present invention is not limited thereto.

When a phosphorescent dopant is used in the EML, an HBL may be formed between the HTL and the EML or between the H-functional layer and the EML in order to prevent diffusion of triplet excitons or holes into the ETL. The HBL may be formed by vacuum deposition, spin coating, casting, LB deposition, or the like. When the HBL is formed using vacuum deposition or spin coating, the conditions for deposition or coating may be similar to those for the formation of the HIL, although the conditions for deposition or coating may vary according to the material that is used to form the HBL. Any known hole-blocking material may be used. Nonlimiting examples of hole-blocking materials include oxadiazole derivatives, triazole derivatives, and phenanthroline derivatives. For example, bathocuproine (BCP) (represented by the following formula) may be used as a material for forming the HBL:

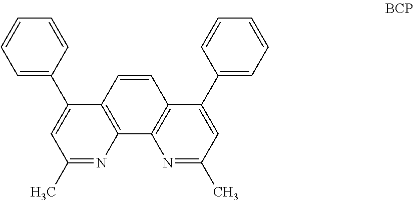 [SMILES: Cc1cc(-c2ccccc2)c2ccc3c(-c4ccccc4)cc(C)nc3c2n1]

The thickness of the HBL may be about 20 Å to about 1000 Å, and in some embodiments, may be about 30 Å to about 300 Å. When the thickness of the HBL is within these ranges, the HBL may have improved hole blocking ability without a substantial increase in driving voltage.

Nonlimiting examples of the unsubstituted C₁-C₆₀ alkyl group used herein include linear or branched C₁-C₆₀ alkyl groups, such as methyl, ethyl, propyl, isobutyl, sec-butyl, pentyl, iso-amyl, hexyl, or the like. In the substituted C₁-C₆₀ alkyl group, at least one hydrogen atom of the unsubstituted C₁-C₆₀ alkyl group described above is substituted with a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₁-C₆₀ fluoroalkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, —N(Q₁₁)(Q₁₂), or —Si(Q₁₃)(Q₁₄)(Q₁₅) (where Q₁₁ to Q₁₅ are each independently a hydrogen atom, a C₁-C₆₀ alkyl group, a C₂-C₆₀ alkenyl group, a C₂-C₆₀ alkynyl group, a C₆-C₆₀ aryl group, or a C₂-C₆₀ heteroaryl group).

As used herein, the description of Q₁₁ applies also to Q₁₁ₐ, Q_{11b}, and Q_{11c}, the description of Q₁₂ applies also to Q₁₂ₐ, Q_{12b}, and Q_{12c}, the description of Q₁₃ applies also to Q₁₃ₐ, Q_{13b}, and Q_{13c}, the description of Q₁₄ applies also to Q₁₄ₐ, Q_{14b}, and Q_{14c}, and the description of Q₁₅ applies also to Q₁₅ₐ, Q_{15b}, and Q_{15c}.

As used herein, the unsubstituted C₁-C₆₀ alkoxy group may be a group represented by —OA, where A is an unsubstituted C₁-C₆₀ alkyl group. Nonlimiting examples of the unsubstituted C₁-C₆₀ alkoxy group include a methoxy group, an ethoxy group, and an isopropyloxy group. The substituted C₁-C₆₀ alkoxy group refers to the substitution of at least one of the hydrogen atoms in the alkoxy group with the substituents described above in connection with the substituted C₁-C₆₀ alkyl group.

As used herein, the unsubstituted C₂-C₆₀ alkenyl group is a hydrocarbon chain having a carbon-carbon double bond in the center or at a terminal end of the unsubstituted C₂-C₆₀ alkyl group. Nonlimiting examples of the unsubstituted C₂-C₆₀ alkenyl group include ethenyl, propenyl, and butenyl groups. The substituted C₂-C₆₀ alkenyl group refers to the substitution of at least one hydrogen atom in the unsubstituted C₂-C60 alkenyl group with the substituents described above in connection with the substituted C₁-C60 alkyl group.

As used herein, the unsubstituted C₂-C₆₀ alkynyl group is a hydrocarbon chain having at least one carbon-carbon triple bond in the center or at a terminal end thereof. Nonlimiting examples of the unsubstituted C₂-C₆₀ alkynyl group include an ethenyl group, a propenyl group, a butenyl group, and the like. The substituted C₂-C₆₀ alkynyl group refers to the substitution of at least one hydrogen atom in the alkynyl group with the substituents described above in connection with the C₁-C₆₀ alkyl group.

As used herein, the unsubstituted C₆-C₆₀ aryl group is a monovalent group having a carbocyclic aromatic system having 6 to 60 carbon atoms and including at least one aromatic ring. The unsubstituted C₆-C₆₀ arylene group is a bivalent group having a carbocyclic aromatic system having 6 to 60 carbon atoms and including at least one aromatic ring. When the aryl group and the arylene group have at least two rings, they may be fused to each other or connected via a single bond. The substituted C₆-C₆₀ aryl group and substituted C₆-C₆₀ arylene group refer to the substitution of at least one hydrogen atom in the aryl group or arylene group, respectively, with the substituents described above in connection with the C₁-C₆₀ alkyl group.

Nonlimiting examples of the substituted or unsubstituted C₆-C₆₀ aryl group include a phenyl group, a C₁-C₁₀ alkylphenyl group (e.g., an ethylphenyl group), a C₁-C₁₀ alkylbiphenyl group (e.g., an ethylbiphenyl group), a halophenyl group (e.g., an o-, m-, or p-fluorophenyl group or a dichlorophenyl group), a dicyanophenyl group, a trifluoromethoxyphenyl group, an o-, m-, or p-tolyl group, an o-, m-, or p-cumenyl group, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (e.g., a fluoronaphthyl group), a C₁-C₁₀ alkylnaphthyl group (e.g., a methylnaphthyl group), a C₁-C₁₀ alkoxynaphthyl group (e.g., a methoxynaphthyl group), an anthracenyl group, an azulenyl group, a heptalenyl group, an acenaphthalenyl group, a phenalenyl group, a fluorenyl group, an anthraquinolinyl group, a methylanthracenyl group, a phenanthrenyl group, a triphenylenyl group, a pyrenyl group, a chrysenyl group, an ethyl-chrysenyl group, a picenyl group, a perylenyl group, a chloroperylenyl group, a pentaphenyl group, a pentacenyl group, a tetraphenylenyl group, a hexaphenyl group, a hexacenyl group, a rubicenyl group, a coronenyl group, a trinaphthalenyl group, a heptaphenyl group, a heptacenyl group, a pyranthrenyl group, an ovalenyl group, and a spiro-fluorenyl group. Nonlimiting examples of the substituted C₆-C₆₀ aryl group may be inferred from the examples of the unsubstituted C₆-C₆₀ aryl group and the substituted C₁-C₆₀ alkyl group described above. Nonlimiting examples of the substituted or unsubstituted C₆-C₆₀ arylene group may be inferred based on the examples of the substituted or unsubstituted C₆-C₆₀ aryl group described above.

As used herein, the unsubstituted C₂-C₆₀ heteroaryl group is a monovalent group having at least one aromatic ring with at least one of heteroatom selected from N, O, P, S, and Si. The unsubstituted C₂-C₆₀ heteroarylene group is a divalent group having at least one aromatic ring with at least one of heteroatom selected from N, O, P, and S. When the unsubstituted C₂-C₆₀ heteroaryl group or the unsubstituted C₂-C₆₀ heteroarylene group has at least two rings, they may be fused to each other or connected via a single bond. The substituted C₂-C₆₀ heteroaryl group and substituted C₂-C₆₀ heteroarylene group refer to the substitution of at least one hydrogen atom in the heteroaryl group and heteroarylene group, respectively, with the substituents described above in connection with the C₁-C₆₀ alkyl group.

Nonlimiting examples of the unsubstituted C₂-C₆₀ heteroaryl group include a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzoimidazolyl group, an imidazopyridinyl group, an imidazopyrimidinyl group, a furanyl group, a thiophenyl group, a benzofuranyl group, a benzothiophenyl group, a dibenzofuranyl group, and a dibenzothiophenyl group. Nonlimiting examples of the substituted C₂-C₆₀ heteroaryl group may be inferred from the examples of the unsubstituted C₂-C₆₀ arylene group described above and the substituted alkyl group described above. Nonlimiting examples of the substituted and unsubstituted C₂-C₆₀ heteroarylene group may be inferred based on the examples of the substituted or unsubstituted C₂-C₆₀ arylene group described above and the examples of the substituted alkyl group described above.

The substituted or unsubstituted C₆-C₆₀ aryloxy group may be represented by —OA₂ where A₂ is a substituted or unsubstituted C₆-C₆₀ aryl group, which is described above. The substituted or unsubstituted C₆-C₆₀ arylthiol group is represented by —SA₃ where A₃ is a substituted or unsubstituted C₆-C₆₀ aryl group, which is described above.

Hereinafter, the present invention will be described with reference to the following synthesis examples and other examples. However, these examples are presented for illustrative purposes only and are not intended to limit the scope of the present invention.

### EXAMPLES

### Synthesis Example 1

### Synthesis of Compound 2

### Synthesis of Compound 2-1

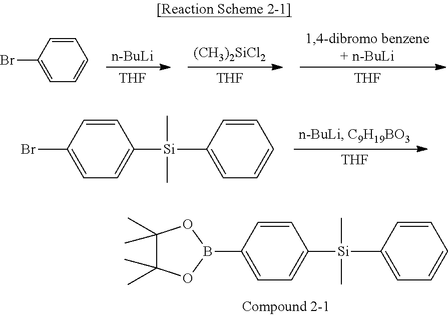

After 12 g (58.25 mmol) of 1-bromobenzene was dissolved in 200 ml of tetrahydrofuran (THF) in a 500-ml 3-necked round flask (flask 1) in a nitrogen atmosphere, 23.65 ml (58.25 mmol) of 2.5M n-BuLi was slowly dropped into the solution at −78° C. and stirred for about 20 minutes while the temperature was maintained. Afterward, 6.93 g (54.17 mmol) of dimethyldichlorosilane was slowly dropwise added into the mixture at −80° C. or less, and the temperature was slowly increased to about −10° C. or less, at which temperature the mixture was further stirred for about 2 hours. After 18.97 g (80.39 mmol) of 1,4-dibromobenzene was dissolved in 200 ml of THF in a 250-ml 3-necked round flask (flask 2) in a nitrogen atmosphere, 32.63 ml (80.39 mmol) of n-BuLi was slowly dropped into the solution at −78° C. and stirred for about 20 minutes while the temperature was maintained. While the temperatures of the reaction products in flasks 1 and 2 were maintained at about −78° C., the reaction product in flask 2 was drawn into a syringe, and dropwise added into flask 1, and then flask 1 was stirred for about 12 hours. After termination of the reaction using water, the reaction product was extracted using chloroform, purified using a silica gel column equipped with a hexane eluent, and then recrystallized using hexane to obtain (4-bromo-phenyl)-dimethyl-phenyl-1-yl-silane. After the (4-bromo-phenyl)-dimethyl-phenyl-1-yl-silane and 250 ml of THF were put in a 500-ml 3-necked round flask, 14.21 ml (35 mmol) of 2.5M n-BuLi was slowly dropped into the solution at −78° C. and stirred for about 40 minutes while the temperature was maintained. Afterward, 6.55 g (35 mmol) of 2-isopropoxy-4,4,5,5,-tetramethyl-1,3,2-dioxaborane was slowly added into the mixture at −78° C. or less and stirred for about 30 minutes, and then further stirred for about 12 hours after the temperature was slowly increased. After termination of the reaction with 10% HCl, the reaction product was extracted using ethylacetate. The extracted organic layer was collected and purified using a silica gel column equipped with a hexane eluent, and then recrystallized using ethylacetate and hexane to obtain 3.94 g (12.65 mmol) of a white solid Compound 2-1 (yield: 20%).

1H NMR (300 MHz, CDCl3) δ: 7.85 (2H), 7.55 (1H), 7.46 (4H), 7.37 (2H), 1.24 (12H), 0.66 (6H)

### Synthesis of Compound 2-2

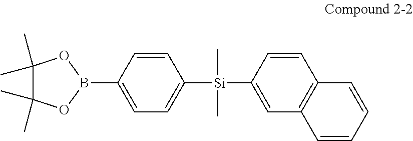 [SMILES: CC1(C)OB(c2ccc([Si](C)(C)c3ccc4ccccc4c3)cc2)OC1(C)C]

Compound 2-2 was synthesized as in the synthesis of Compound 2-1, except that 2-bromonaphthalene was used instead of 1-bromobenzene (white solid, yield: 22%).

1H NMR (300 MHz, CDCl3) δ; 8.10 (1H), 8.00 (2H), 7.95 (1H), 7.85 (2H), 7.60 (1H), 7.59 (2H), 7.46 (2H), 1.24 (12H), 0.66 (6H)

### Synthesis of Compound 2

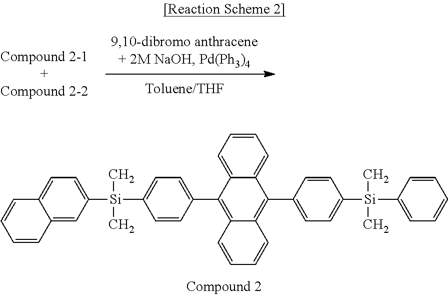 [SMILES: C[Si](C)(c1ccccc1)c1ccc(-c2c3ccccc3c(-c3ccc([Si](C)(C)c4ccc5ccccc5c4)cc3)c3ccccc23)cc1]

After 5 g (14.79 mmol) of Compound 2-1, 5.74 g (14.79 mmol) of Compound 2-2, and 4.28 g (12.86 mmol) of 9,10-dibromoanthracene were added to 300 ml of toluene in a 250-ml 3-necked flask with an addition of 100 ml of 2M NaOH, and reacted for about 30 minutes for nitrogen substitution, a catalytic amount of tetrakis(triphenylphosphine)palladium(0) was added thereto and reacted at about 100° C. for about 36 hours. After termination of the reaction with HCl, the reaction product was filtered, washed several times with acetone, and then dried. The resulting product was subjected to soxhlet extraction with toluene to obtain Compound 2 (white solid, 4.10 g, 6.36 mmol, yield: 43%).

1H NMR (300 MHz, CDCl3) δ; 8.10 (1H), 8.00 (2H), 7.95 (1H), 7.91 (4H), 7.89 (4H), 7.60 (1H), 7.59 (2H), 7.55 (1H), 7.52 (4H), 7.46 (2H), 7.39 (4H), 7.37 (2H), 0.66 (12H)

HRMS (FAB); calcd for C46H36Si2; 644.24, found; 644.95

### Synthesis Example 2

### Synthesis of Compound 6

### Synthesis of Compound 6-1

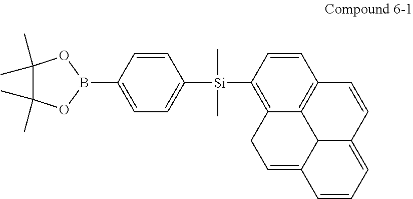 [SMILES: CC1(C)OB(c2ccc([Si](C)(C)c3ccc4c5c3CC=C3C=CC=C(C=C4)C35)cc2)OC1(C)C]

Compound 6-1 was synthesized as in the synthesis of Compound 2-1, except that 1-bromopyrene was used instead of 1-bromobenzene (white solid, yield: 20%).

1H NMR (300 MHz, CDCl3) δ; 7.91 (1H), 7.85 (1H), 7.81 (1H), 7.46 (2H), 7.17 (1H), 7.10 (1H), 6.58 (1H), 6.44 (1H), 6.19 (1H), 6.00 (1H), 1.24 (12H), 0.66 (6H)

### Synthesis of Compound 6

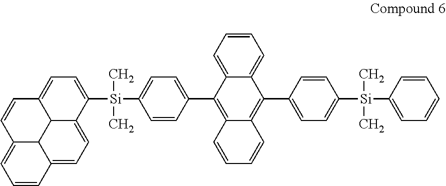 [SMILES: C[Si](C)(C1=CC=C2C=CC3=CC=CC4=CC=C1C2C34)c1ccc(-c2c3ccccc3c(-c3ccc([Si](C)(C)c4ccccc4)cc3)c3ccccc23)cc1]

Compound 6 was synthesized as in the synthesis of Compound 2, except that Compound 6-1 was used instead of Compound 2-2 (yield: 41%).

1H NMR (300 MHz, CDCl3) δ; 7.98 (9H), 7.91 (4H), 7.89 (2H), 7.79 (2H), 7.55 (1H), 7.52 (2H), 7.46 (2H), 7.39 (4H), 7.37 (2H), 7.24 (2H), 4.82 (2H), 0.66 (12H).

HRMS (FAB); calcd for C52H40Si2; 720.27, found; 721.04

### Synthesis Example 3

### Synthesis of Compound 13

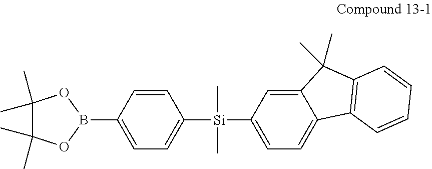 [SMILES: CC1(C)c2ccccc2-c2ccc([Si](C)(C)c3ccc(B4OC(C)(C)C(C)(C)O4)cc3)cc21]

Compound 13-1 was synthesized as in the synthesis of Compound 2-1, except that 2-bromo-(9,9′-dimethyl)fluorene was used instead of 1-bromobenzene (white solid, yield: 18%).

1H NMR (300 MHz, CDCl3) δ; 7.97 (1H), 7.87 (1H), 7.85 (2H), 7.83 (1H), 7.66 (1H), 7.55 (1H), 7.46 (2H), 7.38 (1H), 7.28 (1H), 1.72 (6H), 1.24 (12H), 0.66 (6H)

### Synthesis of Compound 13

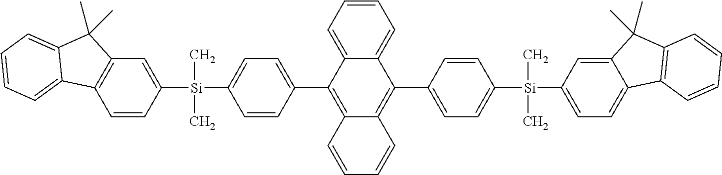 [SMILES: CC1(C)c2ccccc2-c2ccc([Si](C)(C)c3ccc(-c4c5ccccc5c(-c5ccc([Si](C)(C)c6ccc7c(c6)C(C)(C)c6ccccc6-7)cc5)c5ccccc45)cc3)cc21]

Compound 13 was synthesized as in the synthesis of Compound 2, except that Compound 13-1 was used instead of Compound 2-1 and Compound 2-2 (yield: 38%).

1H NMR (300 MHz, CDCl3) δ; 7.97 (2H), 7.91 (4H), 7.89 (4H), 7.87 (2H), 7.83 (2H), 7.66 (2H), 7.55 (2H), 7.52 (4H), 7.39 (4H), 7.38 (2H), 7.28 (2H), 1.72 (12H), 0.66 (12H).

HRMS (FAB); calcd for C60H50Si2; 826.35, found; 827.21.

### Synthesis Example 4

### Synthesis of Compound 19

### Synthesis of Compound 19-1

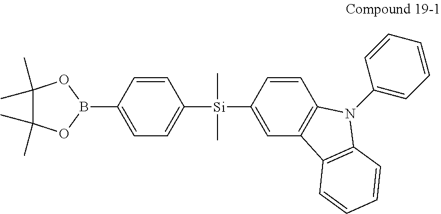 [SMILES: CC1(C)OB(c2ccc([Si](C)(C)c3ccc4c(c3)c3ccccc3n4-c3ccccc3)cc2)OC1(C)C]

Compound 19-1 was synthesized as in the synthesis of Compound 2-1, except that 3-bromo-(9-phenyl)carbazole was used instead of 3-bromobenzene (white solid, yield: 20%).

1H NMR (300 MHz, CDCl3) δ; 8.55 (1H), 7.94 (1H), 7.85 (2H), 7.83 (1H), 7.73 (1H), 7.58 (2H), 7.50 (2H), 7.46 (2H), 7.45 (1H), 7.36 (1H), 7.33 (1H), 7.25 (1H), 1.24 (12H), 0.66 (6H)

### Synthesis of Compound 19

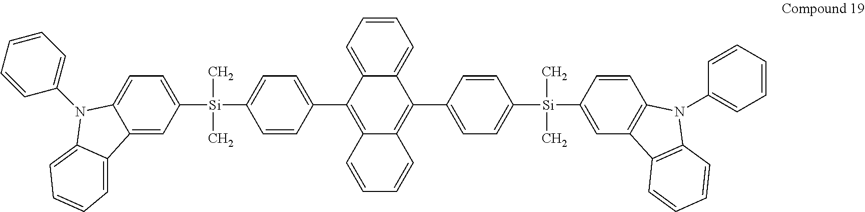 [SMILES: C[Si](C)(c1ccc(-c2c3ccccc3c(-c3ccc([Si](C)(C)c4ccc5c(c4)c4ccccc4n5-c4ccccc4)cc3)c3ccccc23)cc1)c1ccc2c(c1)c1ccccc1n2-c1ccccc1]

Compound 19 was synthesized as in the synthesis of Compound 2, except that Compound 19-1 was used instead of Compound 2-1 and Compound 2-2 (yield: 39%).

1H NMR (300 MHz, CDCl3) δ; 8.55 (2H), 7.94 (2H), 7.91 (4H), 7.89 (4H), 7.83 (2H), 7.73 (2H), 7.58 (4H), 7.52 (4H), 7.50 (4H), 7.45 (2H), 7.39 (4H), 7.36 (2H), 7.33 (2H), 7.25 (2H), 0.66 (12H).

HRMS (FAB); calcd for C66H48N₂Si2; 924.34, found; 925.27.

### Synthesis Example 5

### Synthesis of Compound 21

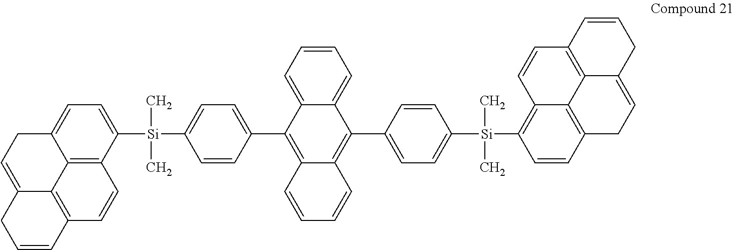 [SMILES: C[Si](C)(c1ccc(-c2c3ccccc3c(-c3ccc([Si](C)(C)c4ccc5c6c7c(ccc46)C=CCC7=CC5)cc3)c3ccccc23)cc1)c1ccc2c3c4c(ccc13)C=CCC4=CC2]

Compound 21 was synthesized as in the synthesis of Compound 2, except that Compound 6-1 was used instead of Compound 2-1 and Compound 2-2 (yield: 42%).

1H NMR (300 MHz, CDCl3) δ; 8.37 (4H), 8.24 (6H), 8.12 (6H), 8.03 (2H), 7.81 (4H), 7.72 (4H), 7.46 (4H), 7.33 (4H), 0.98 (12H)

HRMS (FAB); calcd for C62H46Si2; 846.31, found; 847.20

### Synthesis Example 6

### Synthesis of Compound 24

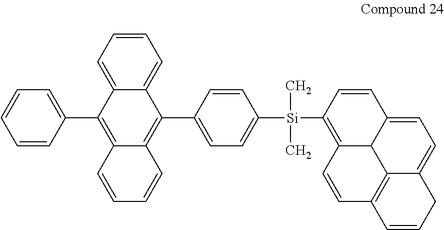 [SMILES: C[Si](C)(C1=C2C=CC3=C4C(=CC=C(C=C1)C24)CC=C3)c1ccc(-c2c3ccccc3c(-c3ccccc3)c3ccccc23)cc1]

Compound 24 was synthesized as in the synthesis of Compound 2, except that 10-bromo-9-phenylanthracene was used instead of 9,10-dibromoanthracene, Compound 6-1 was used instead of Compound 2-1, and Compound 2-2 was not used (yield: 47%).

1H NMR (300 MHz, CDCl3) δ; 7.98 (6H), 7.91 (4H), 7.79 (2H), 7.39 (4H), 7.24 (2H), 5.34 (1H), 3.22 (2H), 2.05 (6H), 0.66 (6H)

HRMS (FAB); calcd for C44H32Si; 588.23, found; 588.81

### Synthesis Example 7

### Synthesis of Compound 33

### Synthesis of Compound 33-1

Compound 33-1 was synthesized in accordance with the following Reaction Scheme 33-1:

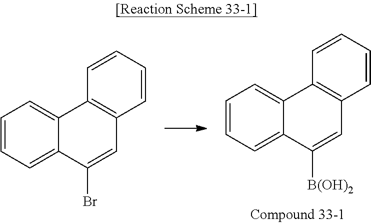 [SMILES: Brc1cc2ccccc2c2ccccc12 ; OB(O)c1cc2ccccc2c2ccccc12]

50 g (194 mmol) of 9-bromophenanthrene was added to 500 ml of THF in a round-bottom flask, and the temperature of the solution was adjusted to −78° C. in a nitrogen atmosphere. After 30 minutes, 146 ml (233 mmol) of n-butyl lithium was slowly dropwise added into the solution, and the temperature of the solution was increased to room temperature. The solution was stirred at room temperature for about 12 hours, a 2N hydrochloric acid aqueous solution was dropwise added into the solution until the solution was acidified, and then the extracted organic layer was collected from the solution and distilled under reduced pressure. The reaction product was recrystallized using n-hexane, filtered, and dried to obtain 35 g of Compound 33-1 (yield: 81%) as a white solid.

### Synthesis of Compound 33-2

Compound 33-2 was synthesized in accordance with the following Reaction Scheme 33-2

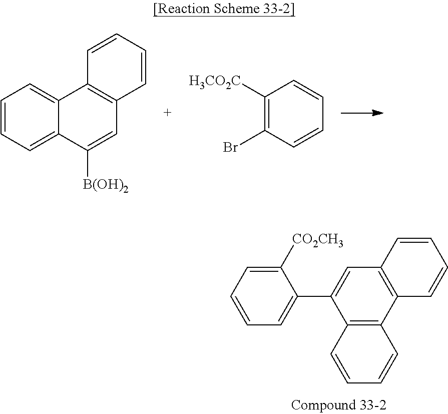 [SMILES: OB(O)c1cc2ccccc2c2ccccc12 ; COC(=O)c1ccccc1Br ; COC(=O)c1ccccc1-c1cc2ccccc2c2ccccc12]

24 g (112 mmol) of methyl 2-bromobenzoate, 34.7 g (0.156 mmol) of Compound 33-1, 2.6 g (2 mmol) of tetrakis(triphenylphosphine)palladium (Pd(PPh₃)₄), 30.9 g (223 mmol) of potassium carbonate, 50 ml of water, 125 ml of toluene, and 125 ml of THF were added in a round-bottom flask and refluxed for 12 hours. After termination of the reaction, the reaction product was separated in layers, and the organic layer was concentrated under reduced pressure, and then the organic layer was dried by performing column separation to obtain 25 g of Compound 33-2 (yield: 72%) as a white solid.

### Synthesis of Compound 33-3

Compound 33-3 was synthesized in accordance with the following Reaction Scheme 33-3.

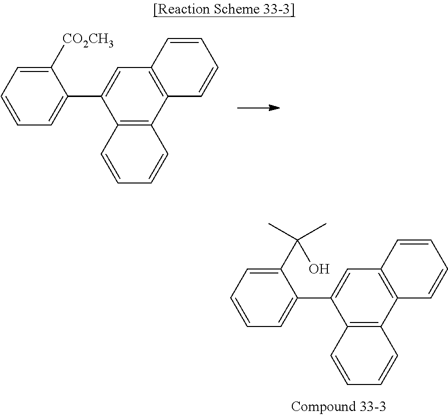 [SMILES: COC(=O)c1ccccc1-c1cc2ccccc2c2ccccc12 ; CC(C)(O)c1ccccc1-c1cc2ccccc2c2ccccc12]

25 g (80 mmol) of Compound 33-2 was added to 250 ml of THF in a round-bottom flask, and the temperature of the solution was adjusted to −78° C. in a nitrogen atmosphere. After 30 minutes, 210 ml (240 mmol) of 1.0 M methylmagnesium bromide was slowly dropwise added into the solution, and the temperature of the solution was increased to room temperature. The solution was stirred at room temperature for about 2 hours, an ammonium chloride aqueous solution was dropwise added into the solution until the solution was acidified, and then the extracted organic layer was collected from the solution and distilled under reduced pressure. The reaction product was recrystallized using n-hexane, filtered, and dried to obtain 27 g of Compound 33-3 (yield: 82%) as a white solid.

### Synthesis of Compound 33-4

Compound 33-4 was synthesized in accordance with the following Reaction Scheme 33-4.

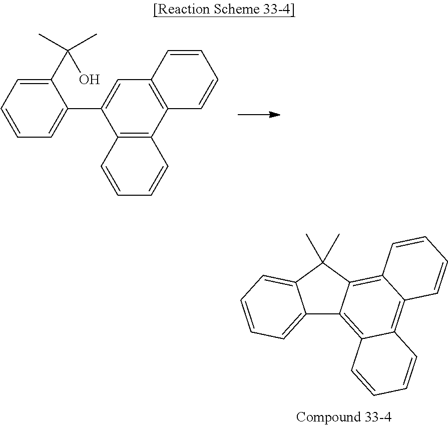

28 g (66 mmol) of Compound 33-3 was added to 290 ml of acetic acid in a round-bottom flask. Then, the temperature of the solution was increased to 80° C., 1 to 2 drops of a hydrochloric acid aqueous solution was added thereto, and the temperature was adjusted to room temperature. The resulting solid was filtered and dried to obtain 26 g of Compound 33-4 (yield: 93%) as a white solid.

### Synthesis of Compound 33-5

Compound 33-5 was synthesized in accordance with the following Reaction Scheme 33-5.

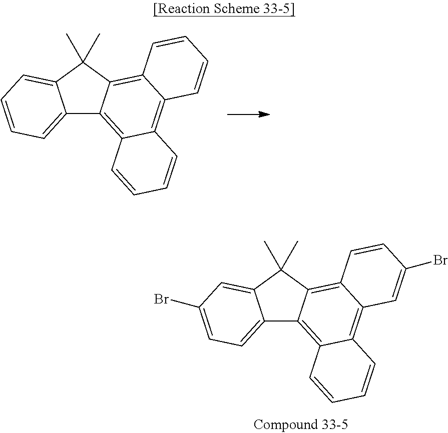

26 g (65 mmol) of Compound 33-4 was added to 216 ml of chloroform in a round-bottom flask, and the solution was stirred. 28.9 g (181 mmol) of bromine was diluted in 54 ml of chloroform, and the diluted solution was slowly dropwise added to the solution in the round-bottom flask, and the flask was stirred at room temperature for 48 hours. The resulting solid was filtered and dried to obtain 26 g of Compound 33-5 (yield: 93%) as a white solid.

### Synthesis of Compound 33

Compound 33 was synthesized in accordance with the following Reaction Scheme 33.

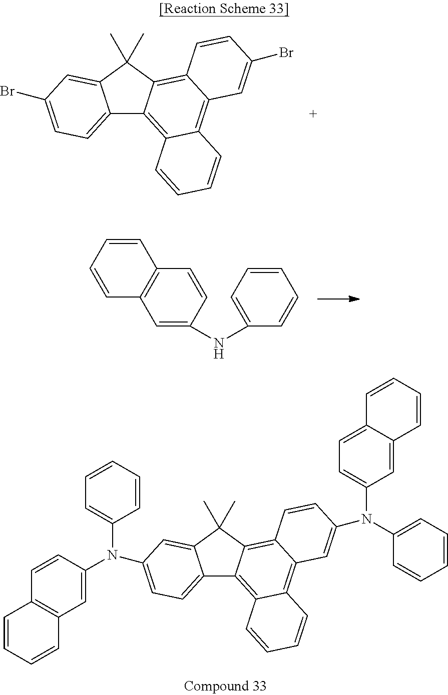 [SMILES: CC1(C)c2cc(Br)ccc2-c2c1c1ccc(Br)cc1c1ccccc21 ; c1ccc(Nc2ccc3ccccc3c2)cc1 ; CC1(C)c2cc(N(c3ccccc3)c3ccc4ccccc4c3)ccc2-c2c1c1ccc(N(c3ccccc3)c3ccc4ccccc4c3)cc1c1ccccc21]

9 g (17 mmol) of Compound 33-5, 8.4 g (45 mmol) of 2-naphthyl-phenylamine, 0.2 g (0.7 mmol) of Pd(OAc)₂, 6.7 g (69 mmol) of sodium tert-butoxide, 0.14 g (0.7 mmol) of tri-tert-butylphosphine, and 100 ml of toluene were added to a round-bottom flask, and reacted at a temperature of 100° C. for 2 hours. After termination of the reaction, the resultant was filtered, and the filtrate was concentrated and separated by column chromatography. The solution separated by the column chromatography was then recrystallized with toluene and methanol to produce a solid, and the solid was filtered and dried to obtain 5.2 g of Compound 33 (yield: 40%) as a yellow solid.

MS: m/z 729 [M]+

### Synthesis Example 8

### Synthesis of Compound 60

### Synthesis of Compound 60-3

Compound 60-3 was synthesized in accordance with Reaction Scheme 60-3 below:

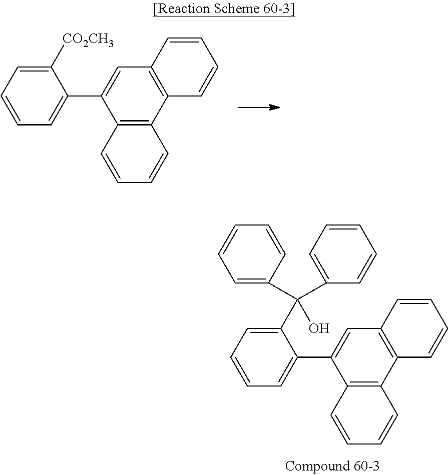 [SMILES: COC(=O)c1ccccc1-c1cc2ccccc2c2ccccc12 ; OC(c1ccccc1)(c1ccccc1)c1ccccc1-c1cc2ccccc2c2ccccc12]

25 g (80 mmol) of Compound 30-2 was added to 250 ml of THF in a round-bottom flask, and the temperature of the solution was adjusted to −78° C. in a nitrogen atmosphere. After 30 minutes, 150 ml of (240 mmol) of 1.6 M phenyl-lithium was slowly dropwise added into the solution, and then the temperature of the solution was increased to room temperature after 1 hour. The solution was stirred at room temperature for about 2 hours, an ammonium chloride aqueous solution was dropwise added to the solution, and then the extracted organic layer was collected from the solution and distilled under reduced pressure. The reaction product was recrystallized using n-hexane, filtered, and dried to obtain 29 g of Compound 60-3 (yield: 83%) as a white solid.

### Synthesis of Compound 60-4

Compound 60-4 was synthesized in accordance with Reaction Scheme 60-4 below:

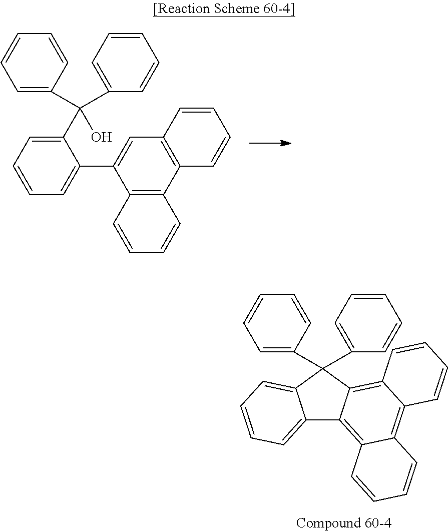

29 g (66 mmol) of Compound 60-3 was added to 290 ml of acetic acid in a round-bottom flask. Then, the temperature of the solution was increased to 80° C., 1 to 2 drops of a hydrochloric acid aqueous solution was added to the solution, refluxed for about 2 hours, and the temperature was adjusted to room temperature. The resulting solid was filtered and dried to obtain 27 g of Compound 60-4 (yield: 93%) as a white solid.

### Synthesis of Compound 60-5

Compound 60-5 was synthesized in accordance with Reaction Scheme 60-5 below:

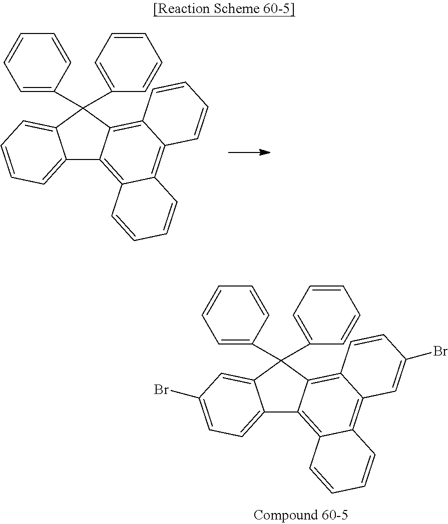

27 g (65 mmol) of Compound 60-4 was added to 216 ml of chloroform in a round-bottom flask, and the solution was stirred. 28.9 g (181 mmol) of bromine was diluted in 54 ml of chloroform, and the diluted solution was slowly dropwise added to the solution in the round-bottom flask, and the flask was stirred at room temperature for 48 hours. The resulting solid was filtered and dried to obtain 27 g of Compound 60-5 (yield: 93%) as a white solid.

### Synthesis of Compound 60

Compound 60 was synthesized in accordance with Reaction Scheme 60 below:

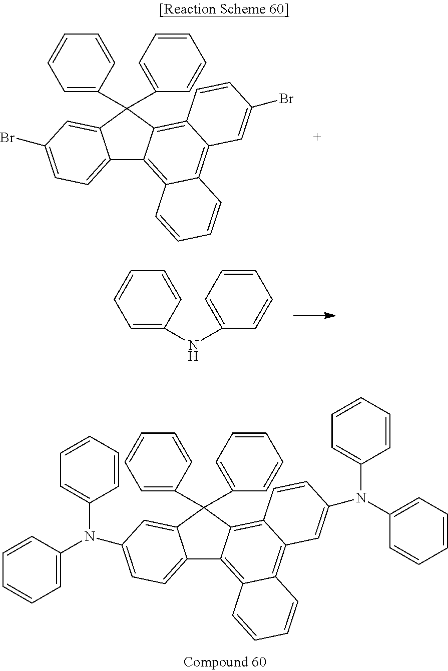

10 g (17 mmol) of Compound 60-5, 7.6 g (45 mmol) of diphenylamine, 0.2 g (0.7 mmol) of Pd(OAc)₂, 6.7 g (69 mmol) of sodium tert-butoxide, 0.14 g (0.7 mmol) of tri-tert-butylphosphine, and 100 ml of toluene were added to a round-bottom flask, and reacted at a temperature of 100° C. for 2 hours. After termination of the reaction, the resultant was filtered, and the filtrate was concentrated and separated by column chromatography. The solution separated by the column chromatography was then recrystallized with toluene and methanol to produce a solid, and the solid was filtered and dried to obtain 5.7 g of Compound 60 (yield: 40%) as a yellow solid.

MS: m/z 752 [M]+

1H NMR (CDCl₃) δ 8.89 (d, 1H), 8.47 (d, 1H), 8.40 (s, 1H), 8.24 (d, 1H), 7.73 (t, 1H), 7.63 (m, 2H), 7.27 (m, 23H), 7.01 (m, 10H)

### Example 1

As a substrate for an anode, a corning 15 Ω/cm² (1200 Å) ITO glass substrate was cut to a size of 50 mm×50 mm×0.7 mm and then sonicated in isopropyl alcohol and pure water each for five minutes, and then cleaned by UV irradiation for 30 minutes and exposure to ozone. The resulting glass substrate was loaded into a vacuum deposition device.

2-TNATA was deposited on the ITO glass substrate (anode) to form an HIL having a thickness of 600 Å on the anode, and then 4,4′-bis[N-(1-naphthyl)-N-phenylamino]biphenyl (NPB) was deposited on the HIL to form a HTL having a thickness of 300 Å.

Compound 2 (host) and Compound 33 (dopant) were co-deposited on the HTL in a weight ratio of about 95:5 to form an EML having a thickness of about 400 Å.

Then, Compound 201 was deposited on the EML to form an ETL having a thickness of about 300 Å, and then LiF was deposited on the ETL to form an EIL having a thickness of about 10 Å. Then, Al was deposited on the EIL to form a second electrode (cathode) having a thickness of about 1100 Å, thereby completing the manufacture of an organic light-emitting diode.

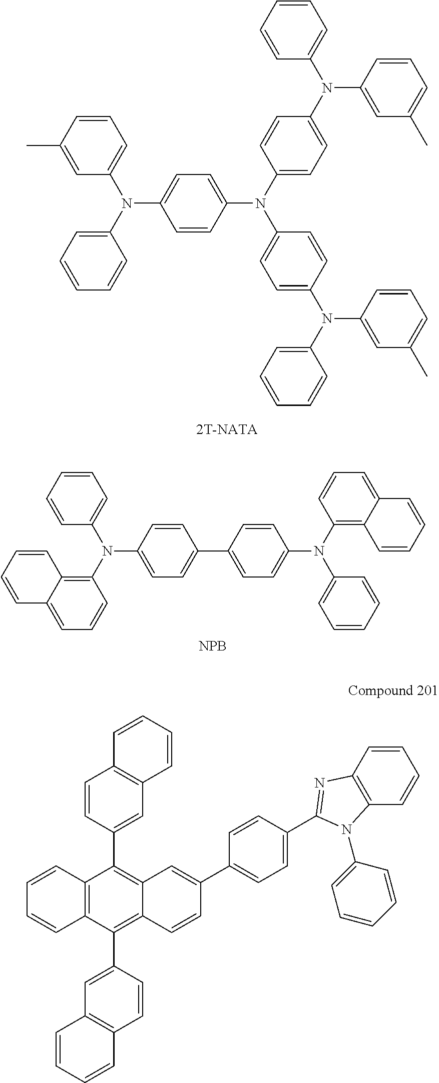

### Example 2

An organic light-emitting diode was manufactured as in Example 1, except that Compound 6 was used instead of Compound 2 to form the EML.

### Example 3

An organic light-emitting diode was manufactured as in Example 1, except that Compound 13 was used instead of Compound 2 to form the EML.

### Example 4

An organic light-emitting diode was manufactured as in Example 1, except that Compound 19 was used instead of Compound 2 to form the EML.

### Example 5

An organic light-emitting diode was manufactured as in Example 1, except that Compound 21 was used instead of Compound 2 to form the EML.

### Example 6

An organic light-emitting diode was manufactured as in Example 1, except that Compound 24 was used instead of Compound 2 to form the EML.

### Example 7

An organic light-emitting diode was manufactured as in Example 1, except that Compound 60 was used instead of Compound 33 to form the EML.

### Example 8

An organic light-emitting diode was manufactured as in Example 7, except that Compound 6 was used instead of Compound 2 to form the EML.

### Example 9

An organic light-emitting diode was manufactured as in Example 7, except that Compound 13 was used instead of Compound 2 to form the EML.

### Example 10

An organic light-emitting diode was manufactured as in Example 7, except that Compound 19 was used instead of Compound 2 to form the EML.

### Example 11

An organic light-emitting diode was manufactured as in Example 7, except that Compound 21 was used instead of Compound 2 to form the EML.

### Example 12

An organic light-emitting diode was manufactured as in Example 7, except that Compound 24 was used instead of Compound 2 to form the EML.

### Comparative Example 1

An organic light-emitting diode was manufactured as in Example 1, except that host A below was used instead of Compound 2 to form the EML.

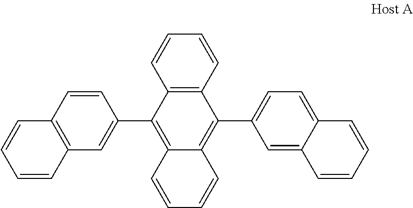 [SMILES: c1ccc2cc(-c3c4ccccc4c(-c4ccc5ccccc5c4)c4ccccc34)ccc2c1]

### Comparative Example 2

An organic light-emitting diode was manufactured as in Example 7, except that the Host A was used instead of Compound 2 to form the EML.

### Comparative Example 3

An organic light-emitting diode was manufactured as in Example 1, except that Host B (below) and 2,5,8,11-tetra-tert-butyl-perylene were used instead of Compounds 2 and 33, respectively, to form the EML.

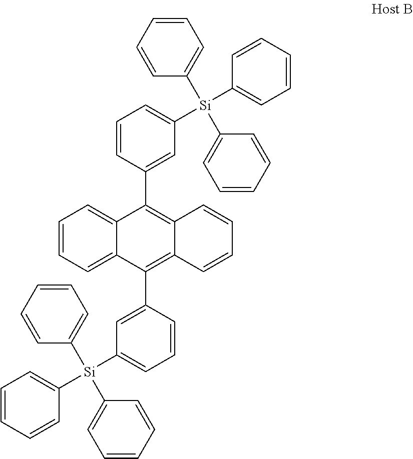 [SMILES: c1ccc([Si](c2ccccc2)(c2ccccc2)c2cccc(-c3c4ccccc4c(-c4cccc([Si](c5ccccc5)(c5ccccc5)c5ccccc5)c4)c4ccccc34)c2)cc1]

### Evaluation Example

Driving voltage, current density, efficiency, and color purity of each of the organic light-emitting diodes of Examples 1 to 12 and Comparative Examples 1 to 3 were measured using a PR650 (Spectroscan) Source Measurement Unit (available from Photo Research, Inc.) while supplying power using a Keithley Source-Measure Unit (SMU 236). The results are shown in Table 1. In Table 1, “T95 lifetime” indicates the time it took for initial brightness (assumed as 100%) measured at a current density of about 10 mA/cm² to reduce to 95%.

TABLE 1

| | | | Driving | | | | T95 |
|---|---|---|---|---|---|---|---|
| | | | voltage | Efficiency | Color coordinates | | lifetime |
| | Host | Dopant | (V) | (cd/A) | CIE x | CIE y | [hr] |
| Example 1 | Compound 2 | Compound 33 | 3.6 | 2.7 | 0.148 | 0.041 | 180 |
| Example 2 | Compound 6 | Compound 33 | 3.6 | 3.0 | 0.147 | 0.045 | 220 |
| Example 3 | Compound 13 | Compound 33 | 3.4 | 2.9 | 0.148 | 0.043 | 170 |
| Example 4 | Compound 19 | Compound 33 | 3.4 | 2.9 | 0.148 | 0.043 | 180 |
| Example 5 | Compound 21 | Compound 33 | 3.6 | 3.4 | 0.148 | 0.045 | 250 |
| Example 6 | Compound 24 | Compound 33 | 3.8 | 3.2 | 0.149 | 0.045 | 220 |
| Example 7 | Compound 2 | Compound 60 | 3.6 | 2.6 | 0.148 | 0.041 | 200 |
| Example 8 | Compound 6 | Compound 60 | 3.7 | 3.1 | 0.148 | 0.045 | 220 |
| Example 9 | Compound 13 | Compound 60 | 3.4 | 3.0 | 0.148 | 0.043 | 180 |
| Example 10 | Compound 19 | Compound 60 | 3.4 | 3.1 | 0.147 | 0.044 | 190 |
| Example 11 | Compound 21 | Compound 60 | 3.7 | 3.5 | 0.147 | 0.045 | 260 |
| Example 12 | Compound 24 | Compound 60 | 3.8 | 3.2 | 0.148 | 0.045 | 230 |
| Comparative | Host A | Compound 33 | 4.8 | 2.8 | 0.148 | 0.054 | 120 |
| Example 1 | | | | | | | |
| Comparative | Host A | Compound 30 | 4.8 | 2.6 | 0.148 | 0.056 | 130 |
| Example 2 | | | | | | | |
| Comparative | Host B | TBPe | 5.2 | 2.2 | 0.152 | 0.072 | 40 |
| Example 3 | | | | | | | |

Referring to Table 1, the organic light-emitting diodes of Examples 1 to 12 have lower driving voltages, higher efficiencies, and improved lifetimes as compared with the organic light-emitting diodes of Comparative Examples 1 to 3.

As described above, the organic light-emitting diode according to embodiments of the present invention may have low driving voltage, high efficiency, and a long lifetime.

While the present invention has been illustrated and described with reference to certain exemplary embodiments, it will be understood by those of ordinary skill in the art that various changes may be made to the described embodiments without departing from the spirit and scope of the present invention, as defined by the following claims.

What is claimed is:

1. An organic light-emitting diode comprising:
a substrate;
a first electrode;
a second electrode facing the first electrode; and
an emission layer between the first electrode and the second electrode, the emission layer comprising an anthracene-based compound represented by Formula 1 and an amine-based compound represented by Formula 20: 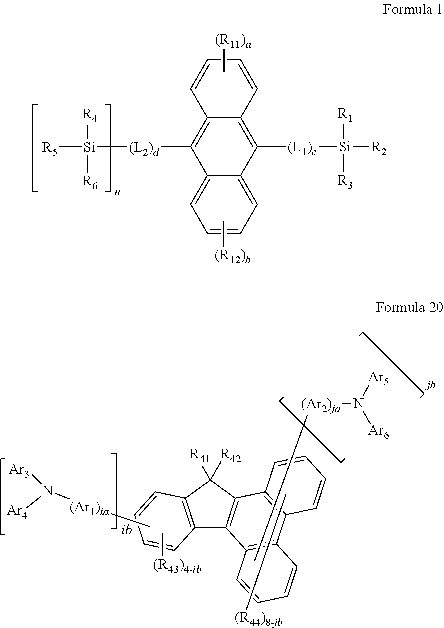
wherein, in Formulae 1 and 20, n is 0 or 1;
R₁ to R₆ are each independently a substituted or unsubstituted C₁-C₆₀ alkyl group, a 3- to 10-membered substituted or unsubstituted non-condensed ring group, or a substituted or unsubstituted condensed ring group in which at least two rings are fused to each other, wherein, if n is 0, at least one of R₁ to R₃ is a substituted or unsubstituted condensed ring group in which at least two rings are fused to each other, and if n is 1, at least one of R₁ to R₆ is a substituted or unsubstituted condensed ring group in which at least two rings are fused to each other;
L₁, L₂, Ar₁, and Ar₂ are each independently a substituted or unsubstituted C₃-C₁₀ cycloalkylene group, a substituted or unsubstituted C₃-C₁₀ cycloalkenylene group, a substituted or unsubstituted C₃-C₁₀ heterocycloalkylene group, a substituted or unsubstituted C₃-C₁₀ heterocycloalkenylene group, a substituted or unsubstituted C₆-C₆₀ arylene group, or a substituted or unsubstituted C₂-C₆₀ heteroarylene group;
c and d are each independently an integer of 1 to 3;
R₁₁, R₁₂, R₄₃, and R₄₄ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, —N(Q₁)(Q₂), or —Si(Q₃)(Q₄)(Q₅),
Q₁ to Q₅ are each independently a hydrogen atom, a C₁-C₁₀ alkyl group, a C₆-C₂₀ aryl group, or a C₂-C₂₀ heteroaryl group,
a and b are each independently an integer of 1 to 4;
R₄₁ and R₄₂ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, or a substituted or unsubstituted C₂-C₆₀ heteroaryl group;
ia and ja are each independently an integer of 0 to 3;
ib and jb are each independently an integer of 0 to 3, and ib+jb≧1; and
Ar₃ to Ar₆ are each independently a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, or a substituted or unsubstituted C₂-C₆₀ heteroaryl group.

2. The organic light-emitting diode of claim 1, wherein a weight ratio of the anthracene-based compound to the amine-based compound in the emission layer is about 99.9:0.01 to about 80:20.

3. The organic light-emitting diode of claim 1, wherein, in Formula 1, R₁ to R₆ are each independently:
a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group; or
a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q₁₁ₐ)(Q₁₂ₐ) wherein Q₁₁ₐ and Q₁₂ₐ are each independently a hydrogen atom, a C₁-C₁₀ alkyl group, a C₆-C₂₀ aryl group, or a C₂-C₂₀ heteroaryl group,
wherein at least one of R₁ to R₃ when n is 0, or at least one of R₁ to R₆ when n is 1, is:
a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group; or
a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q₁₁ₐ)(Q₁₂ₐ) wherein Q₁₁ₐ and Q₁₂ₐ are each independently a hydrogen atom, a C₁-C₁₀ alkyl group, a C₆-C₂₀ aryl group, or a C₂-C₂₀ heteroaryl group.

4. The organic light-emitting diode of claim 1, wherein, in Formula 1, R₁ to R₆ are each independently:
a methyl group, an ethyl group, an n-propyl group, an i-propyl group, an n-butyl group, an i-butyl group, a t-butyl group, a pentyl group, a hexyl group, a heptyl group, an octyl group, a nonyl group, or a decyl group; or
a methyl group, an ethyl group, a n-propyl group, an i-propyl group, an n-butyl group, an i-butyl group, a t-butyl group, a pentyl group, a hexyl group, a heptyl group, an octyl group, a nonyl group, or a decyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q₁₁ₐ)(Q₁₂ₐ) wherein Q₁₁ₐ and Q₁₂ₐ are each independently a hydrogen atom, a C₁-C₁₀ alkyl group, a C₆-C₂₀ aryl group, or a C₂-C₂₀ heteroaryl group; or
a group represented by one of Formulae 2A to 2T; or
a group represented by one of Formulae 3A to 3R;
wherein at least one of R₁ to R₃ when n is 0, or at least one of R₁ to R₆ when n is 1, is represented by one of Formulae 3A to 3R: 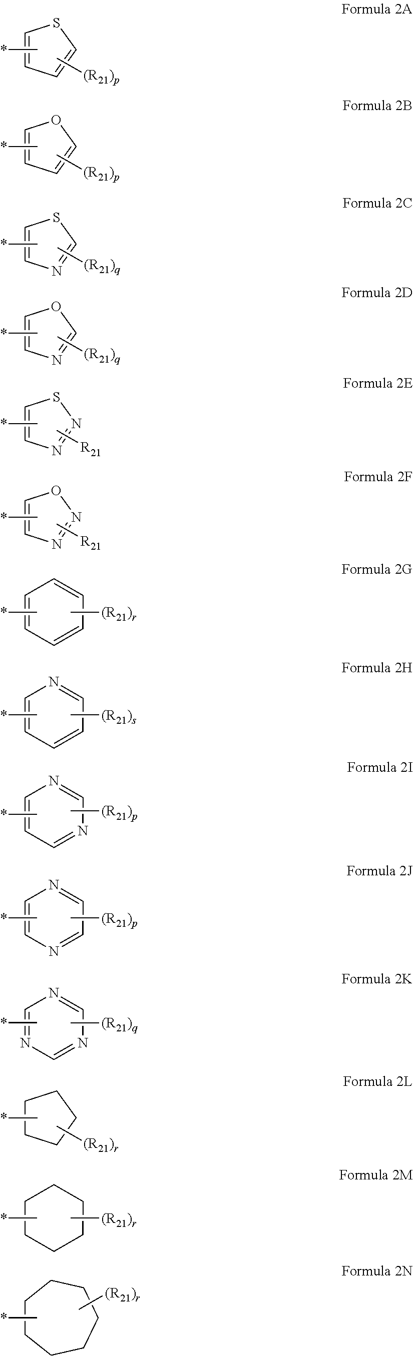 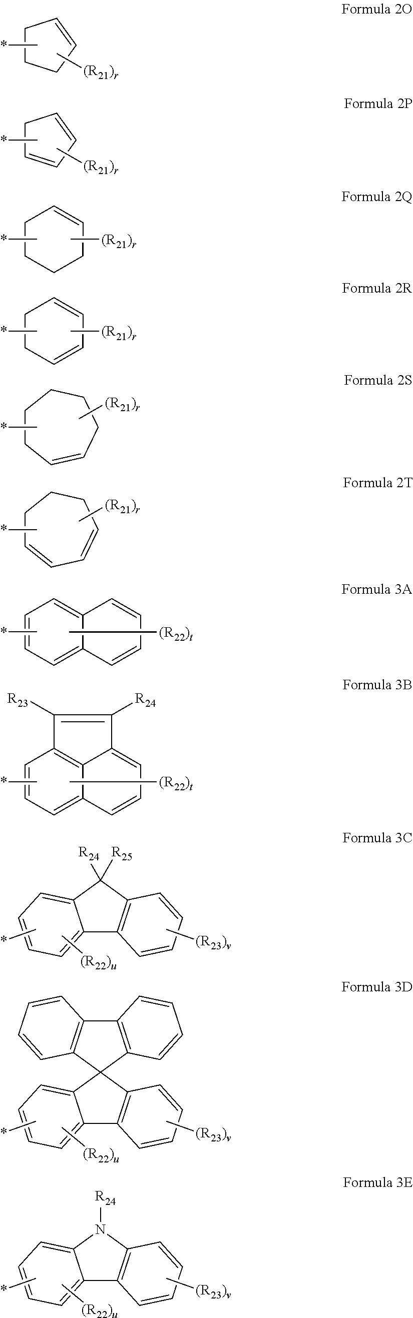 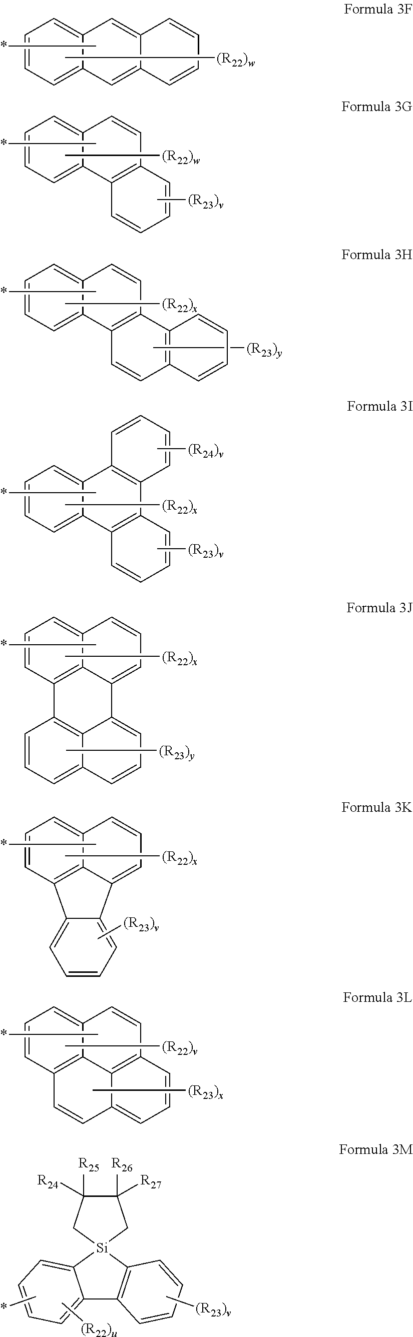 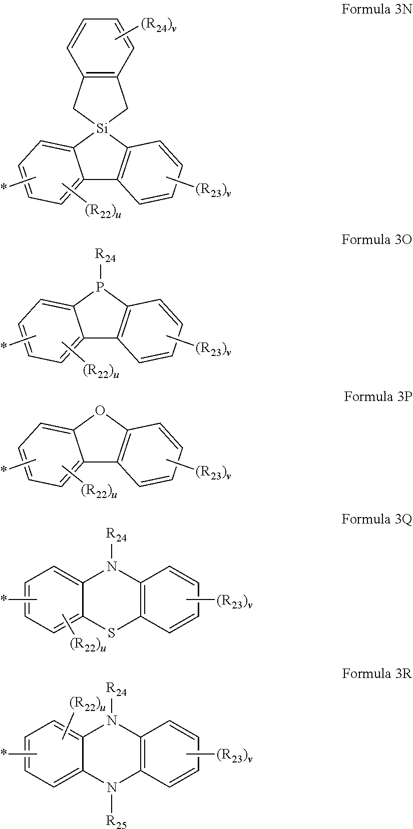
wherein, in Formulae 2A to 2T and 3A to 3R, R₂₁ to R₂₇ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q₁₁ₐ)(Q₁₂ₐ) wherein Q₁₁ₐ and Q₁₂ₐ are each independently a hydrogen atom, a C₁-C₁₀ alkyl group, a C₆-C₂₀ aryl group, or a C₂-C₂₀ heteroaryl group;
p and u are each independently an integer of 1 to 3;
q is 1 or 2;
r and x are each independently an integer of 1 to 5;
s and v are each independently an integer of 1 to 4;
t is an integer of 1 to 7;
w is an integer of 1 to 9; and
y is an integer of 1 to 6.

5. The organic light-emitting diode of claim 1, wherein, in Formula 1, R₁ to R₆ are each independently:
a methyl group, an ethyl group, a n-propyl group, an i-propyl group, an n-butyl group, an i-butyl group, a t-butyl group, a pentyl group, a hexyl group, a heptyl group, an octyl group, a nonyl group, or a decyl group; or
a methyl group, an ethyl group, a n-propyl group, an i-propyl group, an n-butyl group, an i-butyl group, a t-butyl group, a pentyl group, a hexyl group, a heptyl group, an octyl group, a nonyl group, or a decyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a phenyl group, a naphthyl group, or an anthracenyl group; or
a group represented by Formula 2G; or
a group represented by one of Formulae 4A to 4J,
wherein at least one of R₁ to R₃ when n is 0, or at least one of R₁ to R₆ when n is 1, is represented by one of Formulae 4A to 4J: 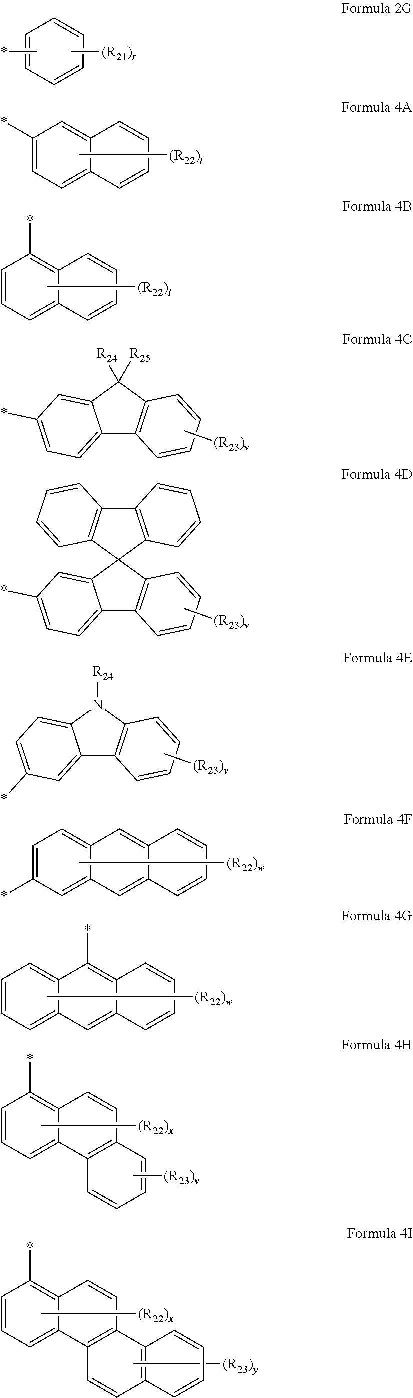 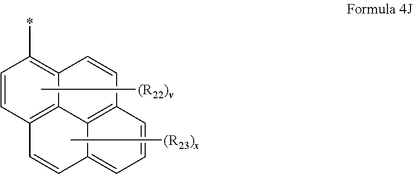
wherein, in Formulae 2G and 4A to 4J, R₂₁ to R₂₅ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a dimethyl-fluorenyl group, a phenyl-carbazolyl group, a pyrenyl group, a chrysenyl group, a benzothiazolyl group, a benzooxazolyl group, a phenyl-benzoimidazolyl group, or —N(Q₁₁ₐ)(Q₁₂ₐ) wherein Q₁₁ₐ and Q₁₂ₐ are each independently a hydrogen atom, a C₁-C₁₀ alkyl group, a phenyl group, a naphthyl group, or an anthracenyl group;
r and x are each independently an integer of 1 to 5;
v is an integer of 1 to 4;
t is an integer of 1 to 7;
w is an integer of 1 to 9; and
y is an integer of 1 to 6.

6. The organic light-emitting diode of claim 1, wherein, in Formulae 1 and 20, L₁, L₂, Ar₁ and Ar₂ are each independently:
a cyclopropylene group, a cyclobutylene group, a cyclopentylene group, a cyclohexylene group, a cycloheptylene group, a cyclooctylene group, a cyclopentenylene group, a cyclopentadienylene group, a cyclohexenylene group, a cyclohexadienylene group, a cycloheptadienylene group, a thiophenylene group, a furanylene group, a pyrrolylene group, an imidazolylene group, a pyrazolylene group, an isothiazolylene group, an isoxazolylene group, a thiazolylene group, an oxazolylene group, an oxadiazolylene group, a thiadiazolylene group, a triazolylene group, a phenylene group, a pyridinylene group, a pyrazinylene group, a pyrimidinylene group, a pyridazinylene group, a triazinylene group, a pentalenylene group, an indenylene group, a naphthylene group, an azulenylene group, a heptalenylene group, a biphenylenylene group, an indacenylene group, an acenaphthalenylene group, a fluorenylene group, a spiro-fluorenylene group, a carbazolylene group, an anthracenylene group, a phenalenylene group, a phenanthrenylene group, a perylenylene group, a fluoranthenylene group, a naphthacenyl ene group, a picenylene group, a pentaphenylene group, a hexacenylene group, a dibenzofuranylene group, a phenothiazinylene group, a phenoxazinylene group, a dihydrophenazinylene group, a phenoxathiinylene group, or a phenanthridinylene group; or
a cyclopropylene group, a cyclobutylene group, a cyclopentylene group, a cyclohexylene group, a cycloheptylene group, a cyclooctylene group, a cyclopentenylene group, a cyclopentadienylene group, a cyclohexenylene group, a cyclohexadienylene group, a cycloheptadienylene group, a thiophenylene group, a furanylene group, a pyrrolylene group, an imidazolylene group, a pyrazolylene group, an isothiazolylene group, an isoxazolylene group, a thiazolylene group, an oxazolylene group, an oxadiazolylene group, a thiadiazolylene group, a triazolylene group, a phenylene group, a pyridinylene group, a pyrazinylene group, a pyrimidinylene group, a pyridazinylene group, a triazinylene group, a pentalenylene group, an indenylene group, a naphthylene group, an azulenylene group, a heptalenylene group, a biphenylenylene group, an indacenylene group, an acenaphthalenylene group, a fluorenylene group, a spiro-fluorenylene group, a carbazolylene group, an anthracenylene group, a phenalenylene group, a phenanthrenylene group, a perylenylene group, a fluoranthenylene group, a naphthacenylene group, a picenylene group, a pentaphenylene group, a hexacenylene group, a dibenzofuranylene group, a phenothiazinylene group, a phenoxazinylene group, a dihydrophenazinylene group, a phenoxathiinylene group, or a phenanthridinylene group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q_{11b})(Q_{12b}) wherein Q_{11b} and Q_{12b} are each independently a hydrogen atom, a C₁-C₁₀ alkyl group, a C₆-C₂₀ aryl group, or a C₂-C₂₀ heteroaryl group.

7. The organic light-emitting diode of claim 1, wherein, in Formulae 1 and 20, L₁, L₂, Ar₁, and Ar₂ are each independently a group represented by one of Formulae 5A to 5J: 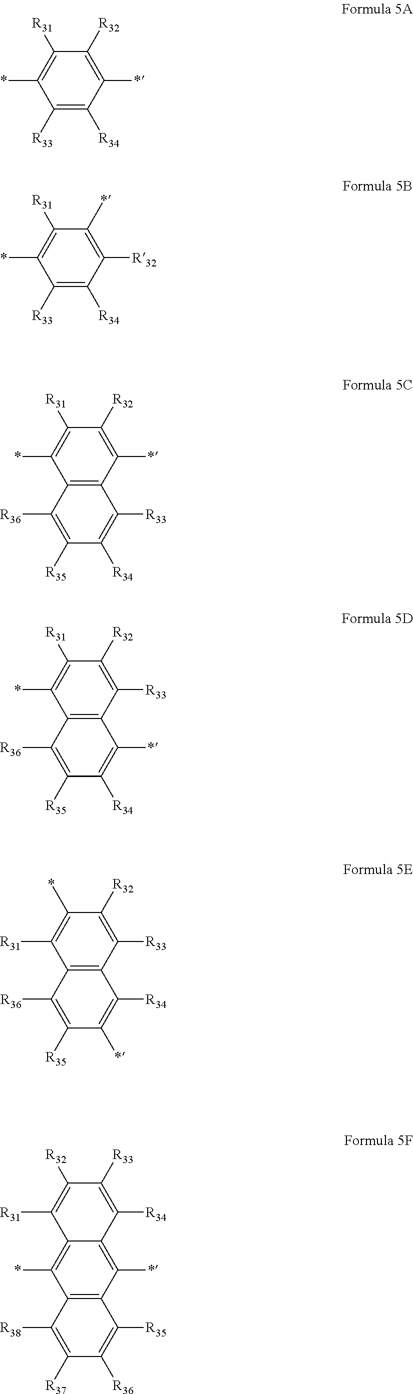 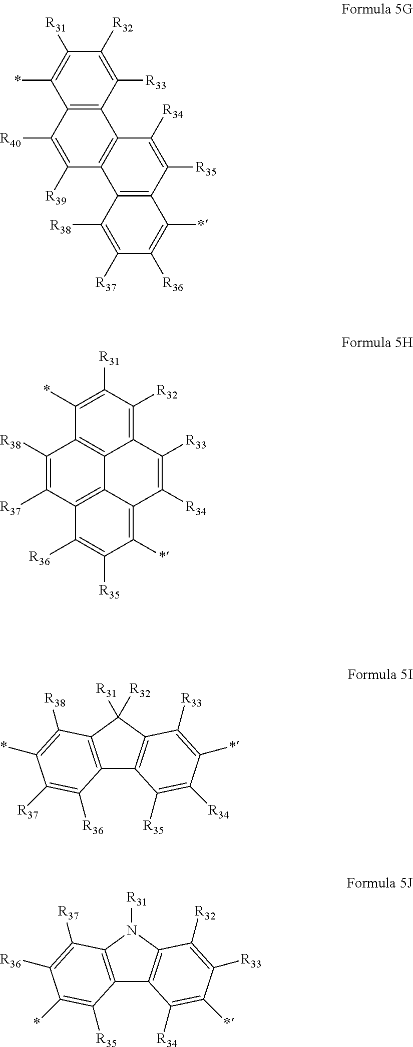
wherein, in Formulae 5A to 5J, R₃₁ to R₄₀ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q_{11b})(Q_{12b}) wherein Q_{11b} and Q_{12b} are each independently a hydrogen atom, a C₁-C₁₀ alkyl group, a C₆-C₂₀ aryl group, or a C₂-C₂₀ heteroaryl group; and
* is a binding site with an anthracene core in Formula 1.

8. The organic light-emitting diode of claim 1, wherein, in Formula 1:
n is 1;
R₁, R₃, R₄, and R₆ are each independently a substituted or unsubstituted C₁-C₆₀ alkyl group; and
R₂ and R₅ are each independently a 3- to 10-membered substituted or unsubstituted non-condensed ring group, or a substituted or unsubstituted condensed ring group in which at least two rings are fused to each other, wherein at least one of R₃ or R₅ is a substituted or unsubstituted condensed ring group in which at least two rings are fused to each other.

9. The organic light-emitting diode of claim 1, wherein, in Formula 1:
n is 0;
R₁ and R₃ are each independently a substituted or unsubstituted C₁-C₆₀ alkyl group; and
R₂ is a substituted or unsubstituted condensed ring group in which at least two rings are fused to each other.

10. The organic light-emitting diode of claim 1, wherein the anthracene-based compound is one of Compounds 1 to 24:

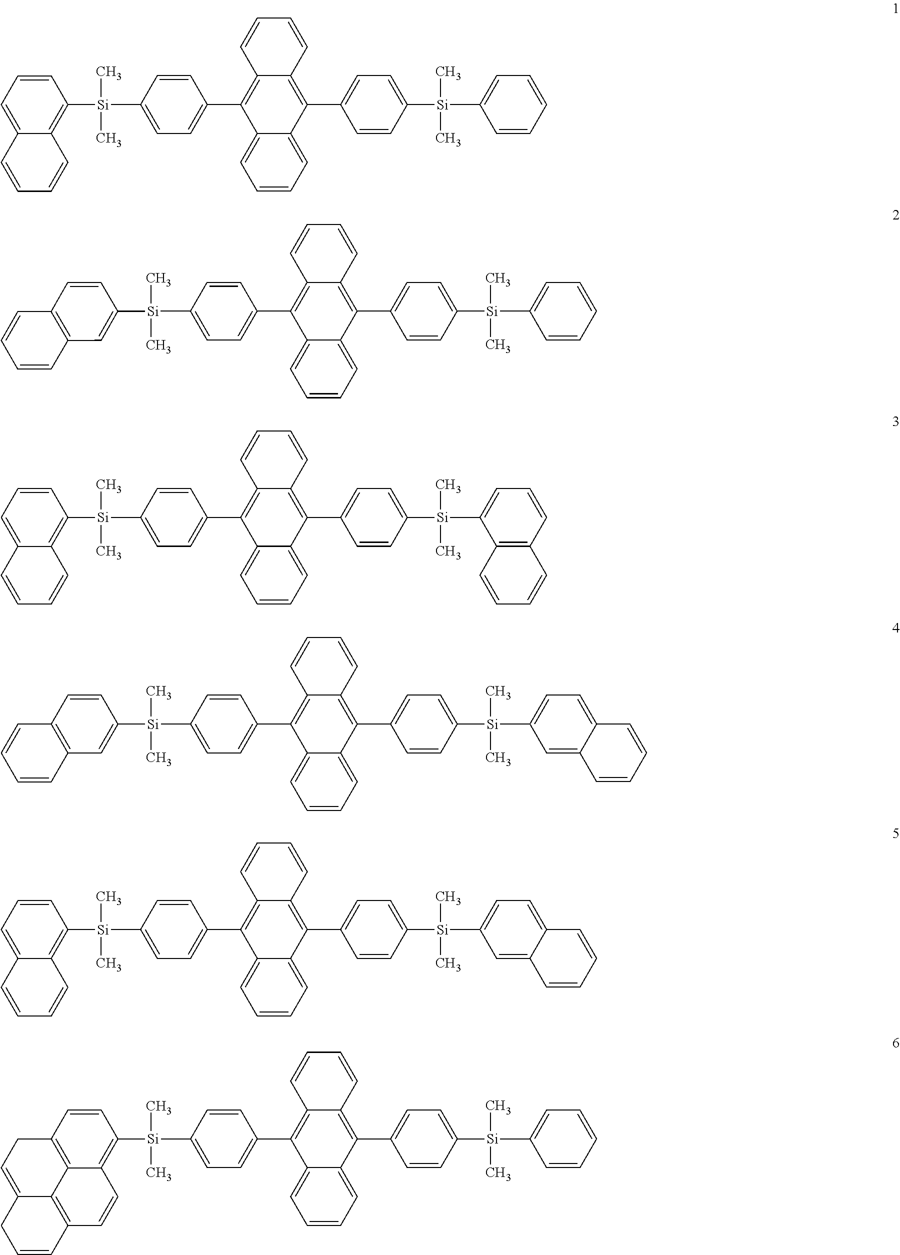

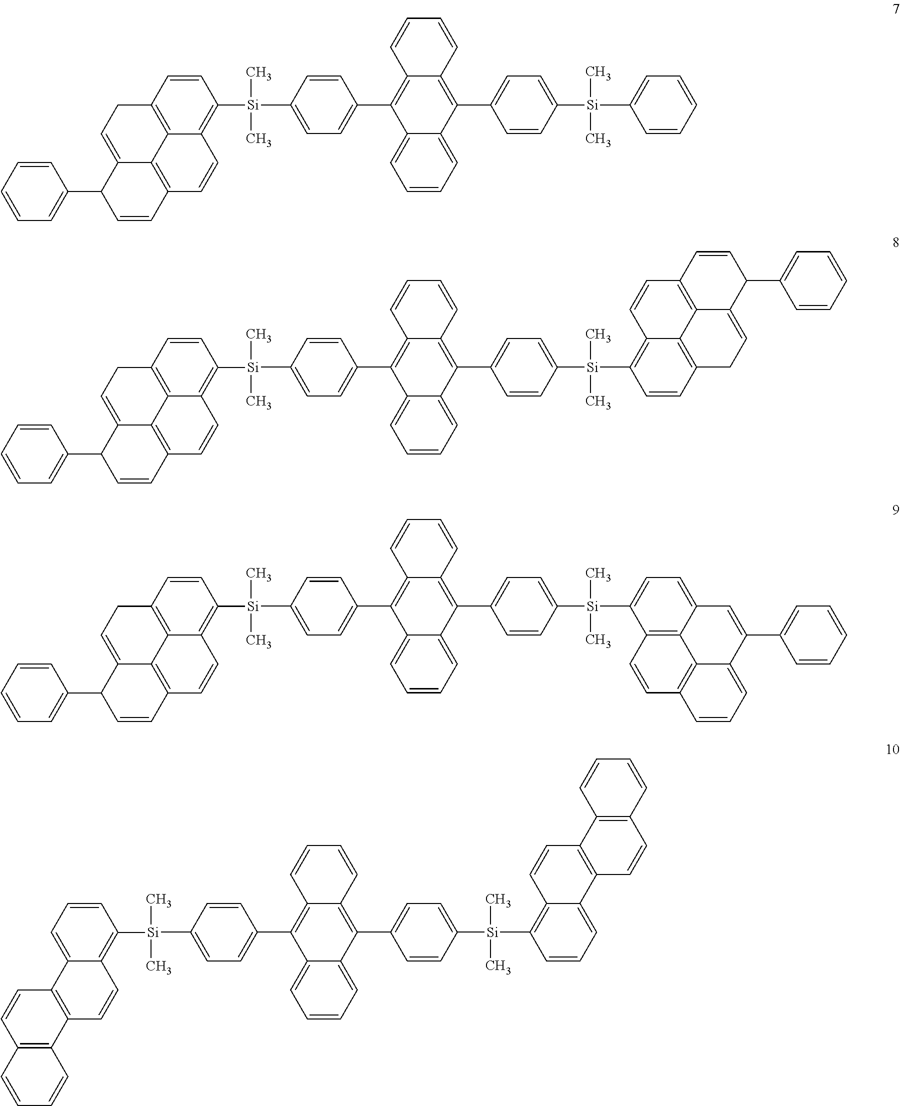

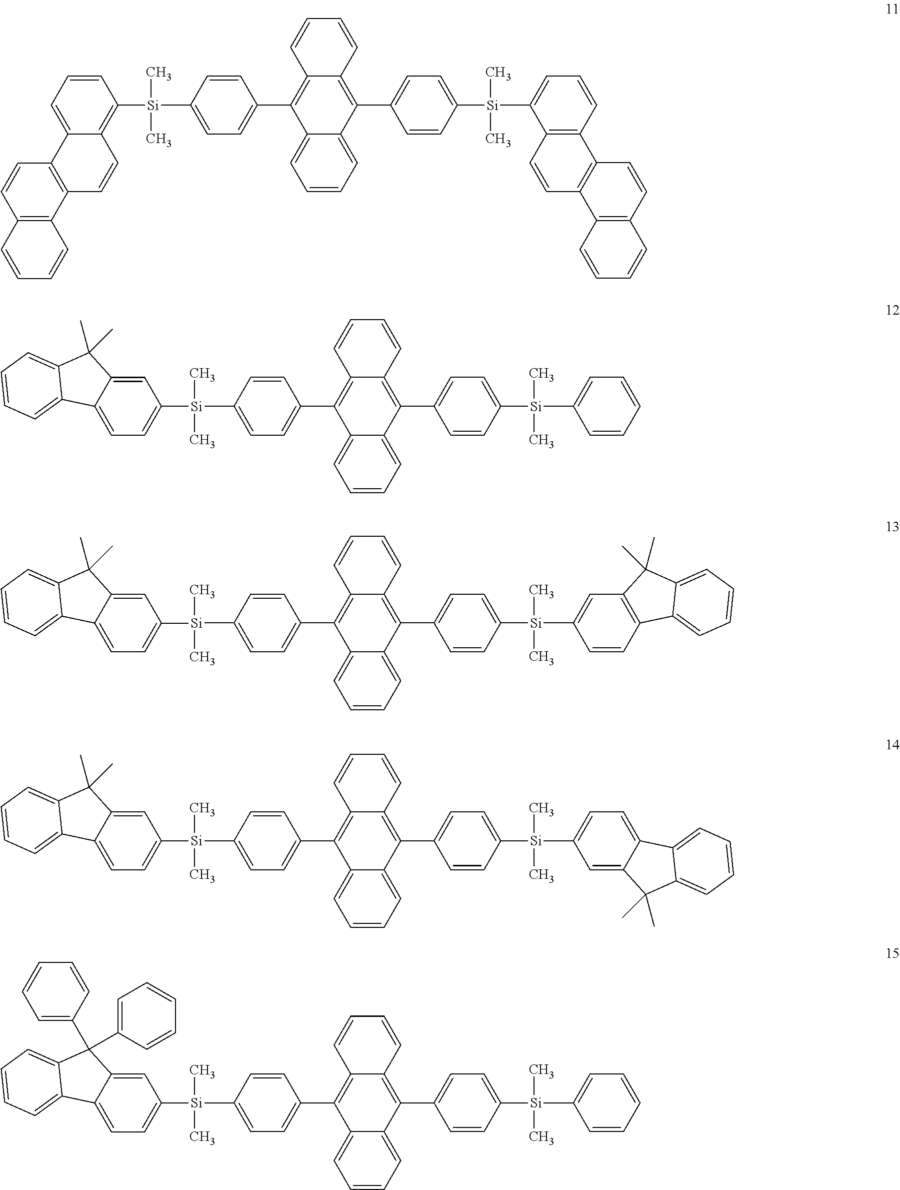

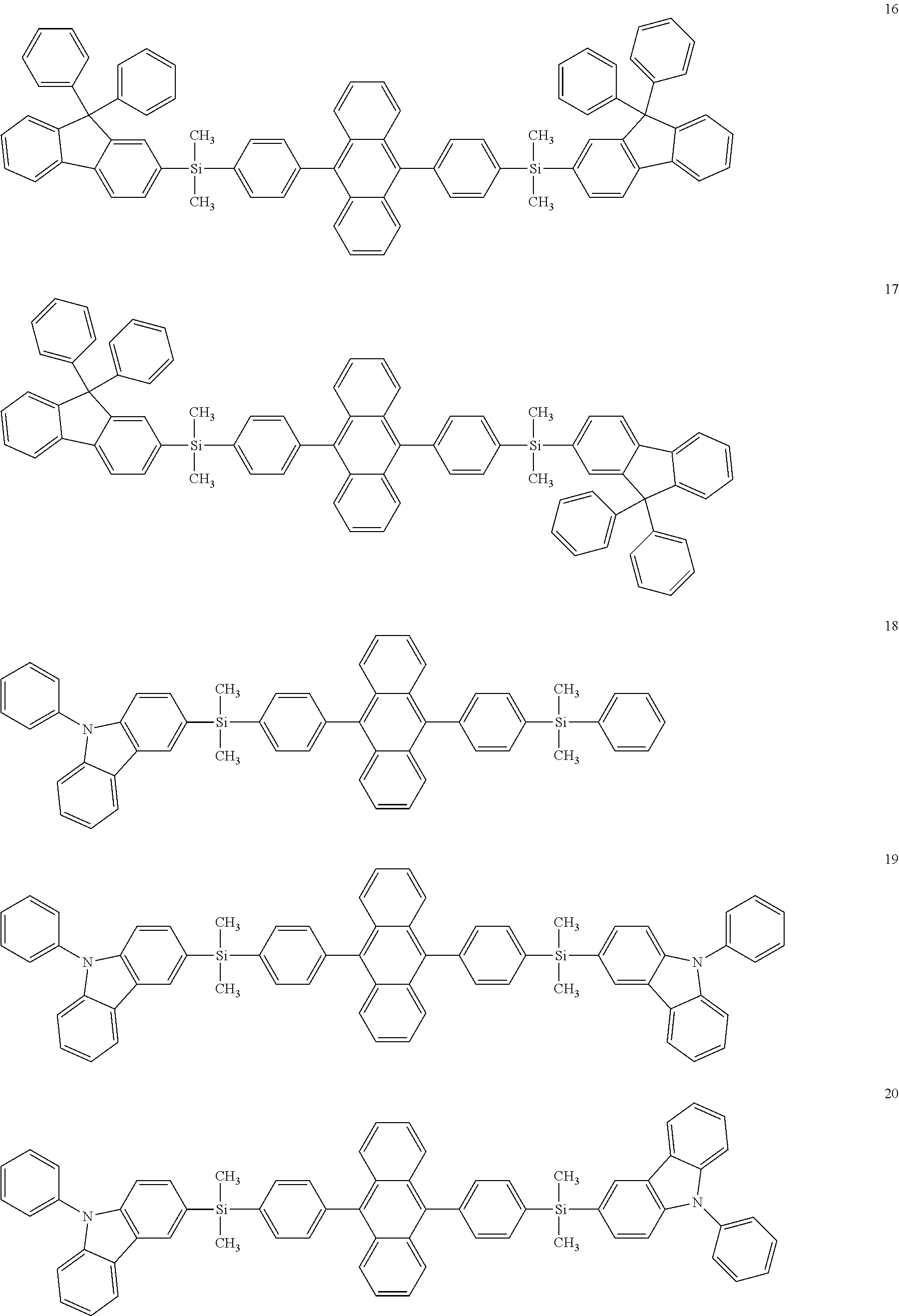

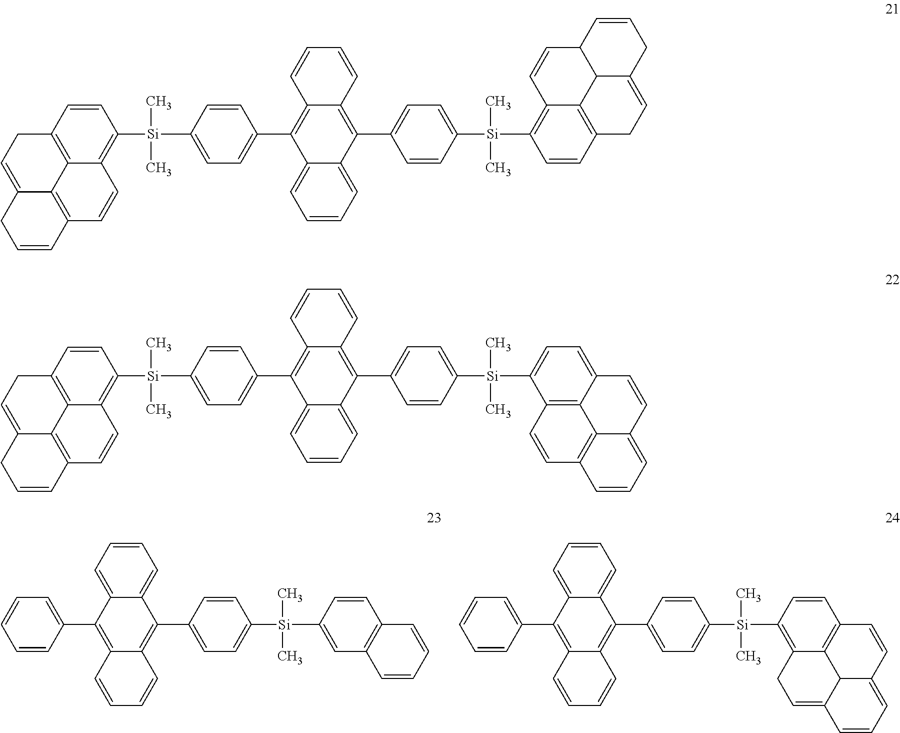

11. The organic light-emitting diode of claim 1, wherein the amine-based compound is a blue fluorescent dopant for emitting blue light via a fluorescence emission mechanism.

12. The organic light-emitting diode of claim 1, wherein, in Formula 20, R₄₁ and R₄₂ are each independently:
a C₁-C₂₀ alkyl group, a C₁-C₂₀ alkoxy group, a phenyl group, a naphthyl group, an anthracenyl group, a pyrenyl group, or a chrysenyl group; or
a C₁-C₂₀ alkyl group, a C₁-C₂₀ alkoxy group, a phenyl group, a naphthyl group, an anthracenyl group, a pyrenyl group, or a chrysenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyrenyl group, or a chrysenyl group.

13. The organic light-emitting diode of claim 1, wherein, in Formula 20:
ia=0 & ja=0; or
ia=1 & ja=0; or
ia=0 & ja=1; or
ia=1 & ja=1.

14. The organic light-emitting diode of claim 1, wherein, in Formula 20, Ar₃ to Ar₆ are each independently:
a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group; or
a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₁-C₆₀ fluoroalkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, —N(Q_{11c})(Q_{12c}), or —Si(Q_{13c})(Q_{14c})(Q_{15c}) wherein Q11c through Q15c are each independently a hydrogen atom, a C₁-C₁₀ alkyl group, a C₆-C₂₀ aryl group, or a C₂-C₂₀ heteroaryl group.

15. The organic light-emitting diode of claim 1, wherein, in Formula 20, Ar₃ to Ar₆ are each independently:
a phenyl group, a naphthyl group, an azulenyl group, a heptalenyl group, a biphenylenyl group, an indacenyl group, an acenaphthalenyl group, a fluorenyl group, a spiro-fluorenyl group, an anthracenyl group, a phenalenyl group, a phenanthrenyl group, a perylenyl group, a fluoranthenyl group, a naphthacenyl group, a picenyl group, a pentaphenyl group, or a hexacenyl group; or
a phenyl group, a naphthyl group, an azulenyl group, a heptalenyl group, a biphenylenyl group, an indacenyl group, an acenaphthalenyl group, a fluorenyl group, a spiro-fluorenyl group, an anthracenyl group, a phenalenyl group, a phenanthrenyl group, a perylenyl group, a fluoranthenyl group, a naphthacenyl group, a picenyl group, a pentaphenyl group, or a hexacenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ fluoroalkyl group, a C₁-C₂₀ alkoxy group, a phenyl group, a naphthyl group, an anthracenyl group, or —Si(Q_{13c})(Q_{14c})(Q_{15c}) wherein Q_{13c} to Q_{15c} are each independently a C₁-C₂₀ alkyl group, a phenyl group, a naphthyl group, or an anthracenyl group.

16. The organic light-emitting diode of claim 1, wherein the amine-based compound is represented by Formula 20-1: 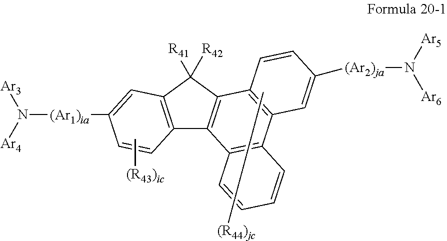
wherein, in Formula 20-1, ic is an integer of 0 to 3, and jc is an integer of 0 to 7.

17. The organic light-emitting diode of claim 16, wherein, in Formula 20-1, R₄₁ and R₄₂ are each independently:
a C₁-C₂₀ alkyl group, a C₁-C₂₀ alkoxy group, a phenyl group, a naphthyl group, an anthracenyl group, a pyrenyl group, or a chrysenyl group; or
a C₁-C₂₀ alkyl group, a C₁-C₂₀ alkoxy group, a phenyl group, a naphthyl group, an anthracenyl group, a pyrenyl group, or a chrysenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyrenyl group, or a chrysenyl group;
R₄₃ and R₄₄ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyrenyl group, or a chrysenyl group;
Ar₁ and Ar₂ are each independently:
a cyclopropylene group, a cyclobutylene group, a cyclopentylene group, a cyclohexylene group, a cycloheptylene group, a cyclooctylene group, a cyclopentenylene group, a cyclopentadienylene group, a cyclohexenylene group, a cyclohexadienylene group, a cycloheptadienylene group, a thiophenylene group, a furanylene group, a pyrrolylene group, an imidazolylene group, a pyrazolylene group, an isothiazolylene group, an isoxazolylene group, a thiazolylene group, an oxazolylene group, an oxadiazolylene group, a thiadiazolylene group, a triazolylene group, a phenylene group, a pyridinylene group, a pyrazinylene group, a pyrimidinylene group, a pyridazinylene group, a triazinylene group, a pentalenylene group, an indenylene group, a naphthylene group, an azulenylene group, a heptalenylene group, a biphenylenylene group, an indacenylene group, an acenaphthalenylene group, a fluorenylene group, a spiro-fluorenylene group, a carbazolylene group, an anthracenylene group, a phenalenylene group, a phenanthrenylene group, a perylenylene group, a fluoranthenylene group, a naphthacenylene group, a picenylene group, a pentaphenylene group, a hexacenylene group, a dibenzofuranylene group, a phenothiazinylene group, a phenoxazinylene group, a dihydrophenazinylene group, a phenoxathiinylene group, or a phenanthridinylene group; or
a cyclopropylene group, a cyclobutylene group, a cyclopentylene group, a cyclohexylene group, a cycloheptylene group, a cyclooctylene group, a cyclopentenylene group, a cyclopentadienylene group, a cyclohexenylene group, a cyclohexadienylene group, a cycloheptadienylene group, a thiophenylene group, a furanylene group, a pyrrolylene group, an imidazolylene group, a pyrazolylene group, an isothiazolylene group, an isoxazolylene group, a thiazolylene group, an oxazolylene group, an oxadiazolylene group, a thiadiazolylene group, a triazolylene group, a phenylene group, a pyridinylene group, a pyrazinylene group, a pyrimidinylene group, a pyridazinylene group, a triazinylene group, a pentalenylene group, an indenylene group, a naphthylene group, an azulenylene group, a heptalenylene group, a biphenylenylene group, an indacenylene group, an acenaphthalenylene group, a fluorenylene group, a spiro-fluorenylene group, a carbazolylene group, an anthracenylene group, a phenalenylene group, a phenanthrenylene group, a perylenylene group, a fluoranthenylene group, a naphthacenylene group, a picenylene group, a pentaphenylene group, a hexacenylene group, a dibenzofuranylene group, a phenothiazinylene group, a phenoxazinylene group, a dihydrophenazinylene group, a phenoxathiinylene group, or a phenanthridinylene group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, or —N(Q_{11b})(Q_{12b}) wherein Q_{11b} and Q_{12b} are each independently a hydrogen atom, a C₁-C₁₀ alkyl group, a C₆-C₂₀ aryl group, or a C₂-C₂₀ heteroaryl group; and
Ar₃ to Ar₆ are each independently:
a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group; or
a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cycloheptadienyl group, a thiophenyl group, a furanyl group, a pyrrolyl group, an imidazolyl group, a pyrazolyl group, an isothiazolyl group, an isoxathiazolyl group, a thiazolyl group, an oxazolyl group, an oxadiazolyl group, a thiadiazolyl group, a triazolyl group, a phenyl group, a pyridinyl group, a pyridazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthalenyl group, a fluorenyl group, a spiro-fluorenyl group, a carbazolyl group, an anthracenyl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxathiinyl group, or a phenanthridinyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₁-C₆₀ fluoroalkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, a C₂-C₆₀ heteroaryl group, —N(Q_{11c})(Q_{12c}), or —Si(Q_{13c})(Q_{14c})(Q_{15c}) wherein Q_{11c} through Q_{15c} are each independently a hydrogen atom, a C₁-C₁₀ alkyl group, a C₆-C₂₀ aryl group, or a C₂-C₂₀ heteroaryl group.

18. The organic light-emitting diode of claim 16, wherein, in Formula 20-1,
ia=0 & ja=0; or
ia=1 & ja=0; or
ia=0 & ja=1; or
ia=1 & ja=1.

19. The organic light-emitting diode of claim 1, wherein the amine-based compound is represented by one of Compounds 25 to 116:

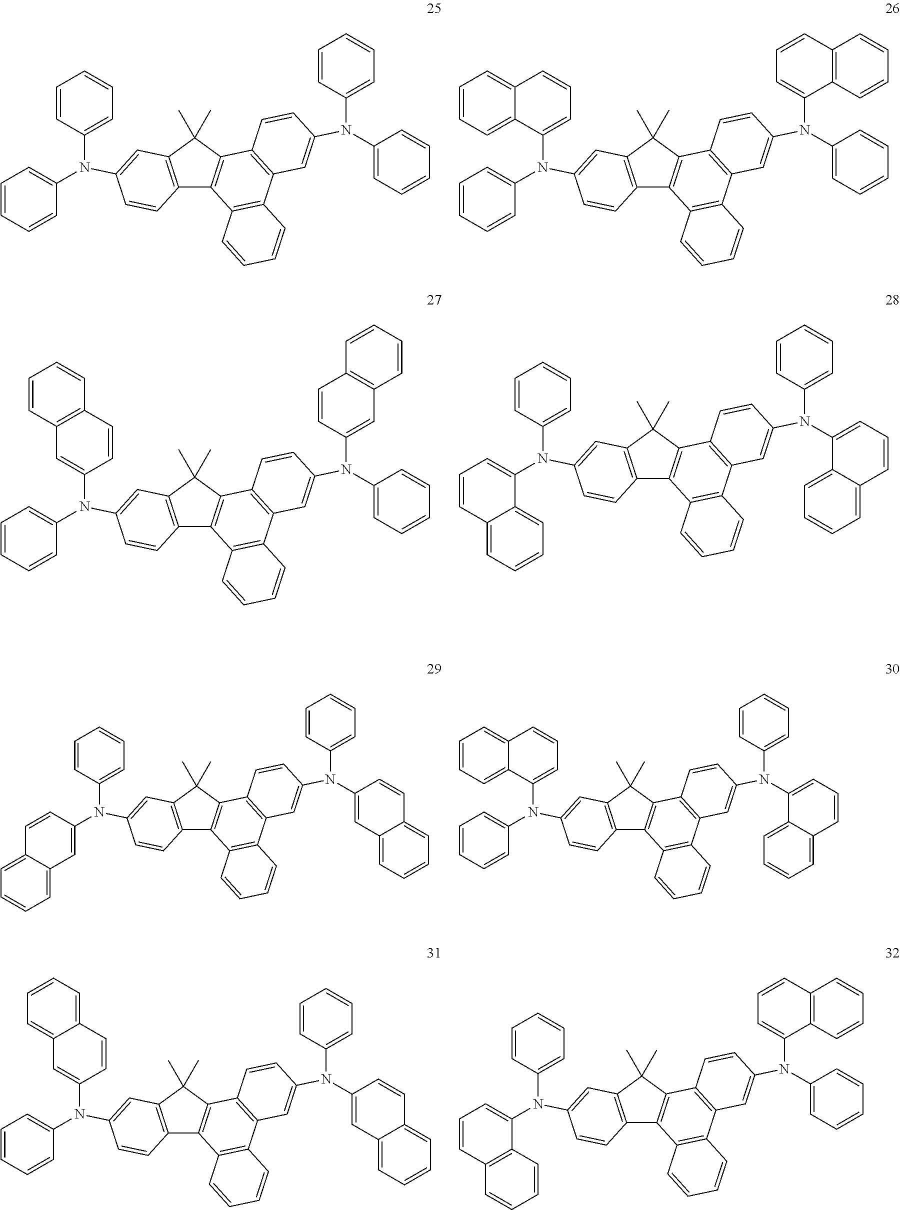

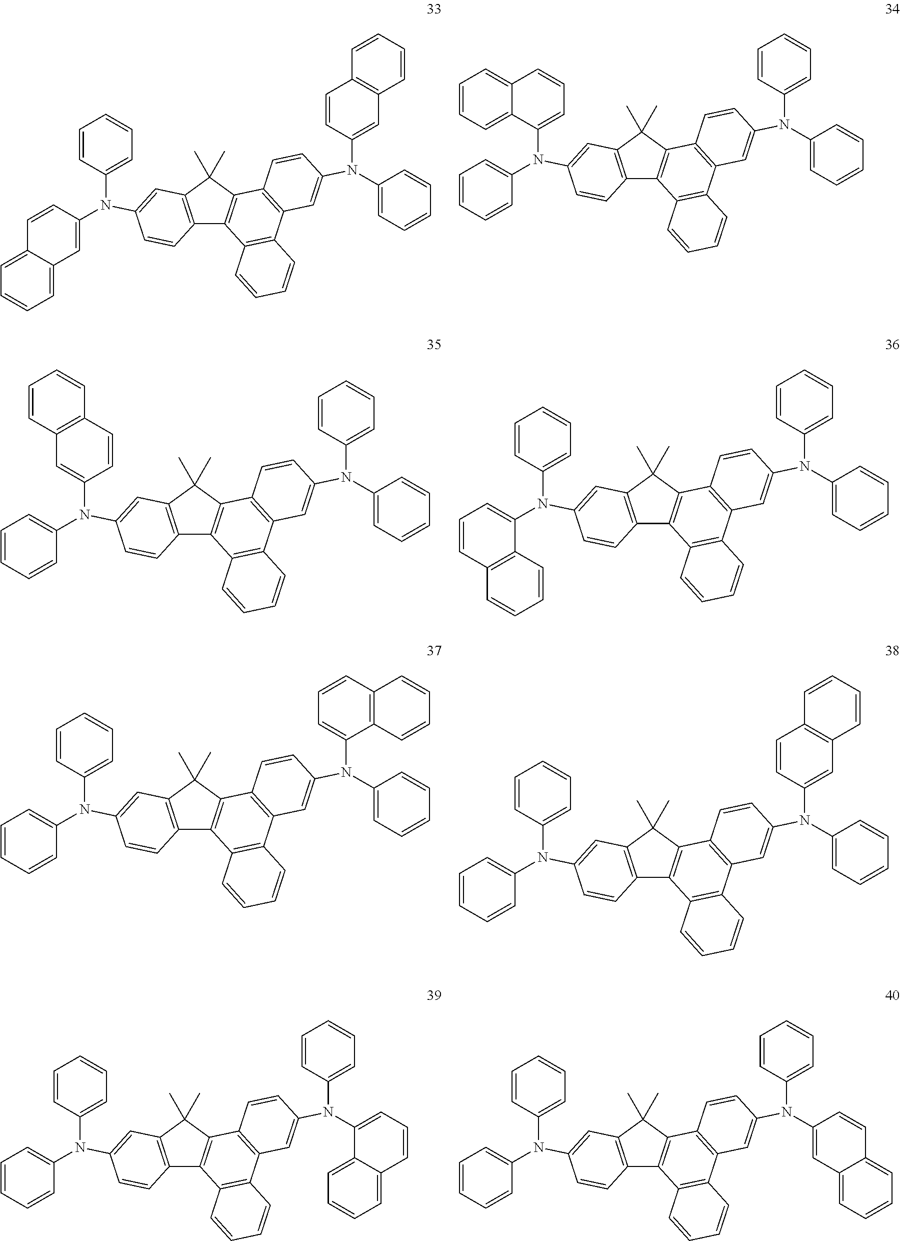

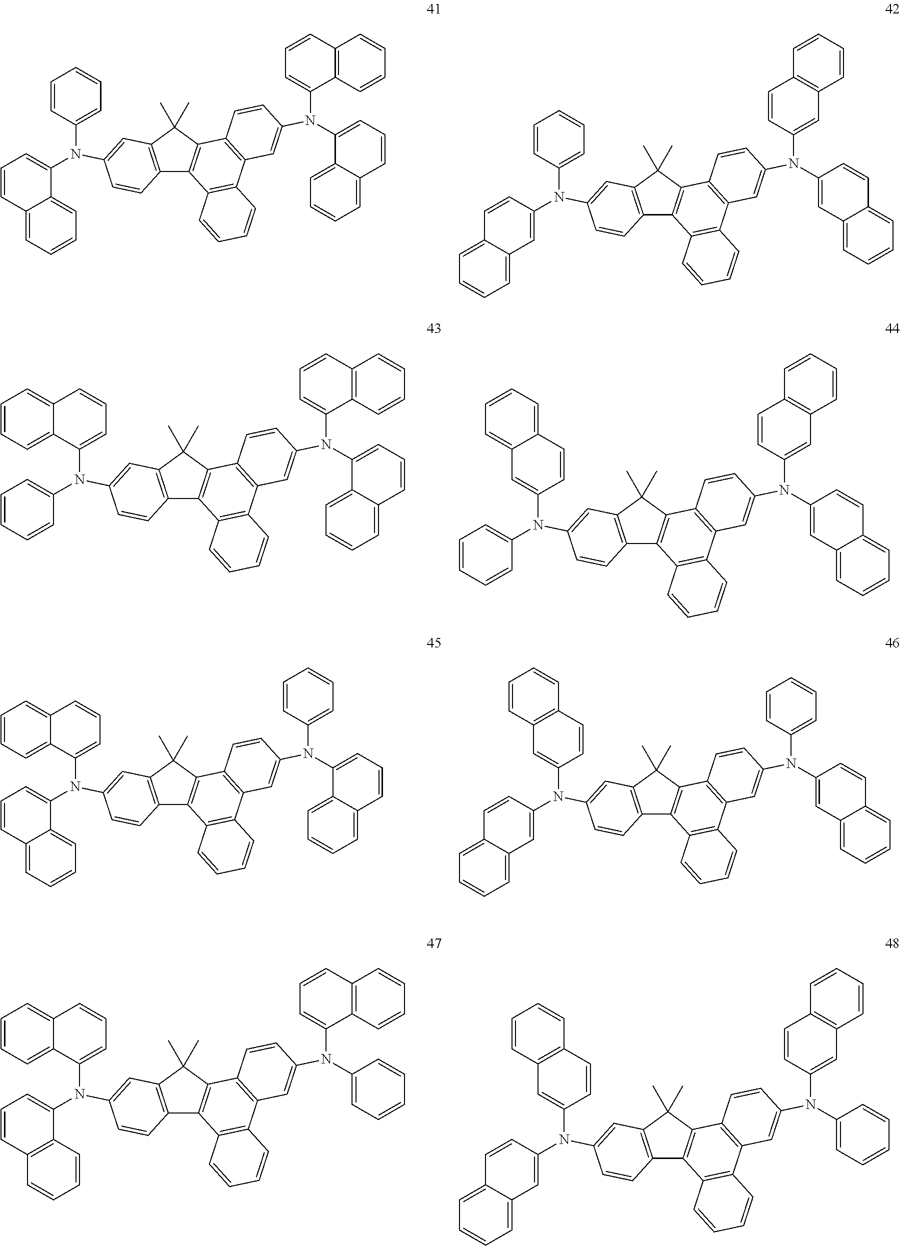

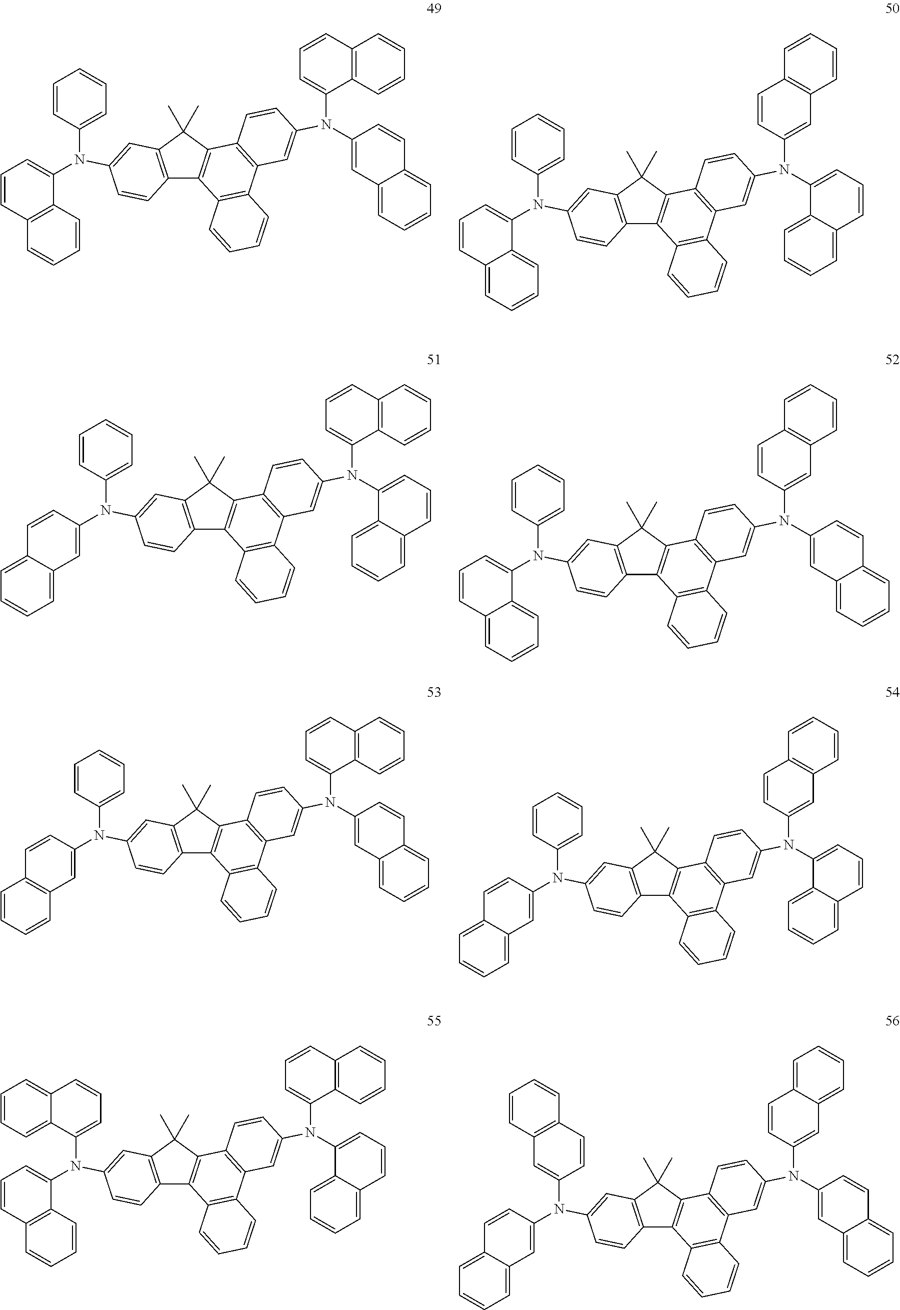

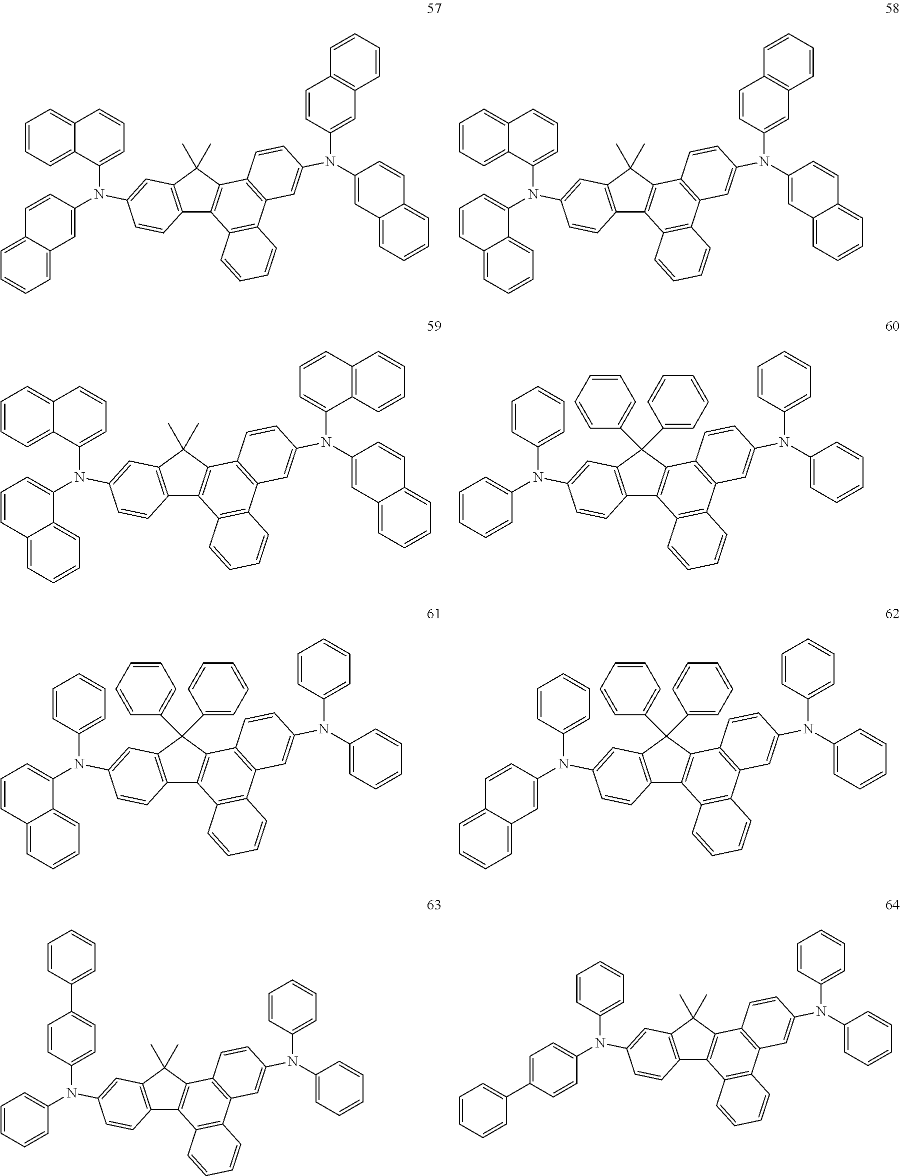

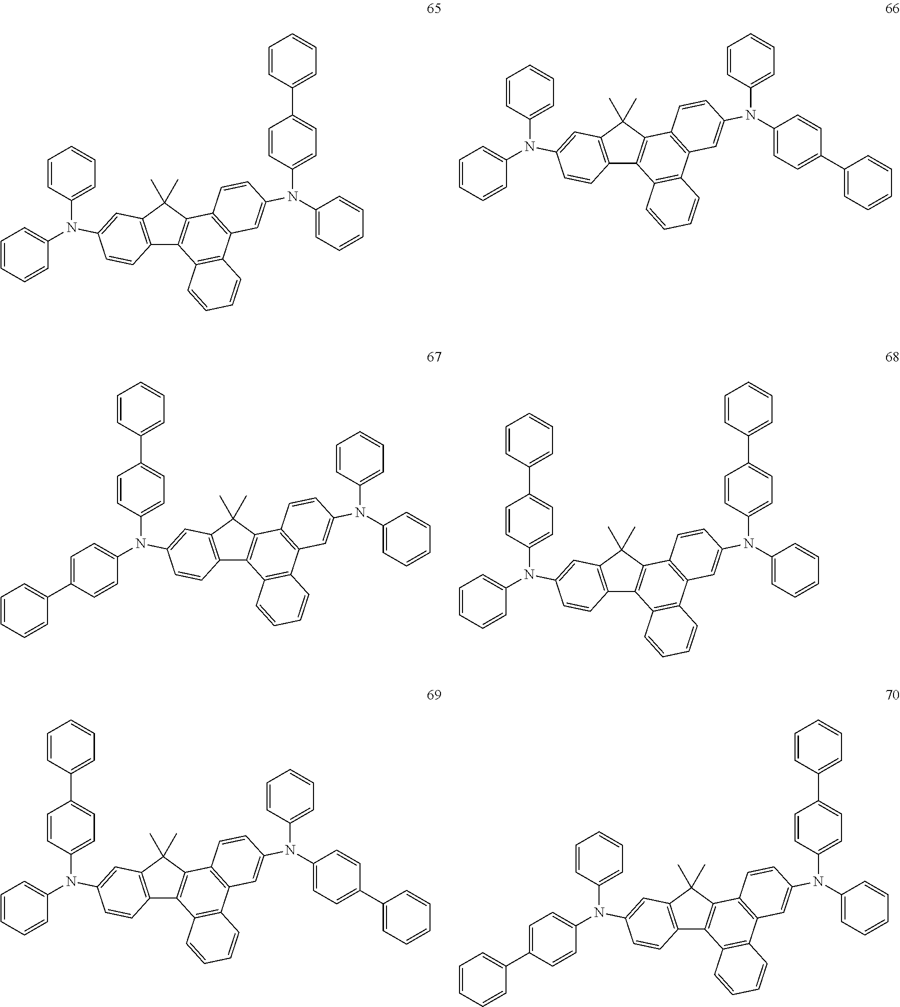

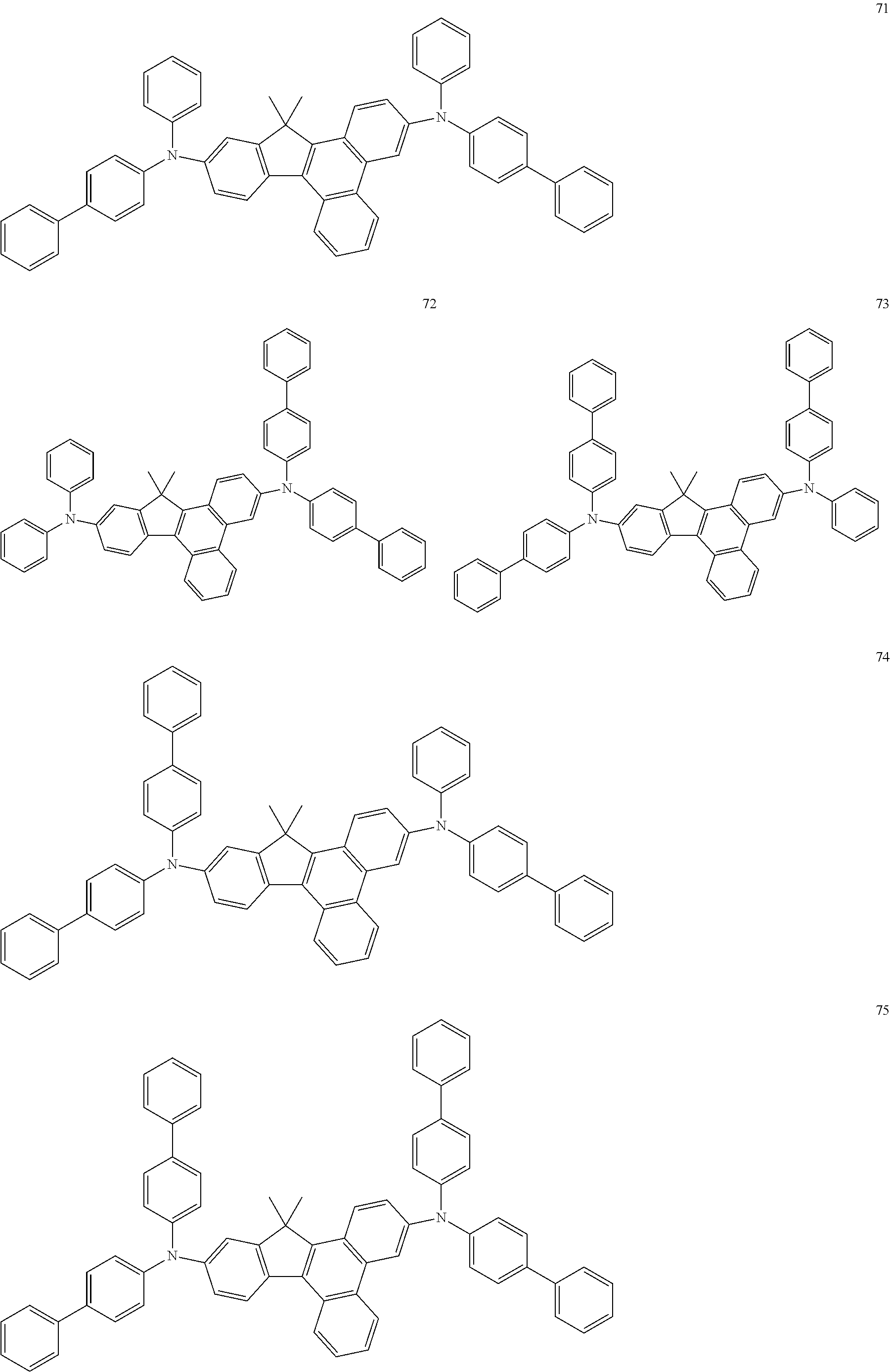

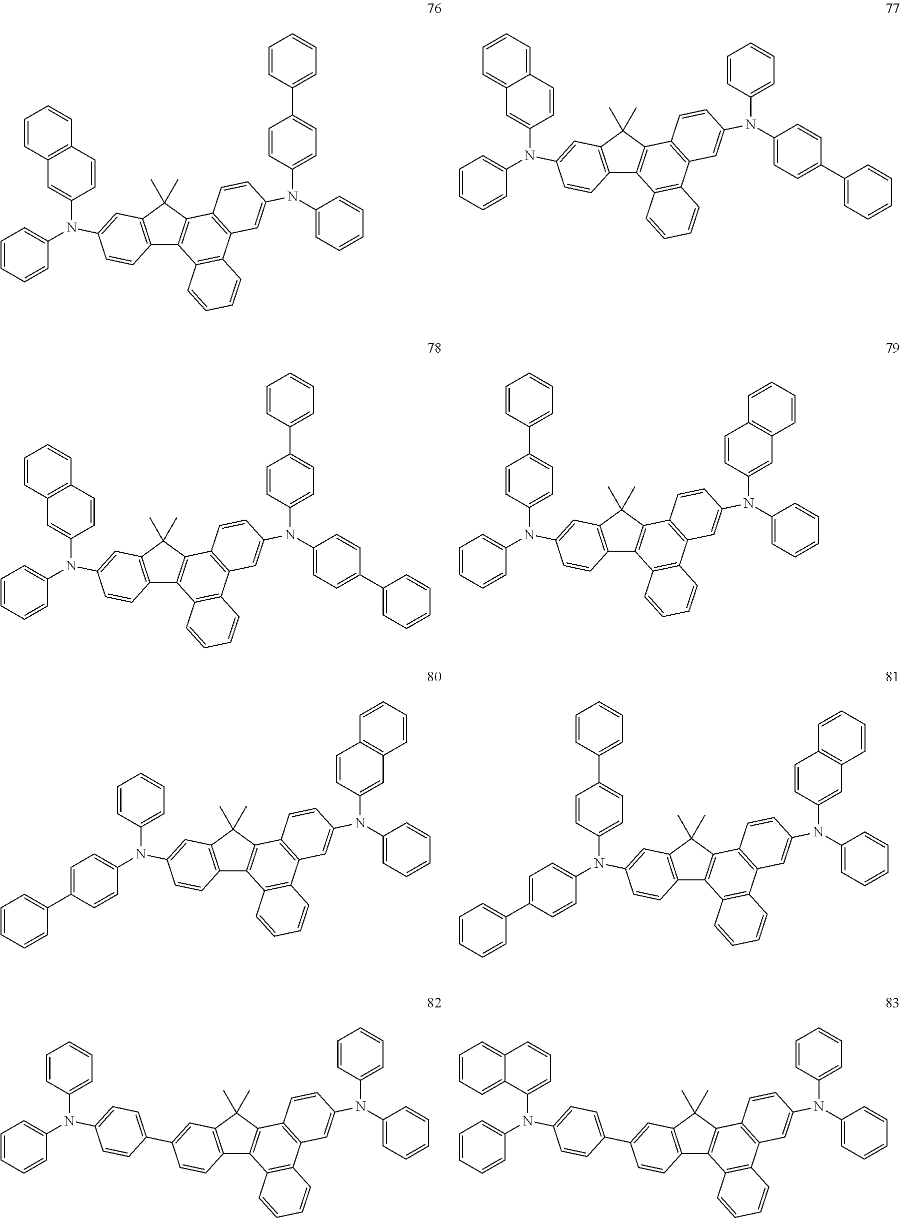

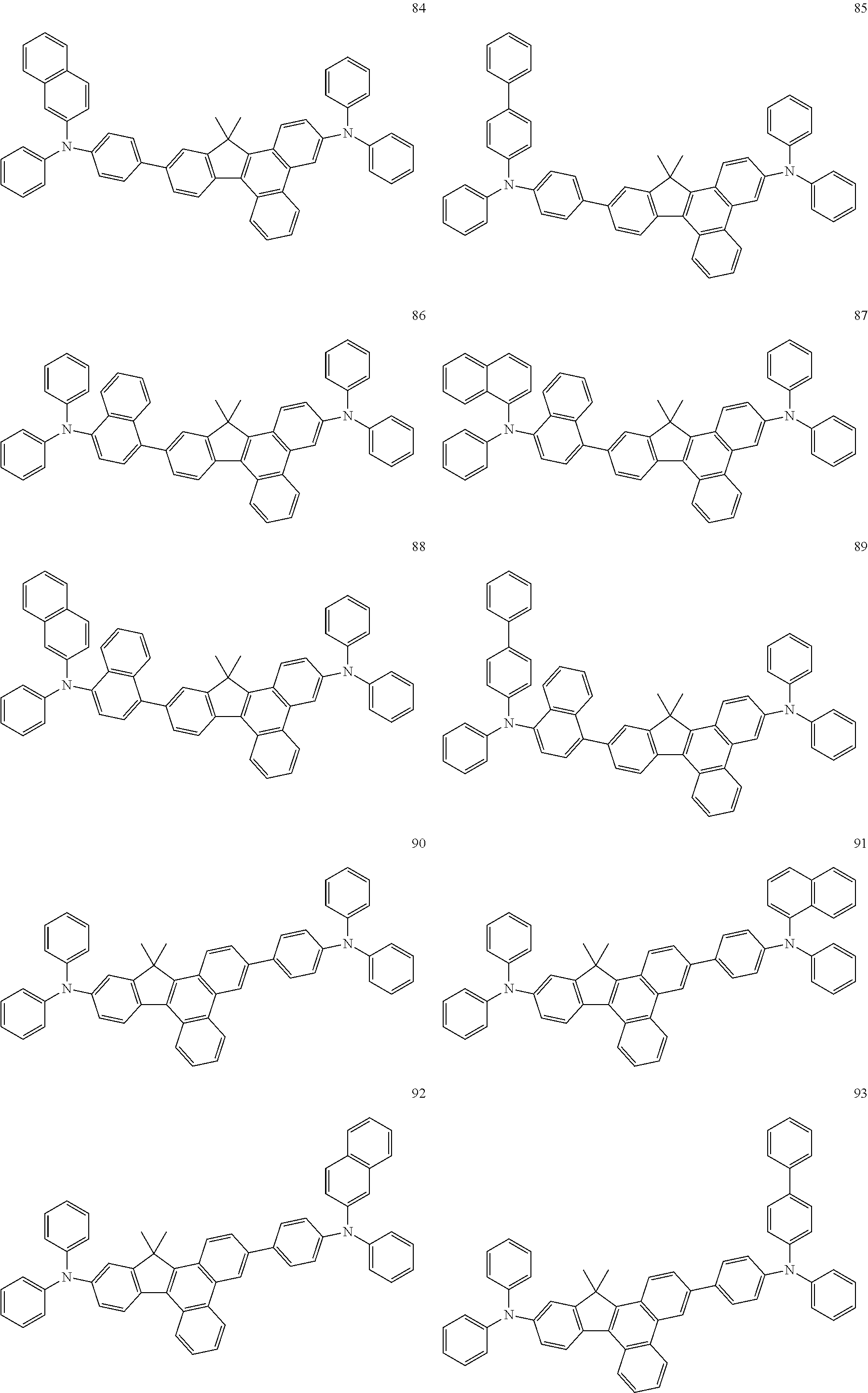

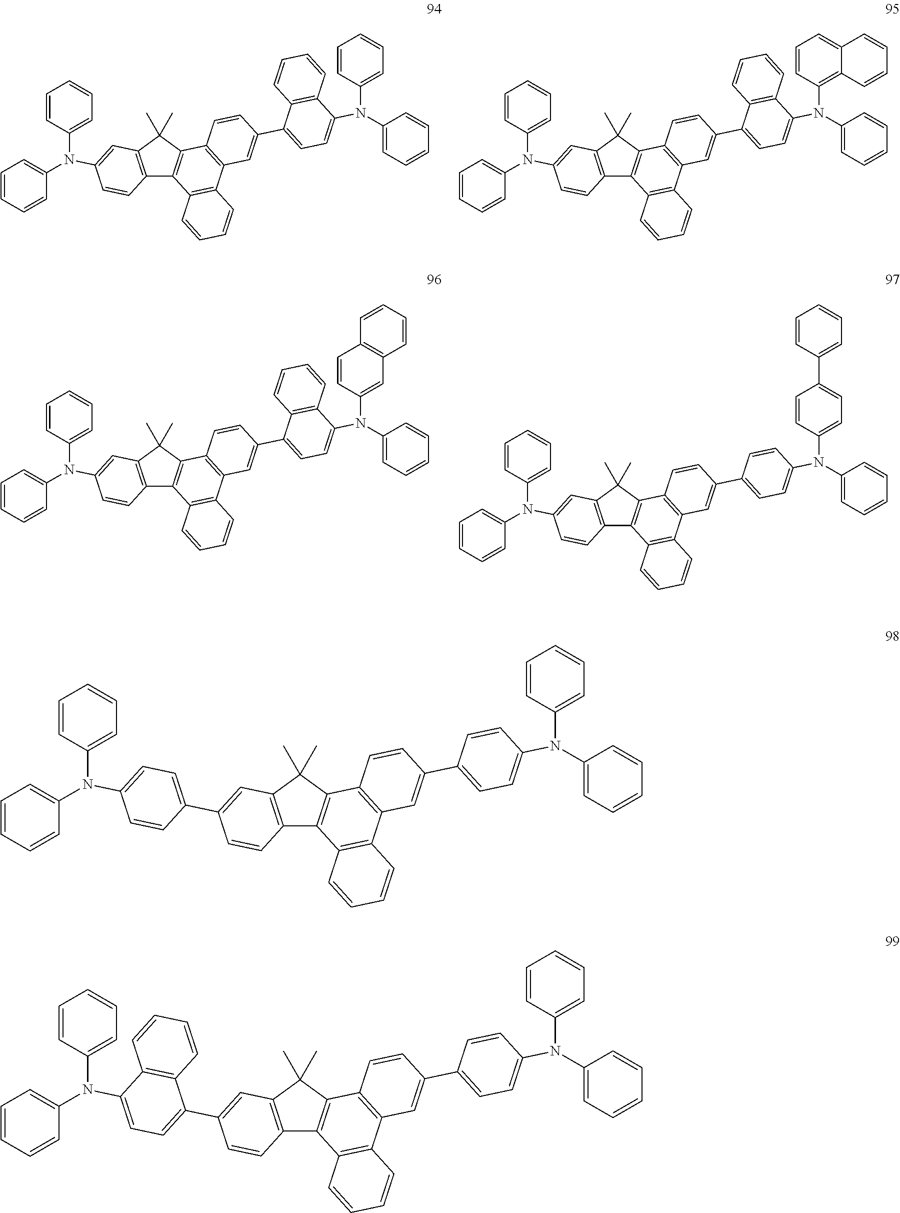

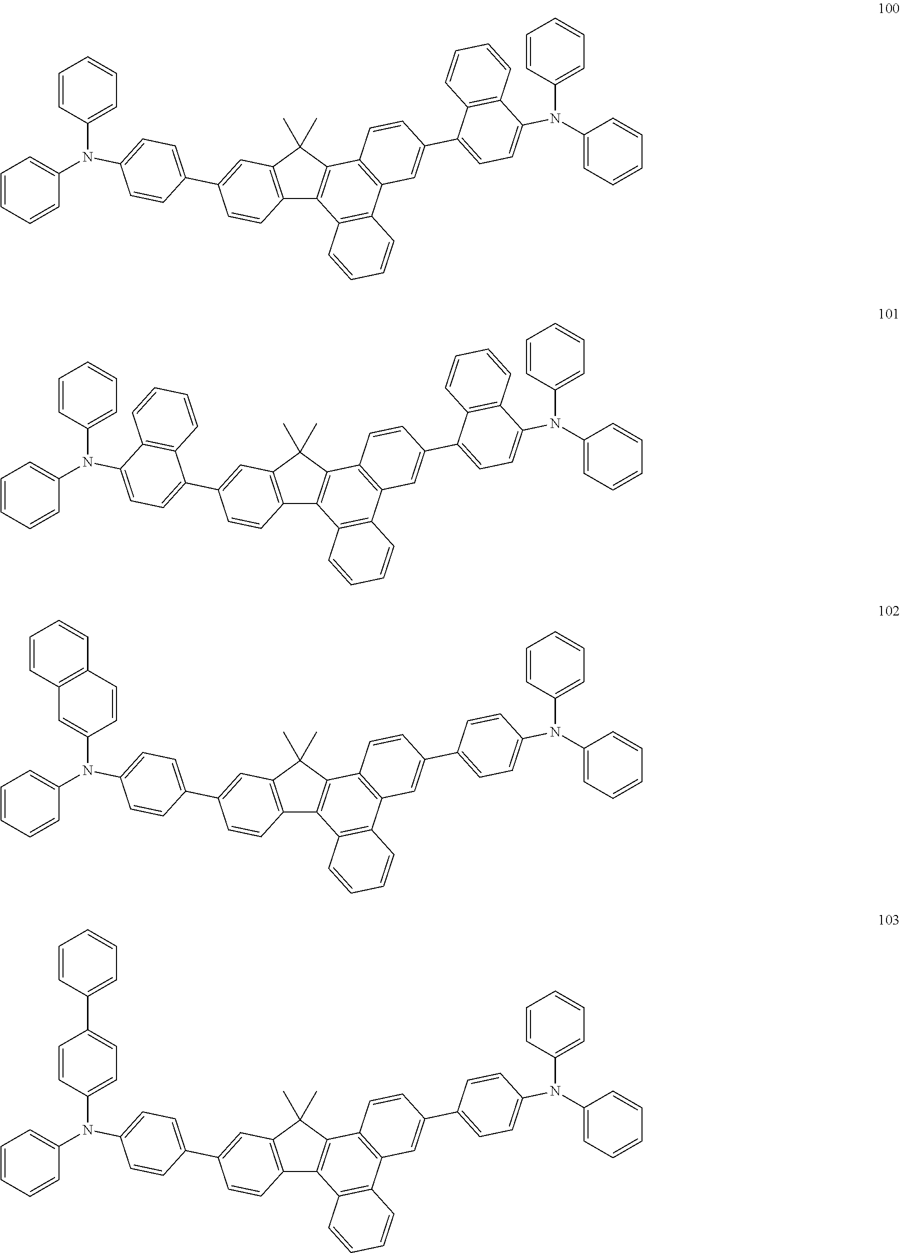 [SMILES: CC1(C)c2cc(-c3ccc(N(c4ccccc4)c4ccccc4)cc3)ccc2-c2c1c1ccc(-c3ccc(N(c4ccccc4)c4ccccc4)c4ccccc34)cc1c1ccccc21 ; CC1(C)c2cc(-c3ccc(N(c4ccccc4)c4ccccc4)c4ccccc34)ccc2-c2c1c1ccc(-c3ccc(N(c4ccccc4)c4ccccc4)c4ccccc34)cc1c1ccccc21 ; CC1(C)c2cc(-c3ccc(N(c4ccccc4)c4ccc5ccccc5c4)cc3)ccc2-c2c1c1ccc(-c3ccc(N(c4ccccc4)c4ccccc4)cc3)cc1c1ccccc21 ; CC1(C)c2cc(-c3ccc(N(c4ccccc4)c4ccc(-c5ccccc5)cc4)cc3)ccc2-c2c1c1ccc(-c3ccc(N(c4ccccc4)c4ccccc4)cc3)cc1c1ccccc21]

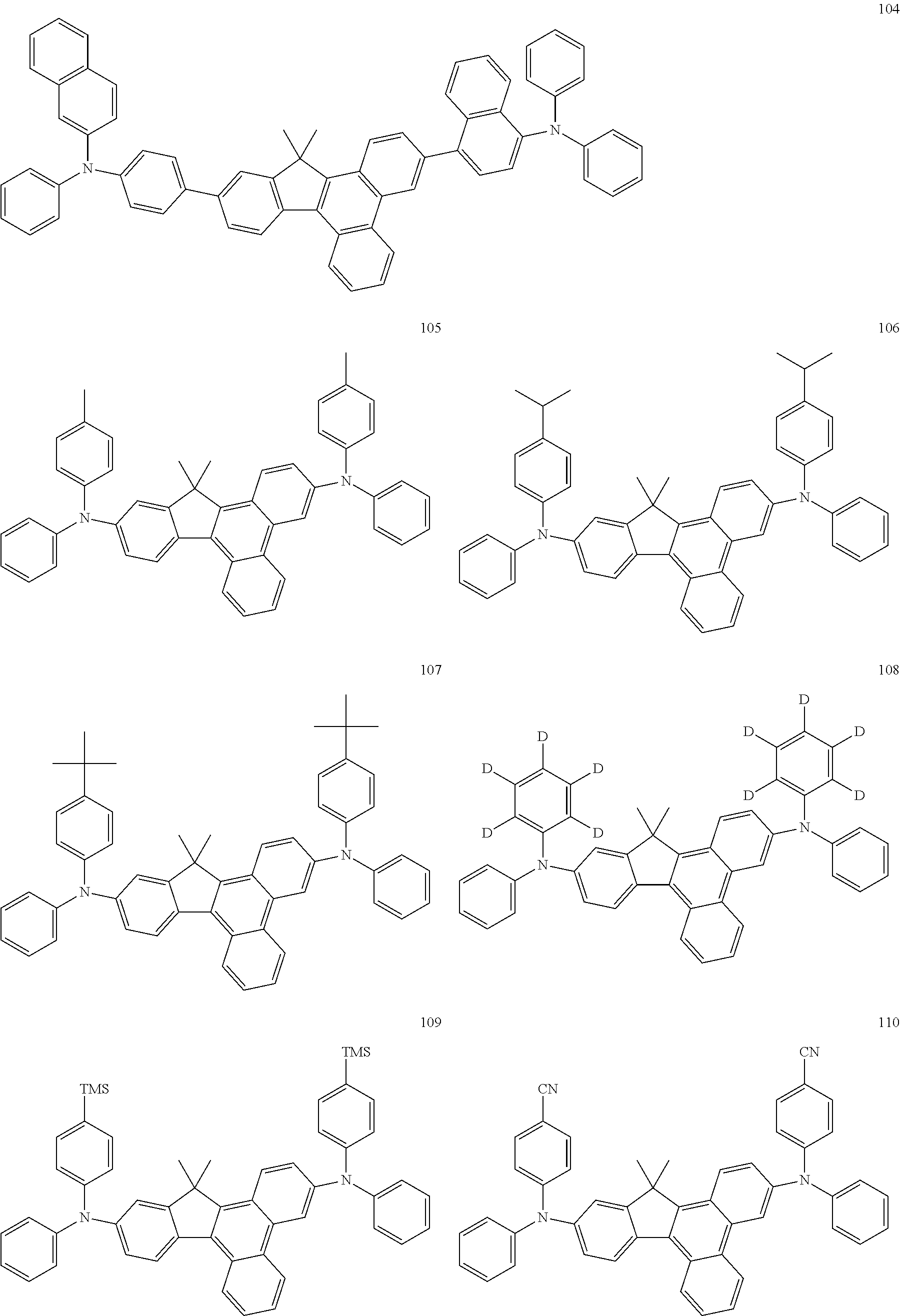

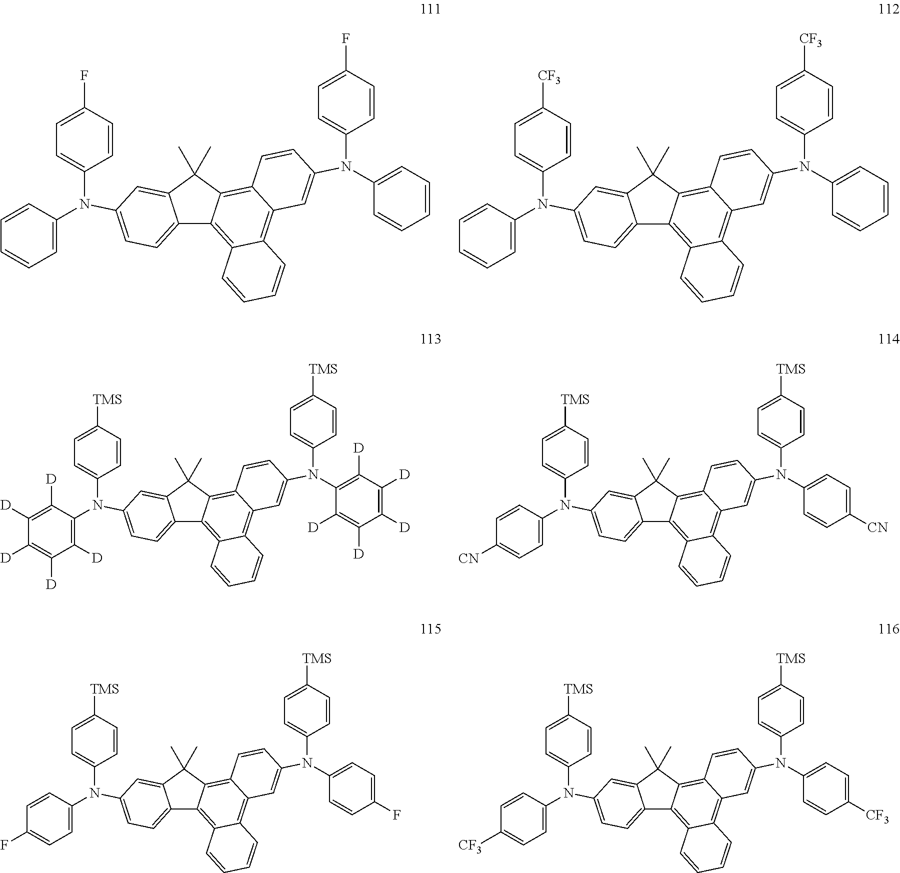

20. An organic-light emitting diode comprising:
a substrate;
a first electrode;
a second electrode facing the first electrode; and
an emission layer between the first electrode and the second electrode, the emission layer comprising an anthracene-based compound selected from the group consisting of Compounds 1 to 24, and an amine-based compound selected from the group consisting of Compounds 25 to 116: 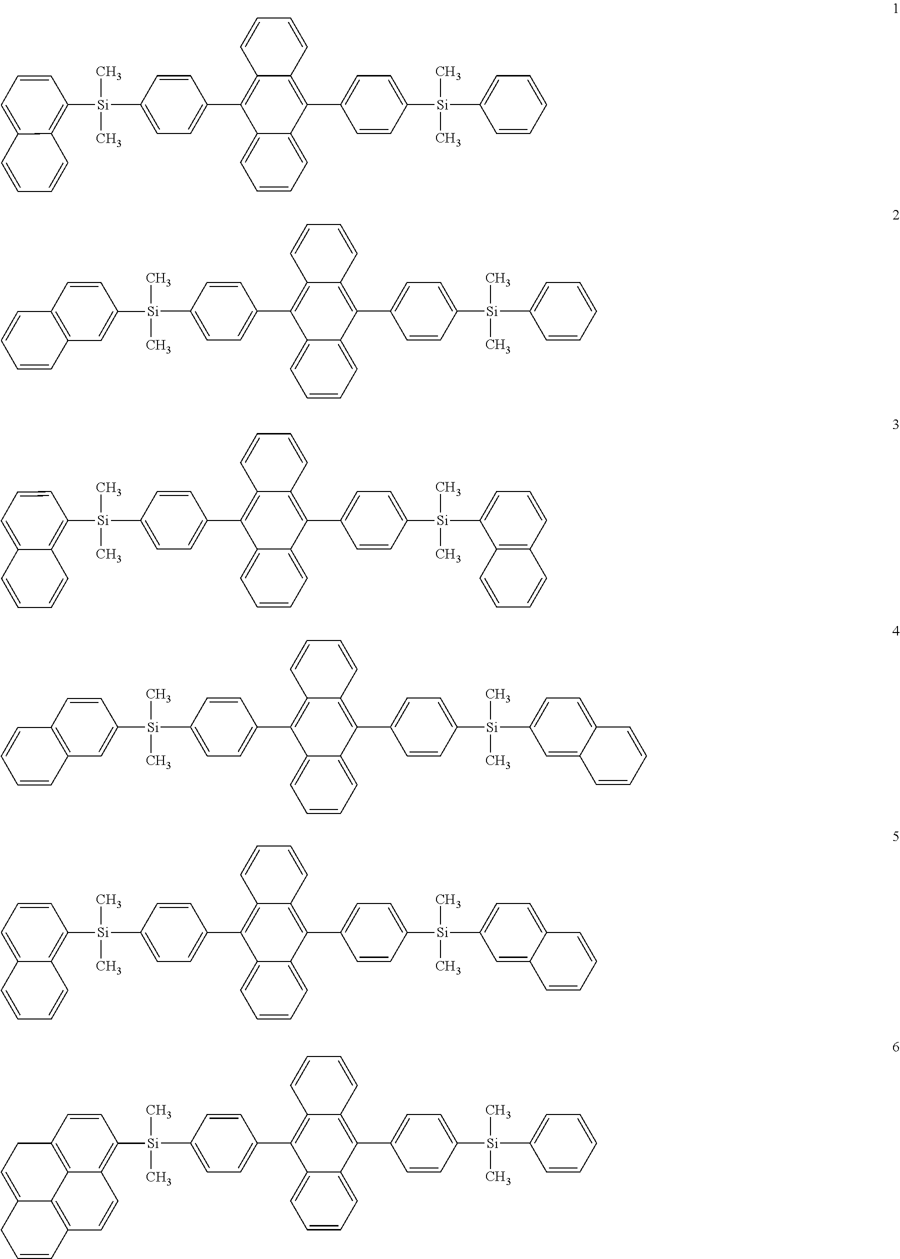 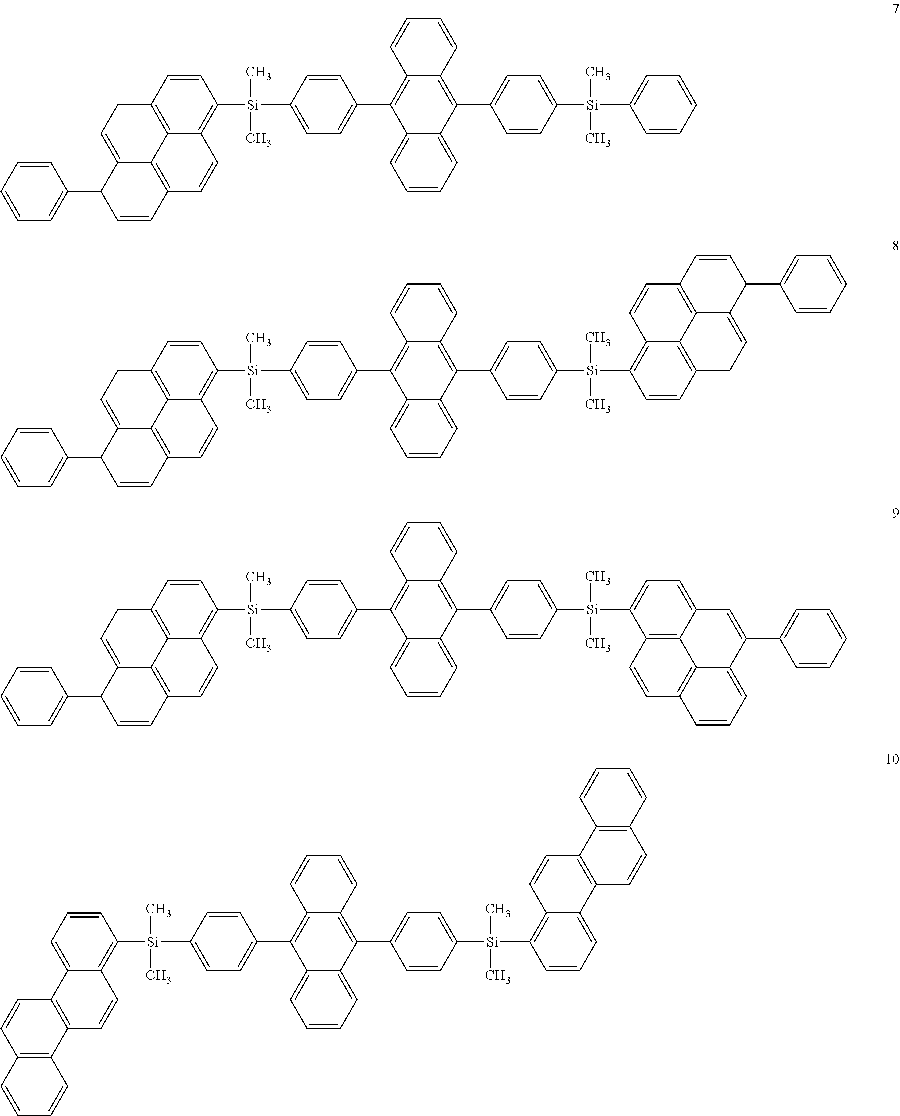 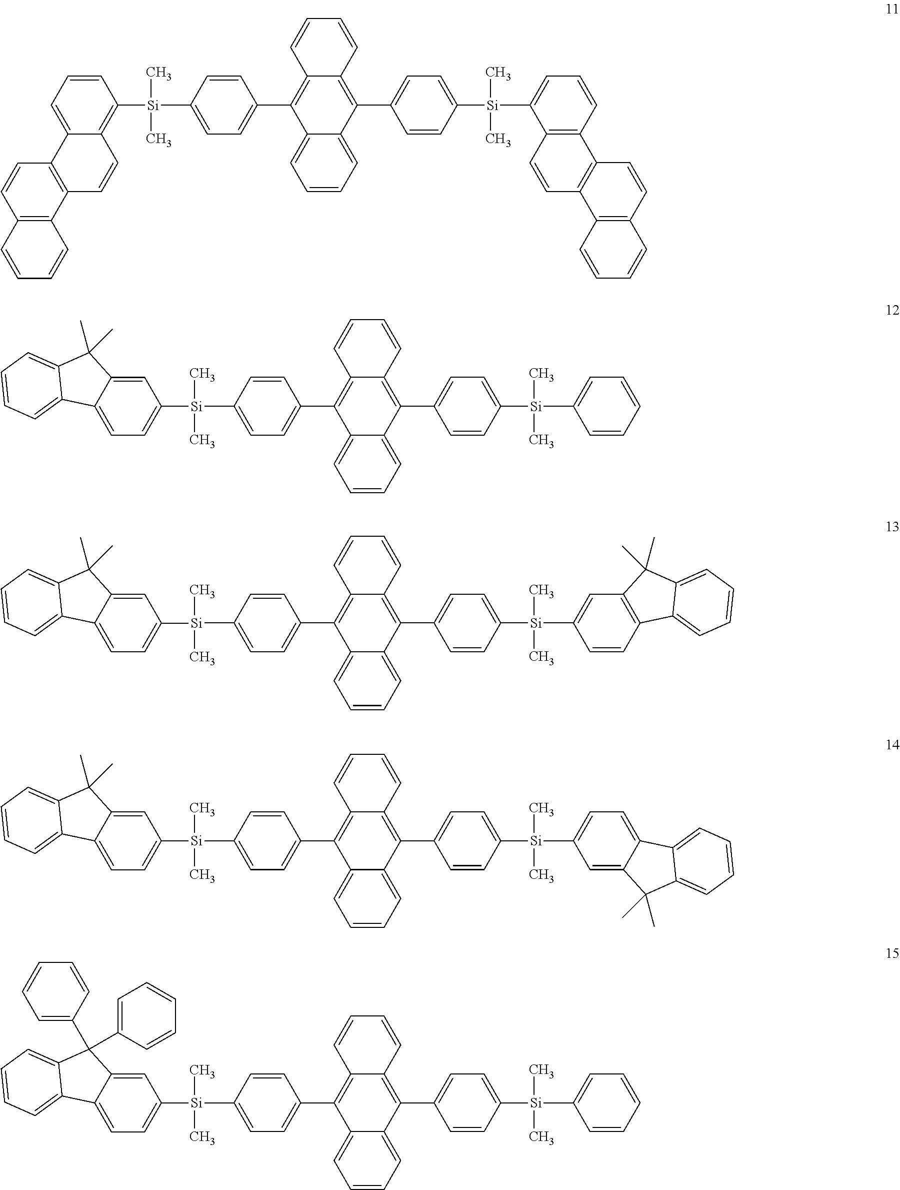 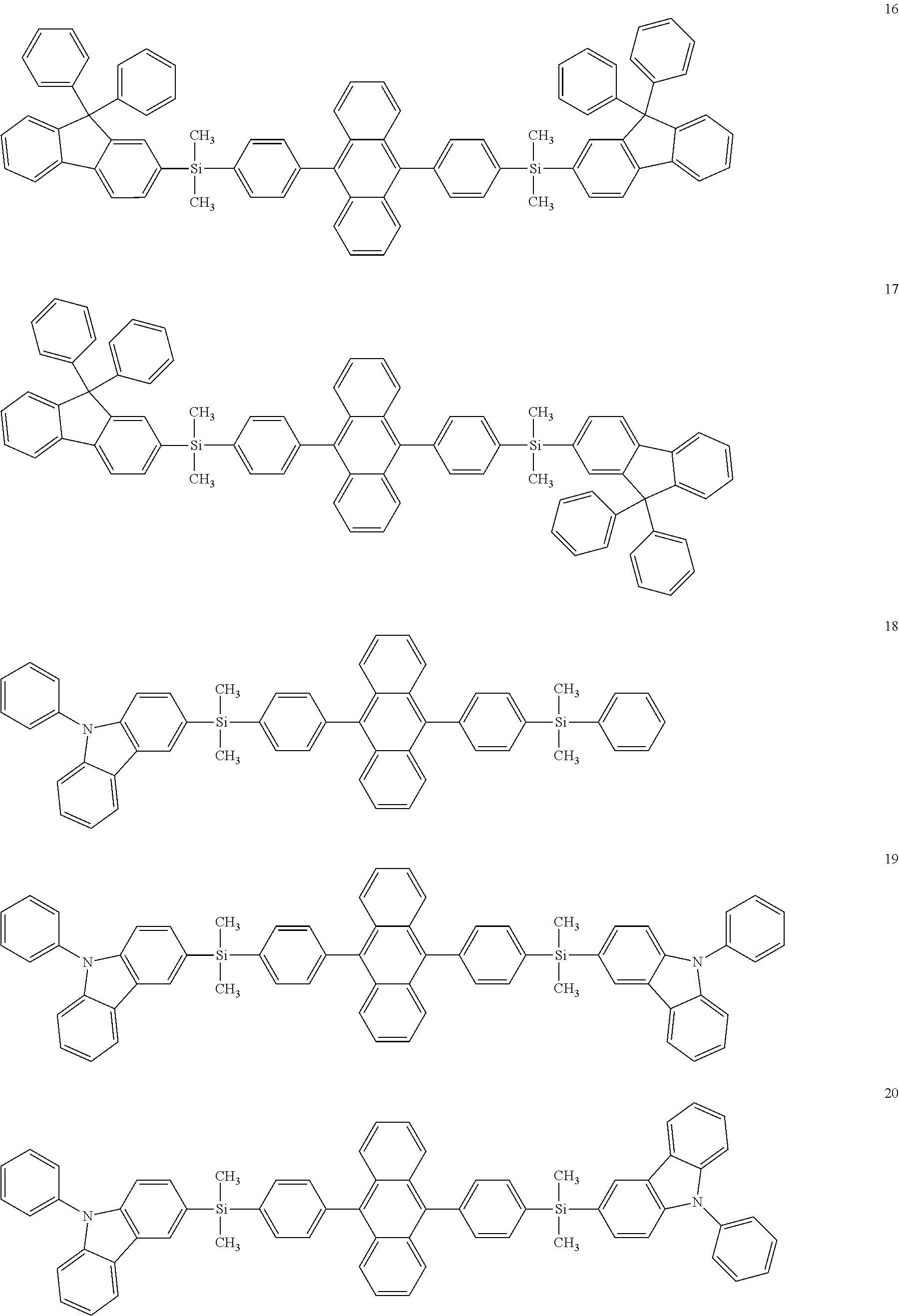 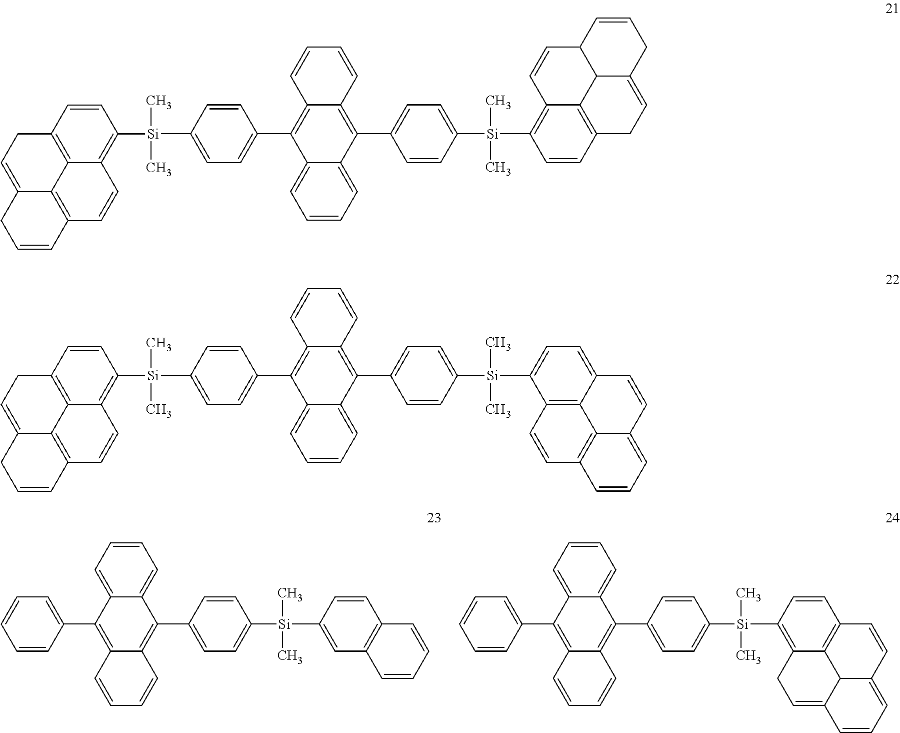 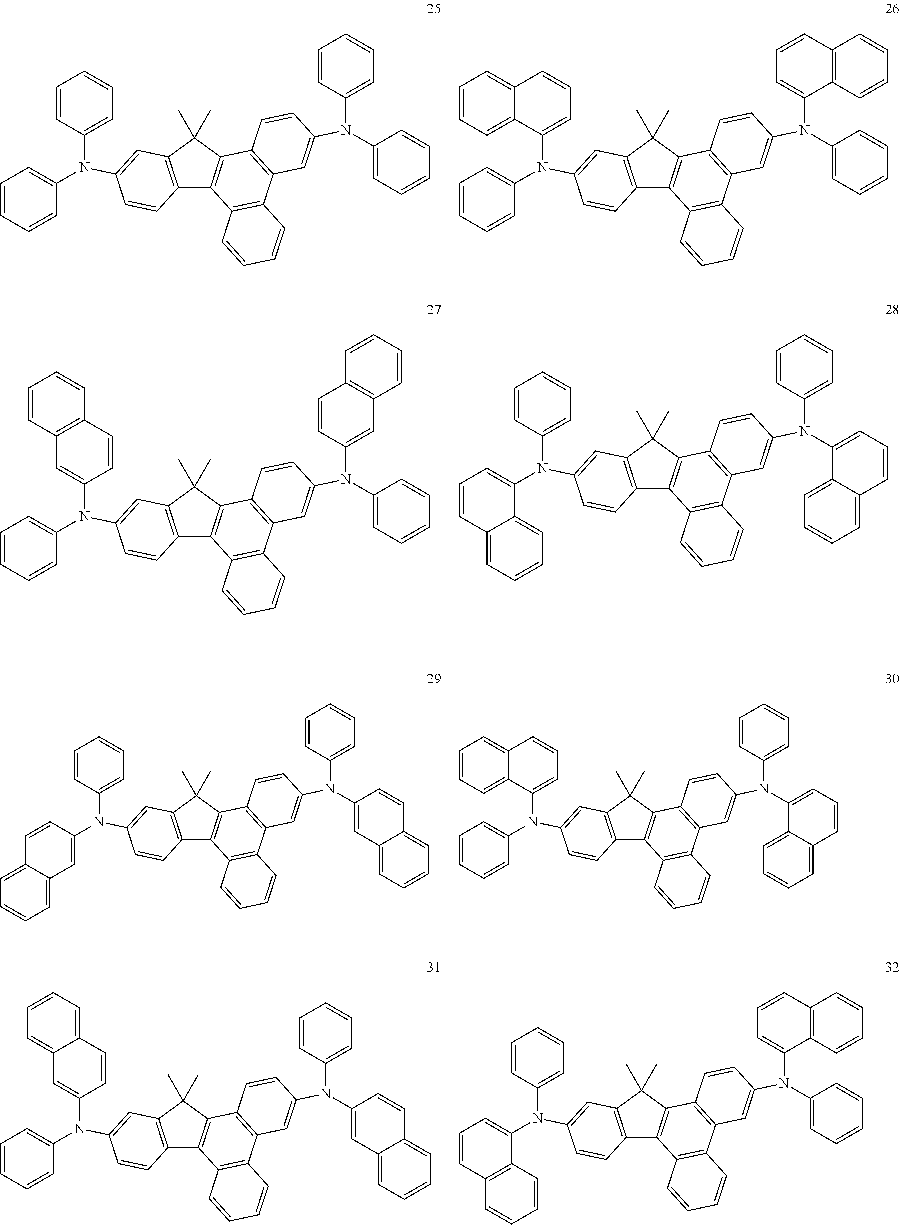 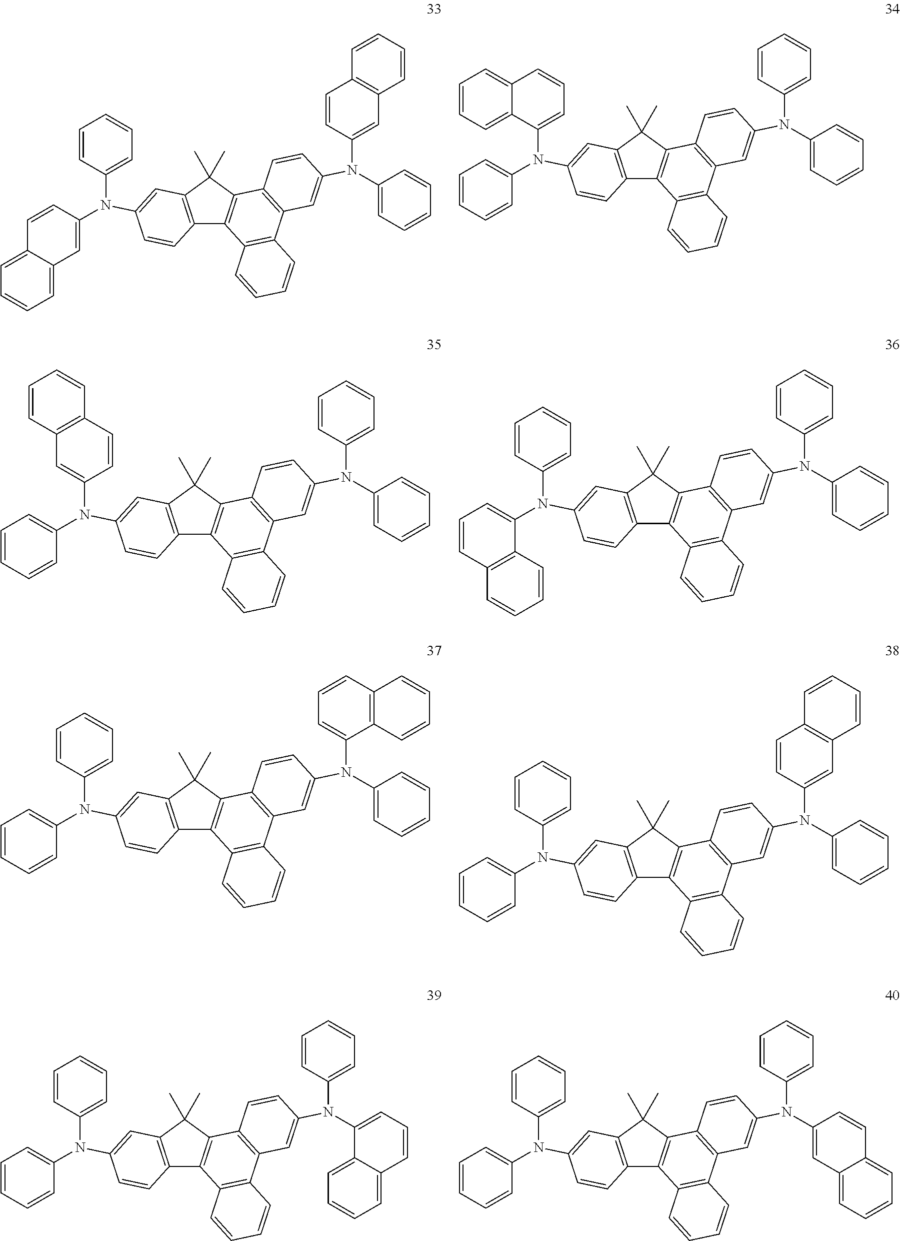 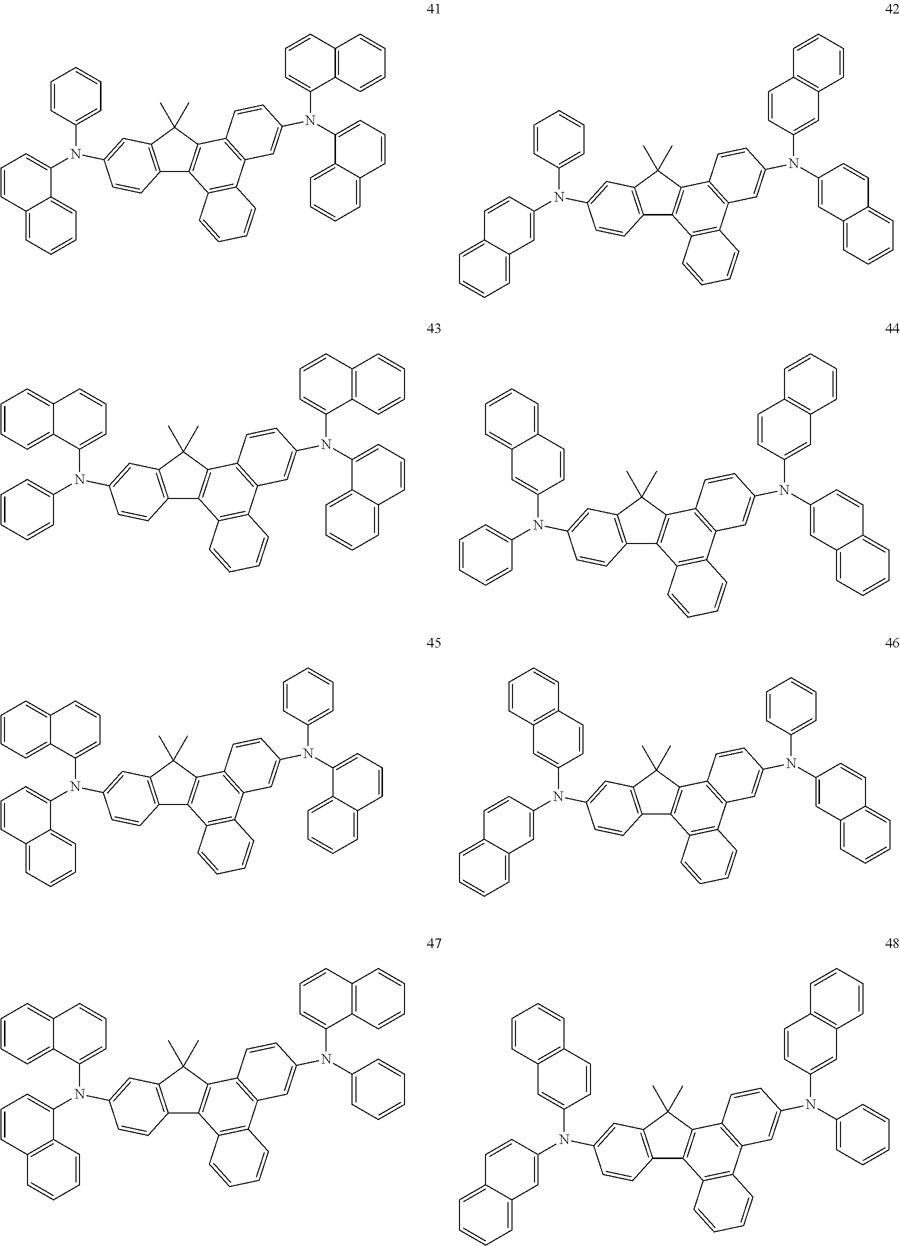 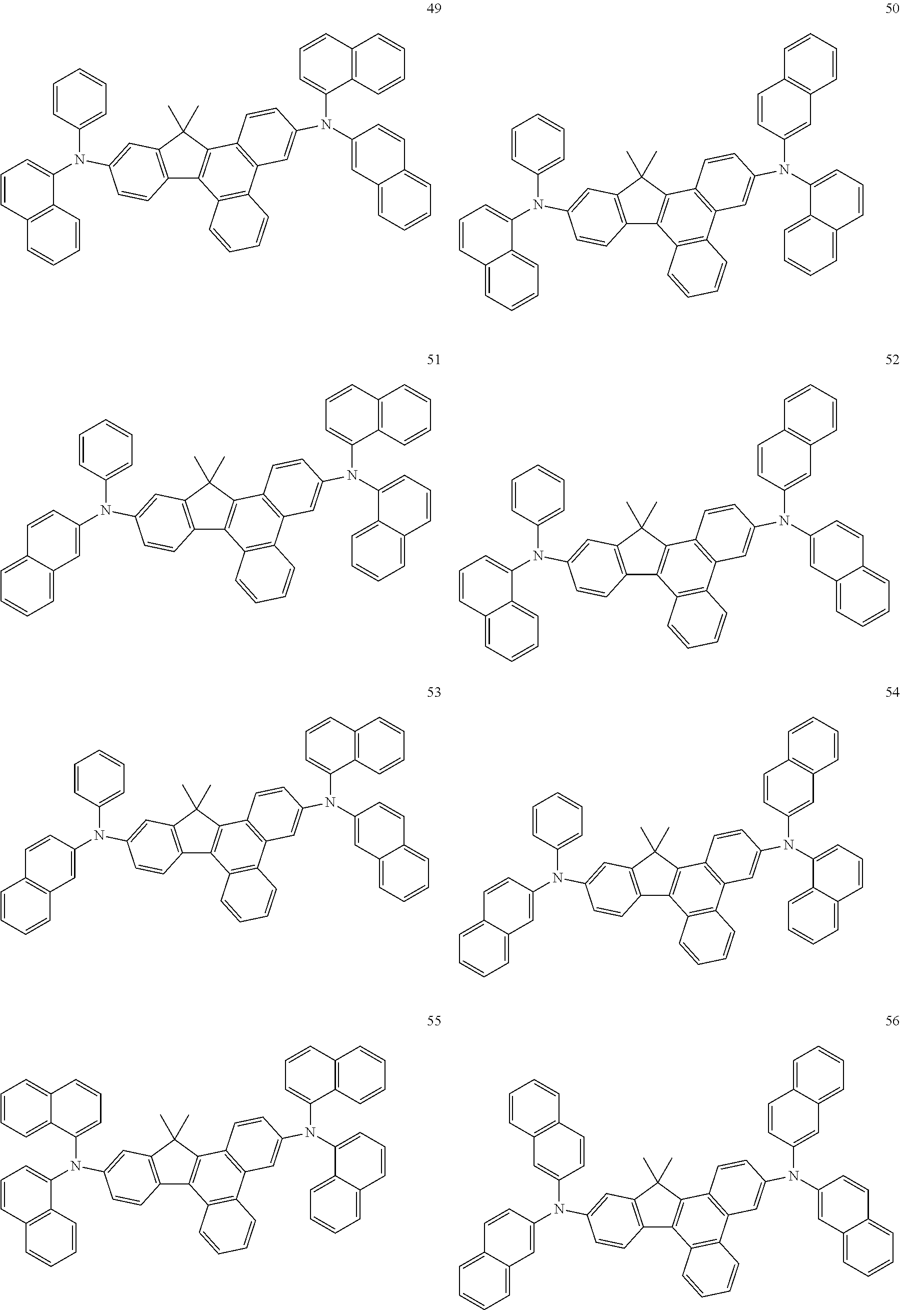 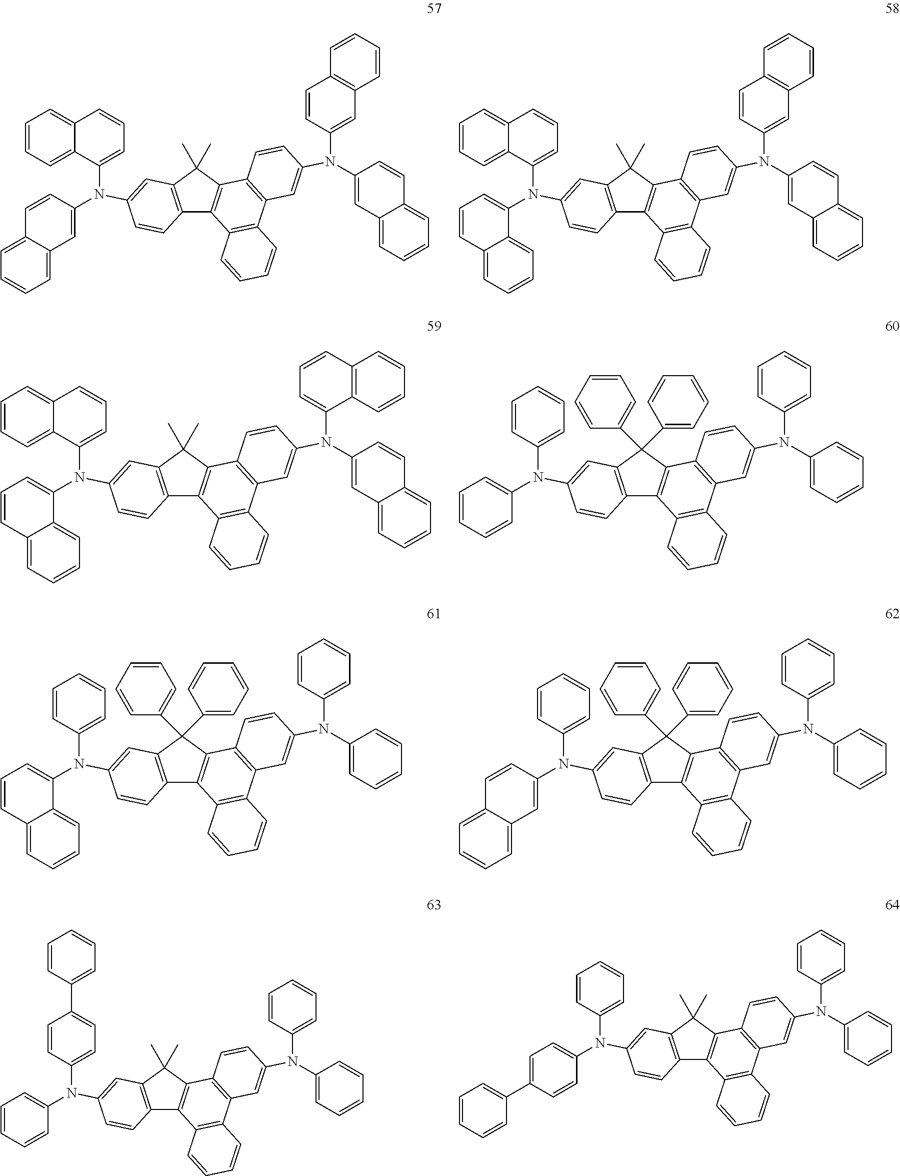 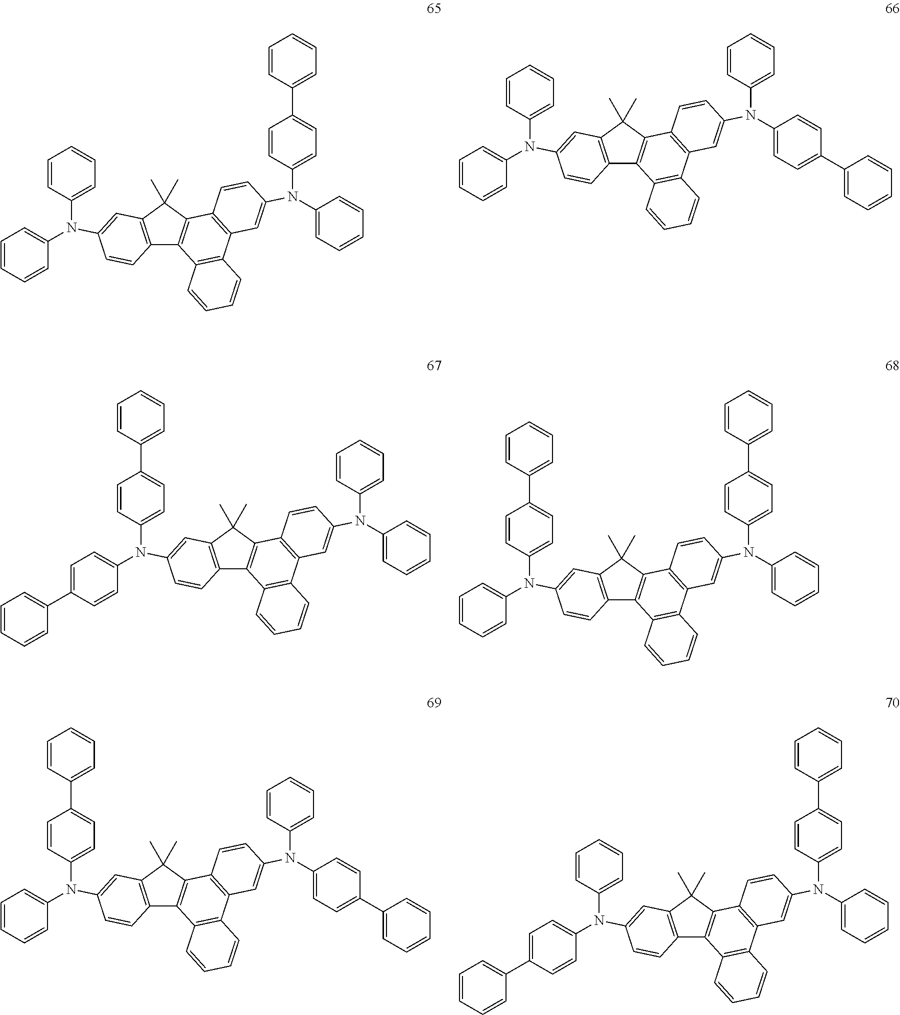 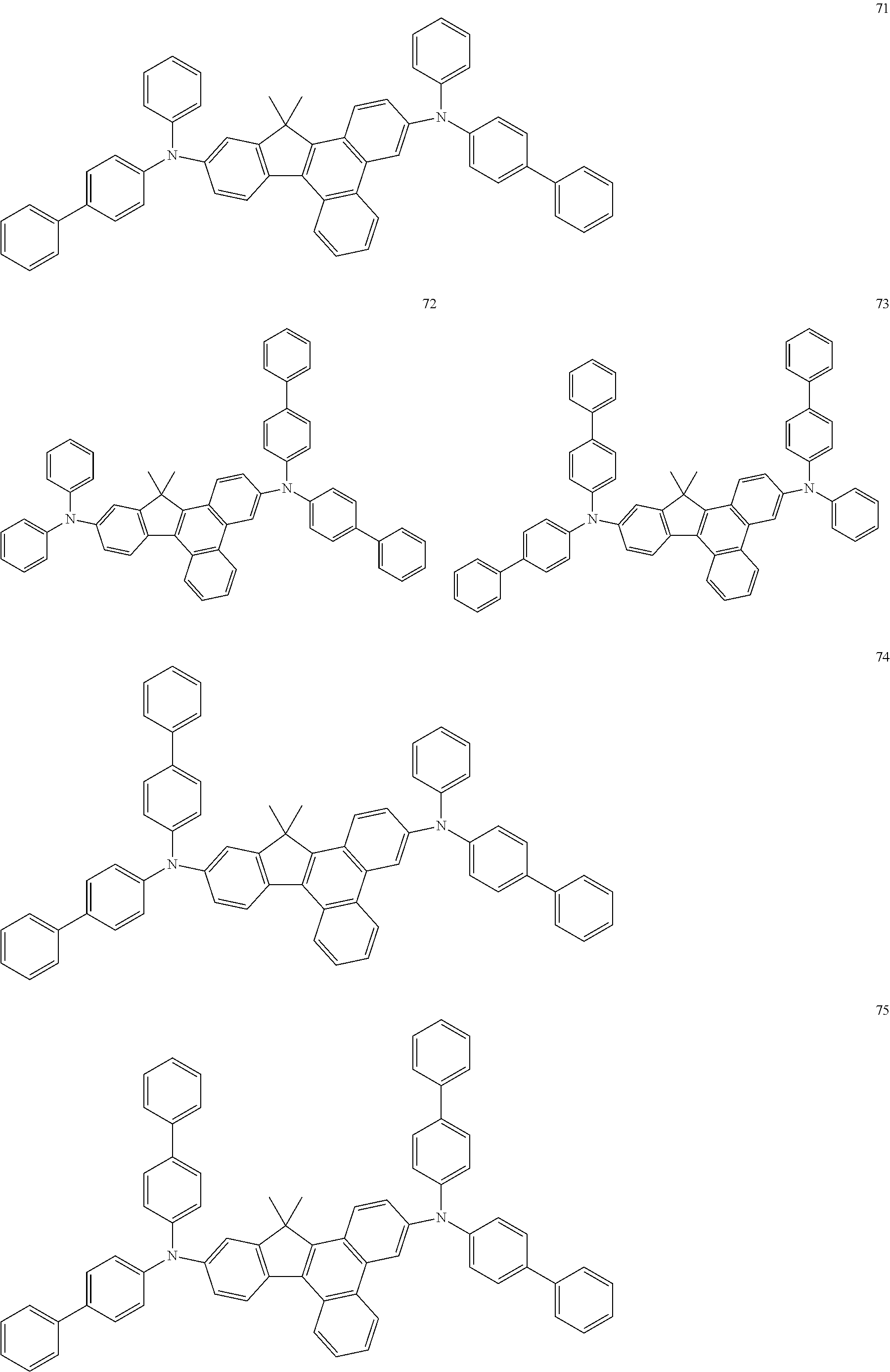 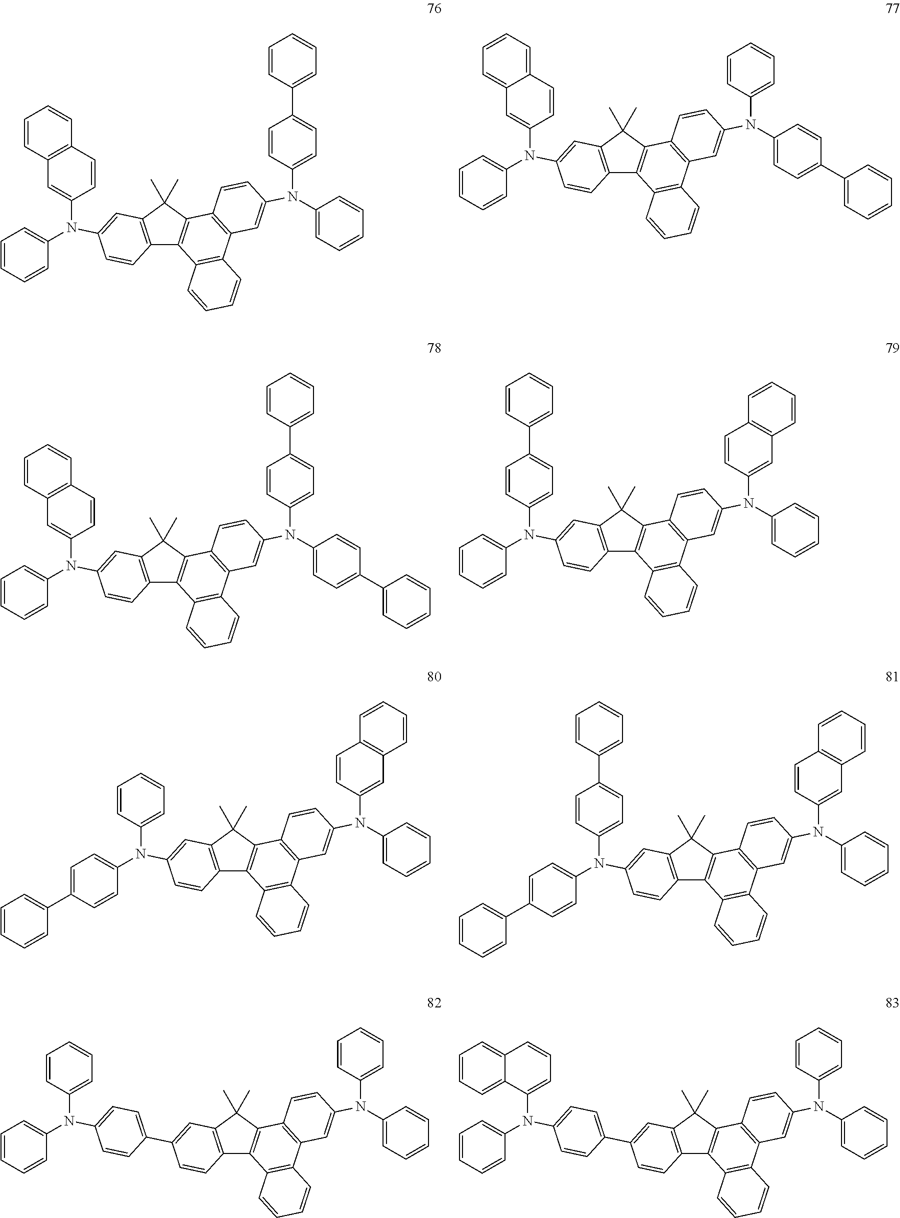 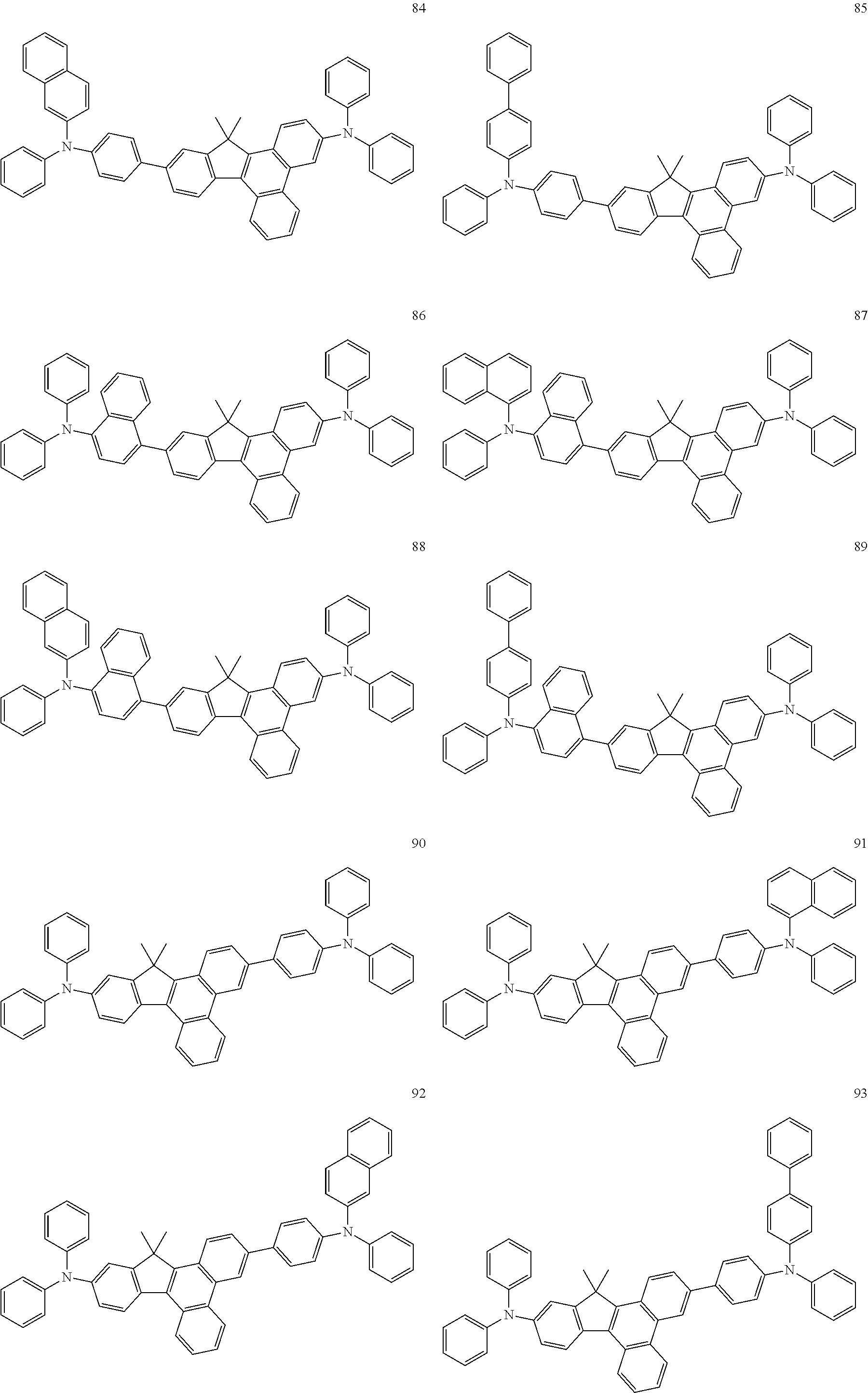 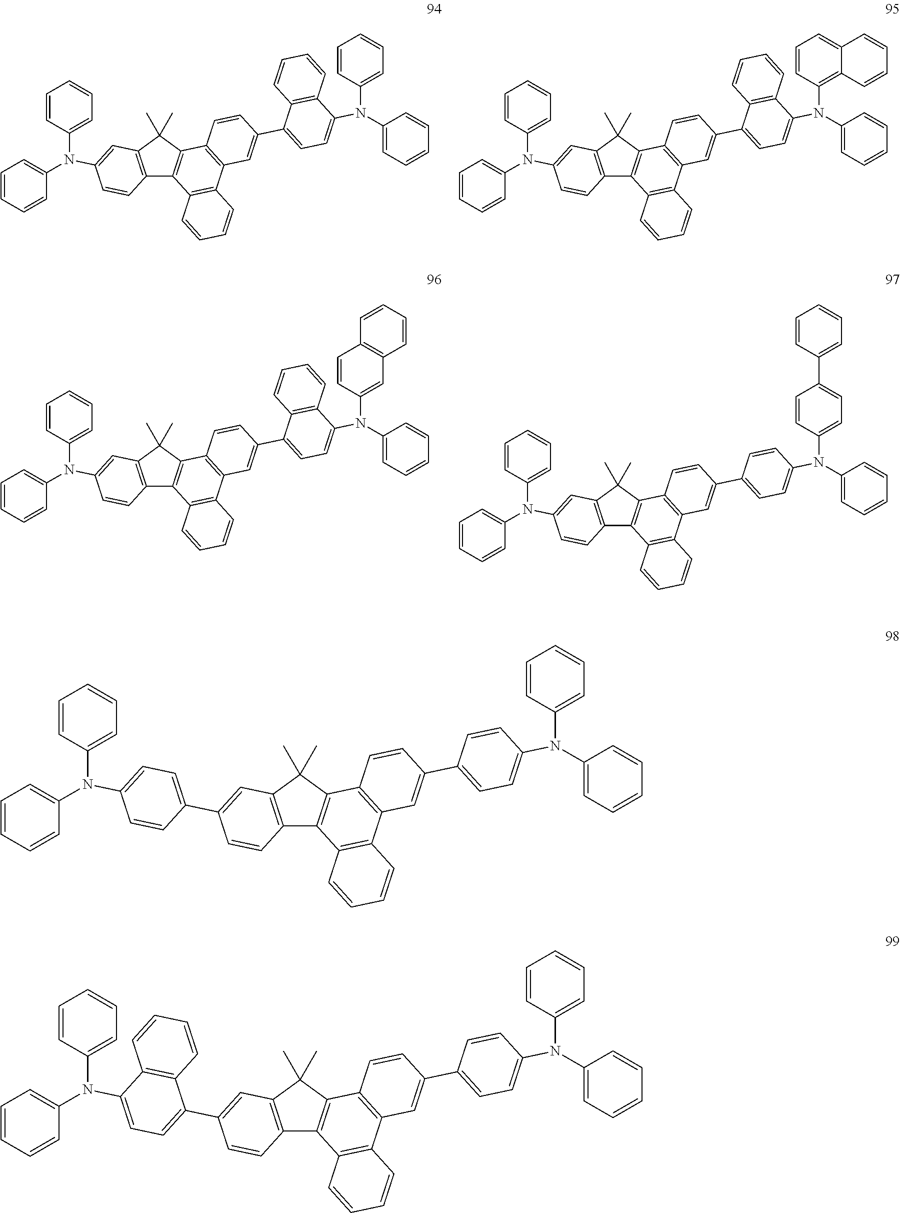 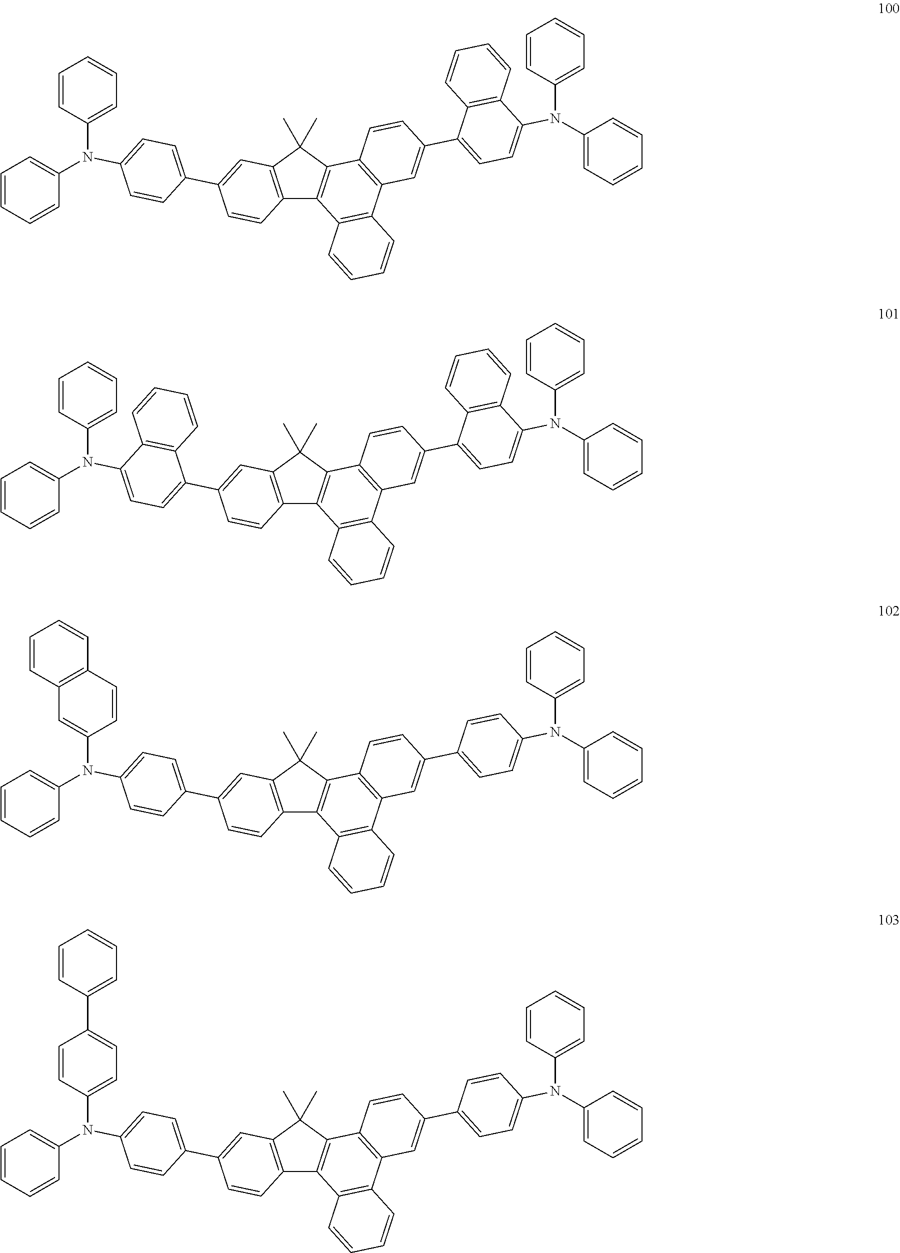 [SMILES: CC1(C)c2cc(-c3ccc(N(c4ccccc4)c4ccccc4)cc3)ccc2-c2c1c1ccc(-c3ccc(N(c4ccccc4)c4ccccc4)c4ccccc34)cc1c1ccccc21 ; CC1(C)c2cc(-c3ccc(N(c4ccccc4)c4ccccc4)c4ccccc34)ccc2-c2c1c1ccc(-c3ccc(N(c4ccccc4)c4ccccc4)c4ccccc34)cc1c1ccccc21 ; CC1(C)c2cc(-c3ccc(N(c4ccccc4)c4ccc5ccccc5c4)cc3)ccc2-c2c1c1ccc(-c3ccc(N(c4ccccc4)c4ccccc4)cc3)cc1c1ccccc21 ; CC1(C)c2cc(-c3ccc(N(c4ccccc4)c4ccc(-c5ccccc5)cc4)cc3)ccc2-c2c1c1ccc(-c3ccc(N(c4ccccc4)c4ccccc4)cc3)cc1c1ccccc21] 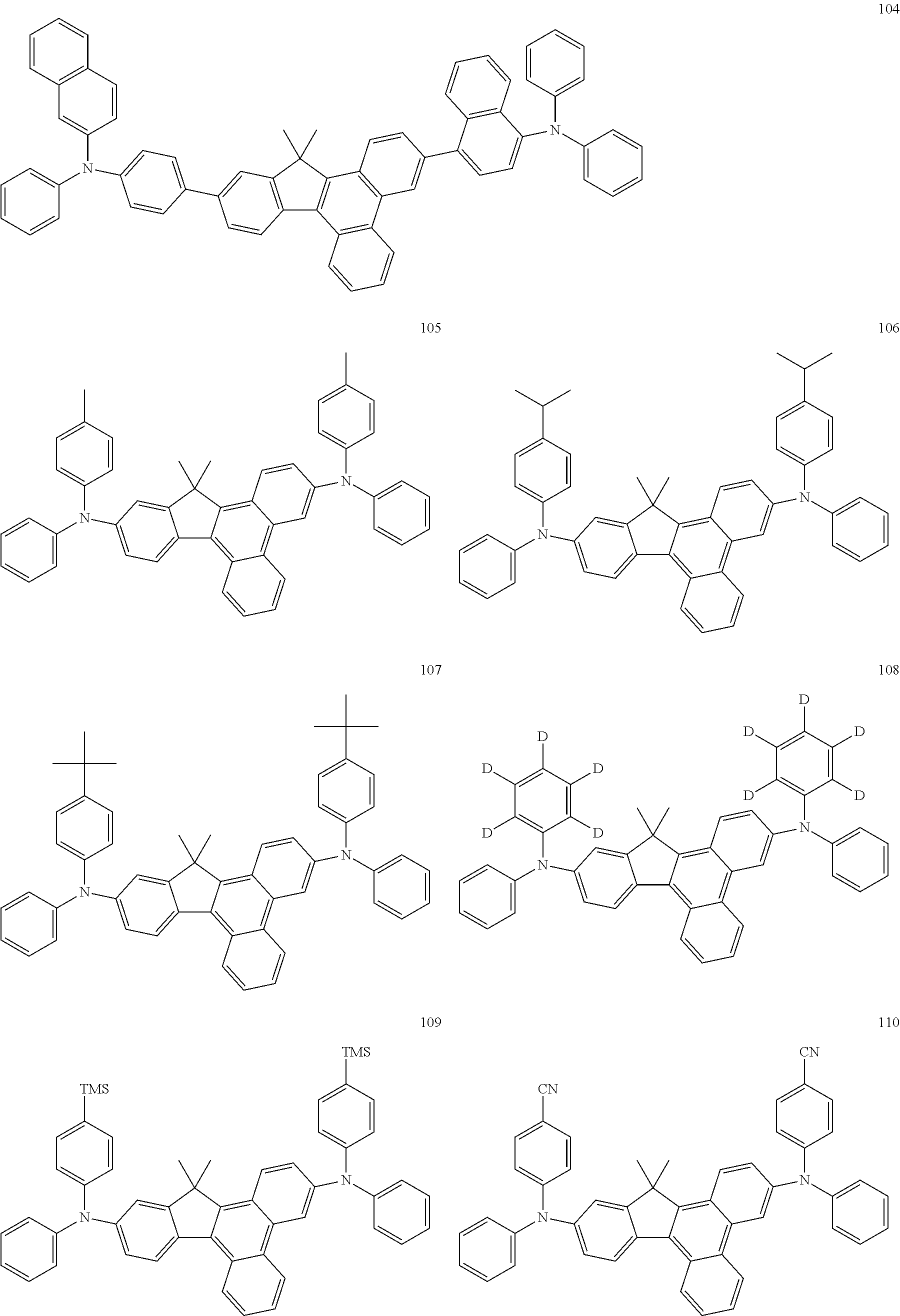 [chemical structure]
